(19) United States
(12) Patent Application Publication
(10) Pub. No.: US 2023/0061301 A1
(43) Pub. Date: Mar. 2, 2023

(54) SEMICONDUCTOR DEVICE AND DATA STORAGE SYSTEM INCLUDING THE SAME

(71) Applicant: SAMSUNG ELECTRONICS CO., LTD., Suwon-si (KR)

(72) Inventors: Kyungdong KIM, Hwaseong-si (KR); Seogoo KANG, Seoul (KR); Kohji KANAMORI, Seongnam-si (KR); Jeehoon HAN, Hwaseong-si (KR)

(21) Appl. No.: 17/857,273

(22) Filed: Jul. 5, 2022

(30) Foreign Application Priority Data
Aug. 31, 2021 (KR) 10-2021-0115769

(51) Int. Cl. H01L 27/11582; H01L 27/1157; H01L 23/528

(52) U.S. Cl. CPC H01L 27/11582; H01L 27/1157; H01L 23/5283

(57) ABSTRACT

A semiconductor device includes an upper structure on a lower structure. The upper structure includes a stack structure including gate layers, a vertical memory structure penetrating the stack structure, a bit line electrically connected to the vertical memory structure and below the stack structure, and a conductive pattern electrically connected to the vertical memory structure and on the stack structure. The vertical memory structure includes an insulating core region, a first pad pattern electrically connected to the conductive pattern on the insulating core region, a dielectric structure on a side surface of the insulating core region and a side surface of the first pad pattern, and a channel layer. The channel layer includes a first portion contacting the dielectric structure and a second portion extending from the first portion and between a lower surface of the first pad pattern and an upper surface of the insulating core region.

### CROSS TO REFERENCE TO RELATED APPLICATION

This application claims benefit of priority to Korean Patent Application No. 10-2021-0115769 filed on Aug. 31, 2021, in the Korean Intellectual Property Office, the disclosure of which is incorporated herein by reference in its entirety.

### BACKGROUND

### 1. Field

Example embodiments of the present disclosure relate to a semiconductor device and a data storage system including the same.

### 2. Description of the Related Art

There has been demand for a semiconductor device for storing high-capacity data in an electronic system requiring data storage. Accordingly, a method of increasing data storage capacity of a semiconductor device has been studied. For example, as one method for increasing data storage capacity of a semiconductor device, a semiconductor device including memory cells arranged three-dimensionally, instead of memory cells arranged two-dimensionally, has been suggested.

### SUMMARY

According to an embodiment, a semiconductor device includes a lower structure including a substrate and a peripheral circuit on the substrate; and an upper structure on the lower structure, wherein the upper structure includes a stack structure including interlayer insulating layers and gate layers, a vertical memory structure penetrating through the stack structure, a bit line electrically connected to the vertical memory structure below the stack structure, a conductive pattern electrically connected to the vertical memory structure on the stack structure, an upper insulating layer covering the conductive pattern and a capping insulating layer on the upper insulating layer, wherein the vertical memory structure includes an insulating core region, a first pad pattern electrically connected to the conductive pattern on the insulating core region, a dielectric structure on a side surface of the insulating core region and a side surface of the first pad pattern, and a channel layer between the insulating core region and the dielectric structure and between the insulating core region and the first pad pattern, and wherein the channel layer includes a first portion contacting the dielectric structure and a second portion extending from the first portion and between a lower surface of the first pad pattern and an upper surface of the insulating core region.

According to an embodiment, a semiconductor device includes a lower structure including a substrate and a peripheral circuit on the substrate; and an upper structure bonded to the lower structure on the lower structure, wherein the upper structure includes a stack structure including interlayer insulating layers and gate layers; a vertical memory structure penetrating through the stack structure; a bit line electrically connected to the vertical memory structure below the stack structure; gate contact plugs contacting pad regions of the gate layers and below the gate layers; a source contact plug and an input/output contact plug spaced apart from the gate layers, and having upper surfaces on a level higher than a level of an uppermost gate layer among the gate layers, and lower surfaces on a level lower than a level of a lowermost gate layer among the gate layers; a first conductive pattern electrically connected to the vertical memory structure and the source contact plug on a level higher than a level of the stack structure; a second conductive pattern electrically connected to the input/output contact plug on the same level as a level of the first conductive pattern; an upper insulating layer covering the first and second conductive patterns; a capping insulating layer on the upper insulating layer; and an input/output pattern penetrating through the capping insulating layer and the upper insulating layer and electrically connected to the second conductive pattern, wherein the vertical memory structure includes an insulating core region, a channel layer covering at least a side surface of the insulating core region, a first pad pattern contacting the channel layer on a level higher than a level of the uppermost gate layer, a dielectric structure contacting the first pad pattern and the channel layer, and a second pad pattern contacting the channel layer below the insulating core region, wherein the insulating core region is spaced apart from the first pad pattern, wherein the dielectric structure includes a first dielectric layer, a second dielectric layer and a data storage layer between the first dielectric layer and the second dielectric layer, and wherein the second dielectric layer includes a portion contacting the channel layer and a portion contacting the first pad pattern, and is spaced apart from the second pad pattern.

According to an embodiment, a data storage system includes a semiconductor device including an input/output pattern; and a controller electrically connected to the semiconductor device through the input/output pattern and controlling the semiconductor device, wherein the semiconductor device includes a lower structure including a substrate and a peripheral circuit on the substrate; and an upper structure bonded to the lower structure on the lower structure, wherein the upper structure includes a stack structure including interlayer insulating layers and gate layers; a vertical memory structure penetrating through the stack structure; a bit line electrically connected to the vertical memory structure below the stack structure; gate contact plugs contacting pad regions of the gate layers and below the gate layers; a source contact plug and an input/output contact plug spaced apart from the gate layers, and having upper surfaces on a level higher than a level of an uppermost gate layer among the gate layers, and lower surfaces on a level lower than a level of a lowermost gate layer among the gate layers; a first conductive pattern electrically connected to the vertical memory structure and the source contact plug on a level higher than a level of the stack structure; a second conductive pattern electrically connected to the input/output contact plug on the same level as a level of the first conductive pattern; an upper insulating layer covering the first and second conductive patterns; and a capping insulating layer on the upper insulating layer, wherein the input/output pattern penetrates the capping insulating layer and the upper insulating layer and is electrically connected to the second conductive pattern, wherein the vertical memory structure includes an insulating core region, a channel layer covering at least a side surface of the insulating core region, a first pad pattern contacting the channel layer on a level higher than a level of the uppermost gate layer, a dielectric structure contacting the first pad pattern and the channel layer, and a second pad pattern below the insulating core region, wherein the dielectric structure includes a first dielectric layer, a second dielectric layer, and a data storage layer between the first dielectric layer and the second dielectric layer, and wherein the second dielectric layer includes a portion contacting the channel layer and a portion contacting the first pad pattern, and is spaced apart from the second pad pattern.

### BRIEF DESCRIPTION OF DRAWINGS

Features will become apparent to those of skill in the art by describing in detail example embodiments with reference to the attached drawings in which:

FIGS. 1, 2A, and 2B are diagrams illustrating a semiconductor device according to an example embodiment;

FIG. 2C is an enlarged diagram illustrating a modified example of a semiconductor device, illustrating a portion of the semiconductor device;

FIG. 3A is an enlarged diagram illustrating a modified example of a semiconductor device, illustrating a portion of the semiconductor device;

FIG. 3B is an enlarged diagram illustrating a modified example of a semiconductor device, illustrating a portion of the semiconductor device;

FIG. 3C is an enlarged diagram illustrating a modified example of a semiconductor device, illustrating a portion of the semiconductor device;

FIG. 4 is an enlarged diagram illustrating a modified example of a semiconductor device, illustrating a portion of the semiconductor device;

FIG. 5 is an enlarged diagram illustrating a modified example of a semiconductor device, illustrating a portion of the semiconductor device;

FIGS. 6, 7, and 8 are diagrams illustrating a modified example of a semiconductor device;

FIG. 9 is an enlarged diagram illustrating a modified example of a semiconductor device, illustrating a portion of the semiconductor device;

FIG. 10 is an enlarged diagram illustrating a modified example of a semiconductor device, illustrating a portion of the semiconductor device;

FIG. 11 is an enlarged diagram illustrating a modified example of a semiconductor device, illustrating a portion of the semiconductor device;

FIG. 12 is an enlarged diagram illustrating a modified example of a semiconductor device, illustrating a portion of the semiconductor device;

FIG. 13 is an enlarged diagram illustrating a modified example of a semiconductor device, illustrating a portion of the semiconductor device;

FIGS. 14, 15A, and 15B are diagrams illustrating a modified example of a semiconductor device;

FIG. 16 is an enlarged diagram illustrating a modified example of a semiconductor device, illustrating a portion of the semiconductor device;

FIG. 17 is an enlarged diagram illustrating a modified example of a semiconductor device, illustrating a portion of the semiconductor device;

FIG. 18 is an enlarged diagram illustrating a modified example of a semiconductor device, illustrating a portion of the semiconductor device;

FIGS. 19, 20A, and 20B are diagrams illustrating a modified example of a semiconductor device;

FIG. 21 is an enlarged diagram illustrating a modified example of a semiconductor device, illustrating a portion of the semiconductor device;

FIG. 22 is an enlarged diagram illustrating a modified example of a semiconductor device, illustrating a portion of the semiconductor device;

FIG. 23 is an enlarged diagram illustrating a modified example of a semiconductor device, illustrating a portion of the semiconductor device;

FIG. 24 is an enlarged diagram illustrating a modified example of a semiconductor device, illustrating a portion of the semiconductor device;

FIGS. 25, 26A, and 26B are diagrams illustrating a modified example of a semiconductor device;

FIG. 27 is an enlarged diagram illustrating a modified example of a semiconductor device, illustrating a portion of the semiconductor device;

FIG. 28 is an enlarged diagram illustrating a modified example of a semiconductor device, illustrating a portion of the semiconductor device;

FIG. 29 is an enlarged diagram illustrating a modified example of a semiconductor device, illustrating a portion of the semiconductor device;

FIG. 30 is a flowchart illustrating processes of a method of manufacturing a semiconductor device according to an example embodiment;

FIG. 31 is a cross-sectional diagram illustrating a method of manufacturing a semiconductor device according to an example embodiment;

FIGS. 32A to 32H are enlarged diagrams illustrating an example of a method of manufacturing a semiconductor device, illustrating a portion of the semiconductor device;

FIG. 33 is an enlarged diagram illustrating a modified example of a method of manufacturing a semiconductor device, illustrating a portion of the semiconductor device;

FIGS. 34A to 34H are enlarged diagrams illustrating a modified example of a method of manufacturing a semiconductor device, illustrating a portion of the semiconductor device;

FIGS. 35A to 35G are enlarged diagrams illustrating a modified example of a method of manufacturing a semiconductor device, illustrating a portion of the semiconductor device;

FIGS. 36A to 36F are enlarged diagrams illustrating a modified example of a method of manufacturing a semiconductor device, illustrating a portion of the semiconductor device;

FIG. 37A to 37F are enlarged diagrams illustrating a modified example of a method of manufacturing a semiconductor device, illustrating a portion of the semiconductor device;

FIG. 38 is a diagram illustrating a data storage system including a semiconductor device according to an example embodiment;

FIG. 39 is a perspective diagram illustrating a data storage system including a semiconductor device according to an example embodiment; and

FIG. 40 is a cross-sectional diagram illustrating a data storage system including a semiconductor device according to an example embodiment.

### DETAILED DESCRIPTION

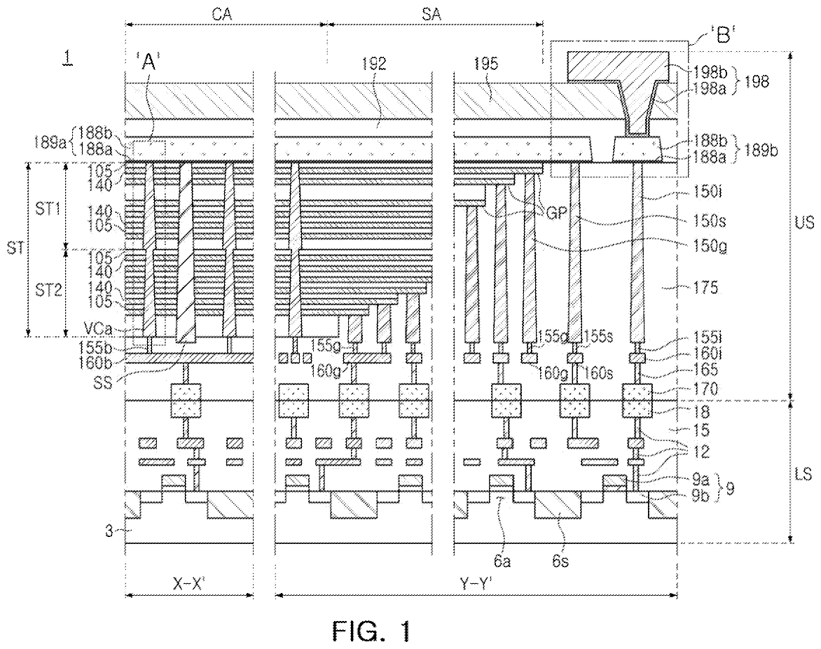

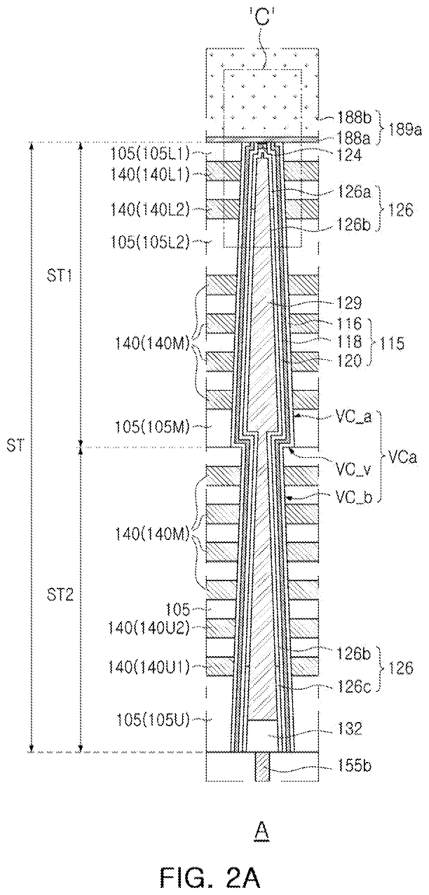

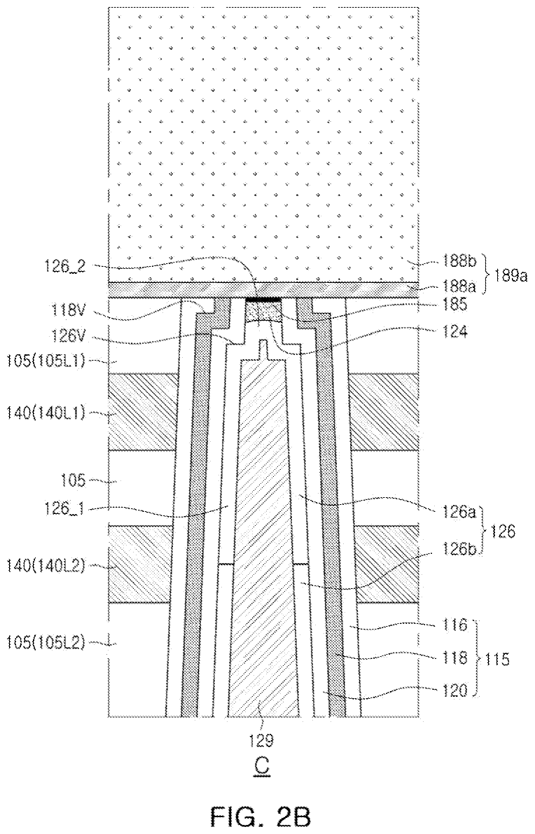

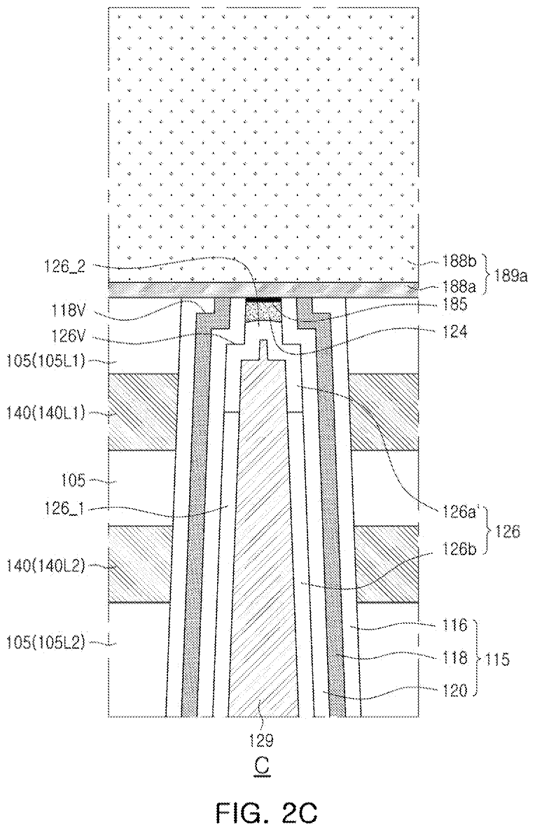

A semiconductor device according to an example embodiment will be described with reference to FIGS. 1, 2A, and 2B.

FIG. 1 is a cross-sectional diagram illustrating a semiconductor device 1 according to an example embodiment. In FIG. 1, a region marked X-X′ is a cross-sectional region in a first direction, and a region marked Y-Y′ is a cross-sectional region in a second direction perpendicular to the first direction.

FIG. 2A is an enlarged diagram illustrating region “A” in FIG. 1. FIG. 2B is an enlarged diagram illustrating region “C” in FIG. 2A.

Referring to FIGS. 1, 2A, and 2B, the semiconductor device 1 according to an example embodiment may include a lower structure LS and an upper structure US on the lower structure LS.

The lower structure LS may include a substrate 3, peripheral circuit structures 9 and 12, a lower insulating structure 15, and first bonding pads 18.

The substrate 3 may be a semiconductor substrate. For example, the substrate 3 may be a single crystal semiconductor substrate. For example, the substrate 3 may be a single crystal silicon layer. The peripheral circuit structures 9 and 12 may include a peripheral circuit 9 on the substrate 3, and a peripheral wiring structure 12 (e.g., a peripheral interconnection structure) electrically connected to the peripheral circuit 9 and on the substrate 3. The peripheral circuit 9 may include source/drain regions 9b in an active region 6a defined by a device isolation region 6s on the substrate 3, and a peripheral gate 9a on the active region 6a between the source/drain regions 9b. The lower insulating structure 15 may cover the peripheral circuit structures 9 and 12 on the substrate 3. The first bonding pads 18 may be electrically connected to the peripheral wiring structure 12, and may be embedded in the lower insulating structure 15. Upper surfaces of the first bonding pads 18 may be coplanar with an upper surface of the lower insulating structure 15. The first bonding pads 18 may include a metal material forming the intermetallic bonding, e.g., copper.

The upper structure US may include a stack structure ST including interlayer insulating layers 105 and gate layers 140 alternately stacked, a vertical memory structure VCa penetrating through the stack structure ST, a bit line 160b electrically connected to the vertical memory structure VCa below the stack structure ST, a first conductive pattern 189a electrically connected to the vertical memory structure VCa on the stack structure ST, an upper insulating layer 192 covering the first conductive pattern 189a, and a capping insulating layer 195 on the upper insulating layer 192. The upper insulating layer 192 may include silicon oxide. The capping insulating layer 195 may include at least one of silicon nitride and polyimide.

The stack structure ST may include a first stack region ST1 and a second stack region ST2 below the first stack region ST1. Each of the first and second stack regions ST1 and ST2 may include the interlayer insulating layers 105 and the gate layers 140 alternately stacked. The interlayer insulating layers 105 may include silicon oxide.

The upper structure US may include a first region CA and a second region SA adjacent to the first region CA. The first region CA may be a memory region or a memory cell array region. The second region SA may be a staircase region.

The gate layers 140 may be vertically stacked and spaced apart from each other in the first region CA, and may extend from the first region CA to the second region SA. The gate layers 140 may include gate pads GP arranged in a staircase shape in the second region SA. The gate pads GP may face the lower structure LS. For example, a gate layer disposed relatively in an upper portion may further extend to the second region SA than a gate layer disposed relatively in a lower portion.

In an example, each of the gate layers 140 may include a gate electrode including a conductive material, e.g., at least one of doped polysilicon, metal nitride (e.g., TiN, etc.), a metal-semiconductor compound (e.g., TiSi, NiSi, etc.), and a metal (e.g., W, etc.).

In a modified example, each of the gate layers 140 may include a conductive layer and a dielectric layer covering the upper and lower surfaces of the conductive layer and covering the side surface of the conductive layer facing the vertical memory structure VCa. The conductive layer may be a gate electrode. The dielectric layer may be a gate dielectric formed of a high dielectric.

The upper structure US may further include a separation structure SS penetrating through the stack structure ST. In an example, the separation structure SS may be formed of an insulating material. In the modified example, the separation structure SS may include a conductive pattern and an insulating spacer covering a side surface of the conductive pattern.

The upper structure US may further include a second conductive pattern 189b on the same level as a level of the first conductive pattern 189a and spaced apart from the first conductive pattern 189a. Each of the first and second conductive patterns 189a and 189b may include a first conductive layer 188a and a second conductive layer 188b on the first conductive layer 188a. Each of the first and second conductive patterns 189a and 189b may have an inclined side surface. For example, each of the first and second conductive patterns 189a and 189b may have side surfaces inclined such that a width thereof may increase downwardly. The first conductive layer 188a may include a metal material, e.g., Ti and/or TiN. The second conductive layer 188b may include a metal material, e.g., aluminum or tungsten.

The upper structure US may include gate contact plugs 150g contacting and electrically connected to the gate pads GP below the gate layers 140, the source contact plug 150s contacting and electrically connected to the first conductive pattern 189a below the first conductive pattern 189a, and the input/output contact plug 150i contacting and electrically connected to the second conductive pattern 189b below the second conductive pattern 189b.

The upper structure US may further include gate interconnections 160g, a source interconnection 160s, and an input/output interconnection 160i on the same level as a level of the bit line 160b. The bit line 160b, the gate interconnections 160g, the source interconnection 160s, and the input/output interconnection 160i may include the same metal material, e.g., tungsten or copper. The bit line 160b, the gate interconnections 160g, the source interconnection 160s, and the input/output interconnection 160i may form the interconnections 160b, 160g, 160s, and 160i. The interconnections 160b, 160g, 160s, and 160i may be wirings.

The upper structure US may further include studs 155b, 155g, 155s, and 155i. The studs 155b, 155g, 155s, and 155i may include a bit line stud 155b electrically connecting the bit line 160b to the vertical memory structure VCa between the bit line 160b and the vertical memory structure VCa, gate studs 155g electrically connecting the gate contact plugs 150g to the gate interconnections 160g between the gate contact plugs 150g and the gate interconnections 160g, a source stud 155s electrically connecting the source contact plug 150s to the source interconnection 160s between the source contact plug 150s and the source interconnection 160s, and an input/output stud 155i electrically connecting the input/output contact plug 150i to the input/output interconnection 160i between the input/output contact plug 150i and the input/output interconnection 160i.

The upper structure US may further include the second bonding pads 170. The second bonding pads 170 may be formed of the same material as that of the first bonding pads 18, and may be in contact with and bonded to the first bonding pads 18.

The upper structure US may further a include a connection structure 165 electrically connecting the interconnections 160b, 160g, 160s, and 160i including the bit line 160b, the gate interconnections 160g, the source interconnection 160s, and the input/output interconnection 160i to the second bonding pads 170. The connection structure 165 may have various shapes. For example, the connection structure 165 may be formed in a shape including a vertically extending via and a horizontally extending line-shaped wiring.

The upper structure US may further include an upper insulating structure 175. The upper insulating structure 175 may contact the lower insulating structure 15. The stack structure ST, the contact plugs 150g, 150s, and 150i, the interconnections 160b, 160g, 160s, and 160i, and the studs 155b, 155g, 155s, and 155i may be embedded in the upper insulating structure 175. An upper surface of the stack structure ST may be coplanar with an upper surface of the upper insulating structure 175, and lower surfaces of the second bonding pads 170 may be coplanar with a lower surface of the upper insulating structure 175.

The first conductive pattern 189a may include a portion covering the stack structure ST and a portion covering the upper surface of the upper insulating structure 175. The second conductive pattern 189b may be on the upper insulating structure 175.

The upper structure US may further include an input/output pattern 198 penetrating through the capping insulating layer 195 and the upper insulating layer 192 on the second conductive pattern 189b, and electrically connected to the second conductive pattern 189b. The input/output pattern 198 may include a conductive liner 198a and a conductive layer 198b on the conductive liner 198a in order. The conductive liner 198a may include a conductive material, e.g., Ti and/or TiN. The conductive layer 198b may include a conductive material, e.g., aluminum or copper. The input/output pattern 198 may include a portion penetrating through the capping insulating layer 195, a portion penetrating through the upper insulating layer 192, and a portion on the capping insulating layer 195.

In the description below, an example of the vertical memory structure VCa will be described with reference to FIGS. 2A and 2B.

Referring to FIGS. 2A and 2B together with FIG. 1, the vertical memory structure VCa may include an insulating core region 129, a first pad pattern 124 on the insulating core region 129, a dielectric structure 115 on the side surface of the insulating core region 129 and the side surface of the first pad pattern 124, and a channel layer 126 between the insulating core region 129 and the dielectric structure 115 and between the insulating core region 129 and the first pad patterns 124.

The first pad pattern 124 may be on a level higher than a level of an uppermost gate layer 140L1 among the gate layers 140. The first pad pattern 124 may be on a level higher than a level of the lower surface of the uppermost interlayer insulating layer 105L1 among the interlayer insulating layers 105, and may be on a level substantially the same as a level of the upper surface of the uppermost interlayer insulating layer 105L1. In a modified example, the first pad pattern 124 may be on a level lower than a level of an upper surface of the uppermost interlayer insulating layer 105L1. A lower surface of the first pad pattern 124 may have a concave shape.

The channel layer 126 may include a first portion 126_1 contacting the dielectric structure 115, and a second portion 126_2 extending from the first portion 126_1 and between the lower surface of the first pad pattern 124 and the upper surface of the insulating core region 129.

The vertical memory structure VCa may further include a second pad pattern 132 below the insulating core region 129. The channel layer 126 may contact the second pad pattern 132. The channel layer 126 may cover a side surface of the second pad pattern 132. The dielectric structure 115 may cover the external side surface of the channel layer 126 on a level on which the second pad pattern 132 is disposed.

The first and second pad patterns 124 and 132 may include doped silicon, e.g., polysilicon having an N-type conductivity. The channel layer 126 may be formed of a silicon layer. The channel layer 126 may be formed of a single silicon layer.

The second pad pattern 132 may have a width greater than that of the first pad pattern 124.

The dielectric structure 115 may include a first dielectric layer 116, a data storage layer 118, and a second dielectric layer 120. The data storage layer 118 may be interposed between the first dielectric layer 116 and the second dielectric layer 120. The first dielectric layer 116 may include silicon oxide and/or a high dielectric. The data storage layer 118 may include a material able to store data in a memory device, e.g., silicon nitride able to trap charges. The second dielectric layer 120 may be a tunnel dielectric layer contacting the channel layer 126. The second dielectric layer 120 may be silicon oxide or silicon oxide doped with impurities. The second dielectric layer 120 may include a region contacting the channel layer 126 and a region contacting a side surface of the first pad pattern 124.

The semiconductor device 1 may further include a metal-semiconductor compound layer 185 between the first pad pattern 124 and the first conductive pattern 189a. The metal-semiconductor compound layer 185 may be formed of a metal silicide, e.g., TiSi, CoSi, WSi, or NiSi.

The metal-semiconductor compound layer 185 may be configured as a portion of the first conductive pattern 189. For example, a component formed of silicon in contact with the first conductive pattern 189, e.g., a region of the first conductive pattern 189 in contact with the first pad pattern 124, may be the metal-semiconductor compound layer 185.

An upper end of the dielectric structure 115 may contact the first conductive pattern 189a. For example, an upper end of the first dielectric layer 116, an upper end of the data storage layer 118, and an upper end of the second dielectric layer 120 may contact the first conductive pattern 189a.

The data storage layer 118 may include a bent portion 118v on a level higher than a level of the uppermost gate layer 140L1 among the gate layers 140. The channel layer 126 may include a bent portion 126V on a level higher than a level of the uppermost gate layer 140L1 among the gate layers 140.

The channel layer 126 may include a first doped region 126a contacting the first pad pattern 124, a second doped region 126c contacting the second pad pattern 132, and an undoped region 126b between the first doped region 126a and the second doped region 126c. The first and second doped regions 126a and 126c may be silicon regions having an N-type conductivity. The undoped region 126b may be an undoped silicon region.

The gate layers 140 may include a plurality of upper gate layers 140L1 and 140L2, a plurality of lower gate layers 140U1 and 140U2, and intermediate gate layers 140M between the plurality of upper gate layers 140L1 and 140L2 and the plurality of lower gate layers 140U1 and 140U2. The intermediate gate layers 140M may include word lines.

The first doped region 126a may extend from a portion contacting the first pad pattern 124, and may face at least one of the plurality of upper gate layers 140L1 and 140L2. The second doped region 126c may extend from a portion contacting the second pad pattern 132, and may face at least one of the plurality of lower gate layers 140U1 and 140U2.

The semiconductor device 1 may be a flash memory device, in which case at least one of the plurality of upper gate layers 140L1 and 140L2 may be an upper erase control gate electrode used for an erase operation of the flash memory device, and at least one of the plurality of lower gate layers 140U1 and 140U2 may be a lower erase control gate electrode used in an erase operation of the flash memory device. The number of erase control gates may be determined according to the total number of the stacked gate layers 140. Accordingly, the number of the plurality of upper gate layers 140L1 facing the first doped region 126a, and the number of the plurality of lower gate layers 140U1 and 140U2 facing the second doped region 126c may be determined.

Among the gate layers 140, a gate layer between the upper erase control gate electrode and the word lines may be a ground select gate electrode, and a gate layer between the lower erase control gate electrode and the word lines may be a string select gate electrode.

In an example, as illustrated in FIG. 2B, the number of the plurality of upper gate layers 140L1 and 140L2 facing the first doped region 126a may be two.

FIG. 2C is an enlarged diagram illustrating a modified example of the first doped region 126a of the channel layer 126 in the enlarged diagram in FIG. 2B.

In the modified example, referring to FIG. 2C, a first doped region 126a′ of the channel layer 126 may face one of the plurality of upper gate layers 140L1 and 140L2, such as the uppermost upper gate layer 140L1.

Referring back to FIGS. 2A and 2B together with FIG. 1, the vertical memory structure VCa may include a lower vertical region VC_b penetrating through the second stack region ST2, an upper vertical region VC_a penetrating through the first stack region ST1, and a width change region VC_v between the upper vertical region VC_a and the lower vertical region VC_b. The upper vertical region VC_a may have an inclined side surface, such that a width of the lower region thereof may be greater than a width of the upper region. The lower vertical region VC_b may have an inclined side surface, such that a width of the lower region thereof may be greater than a width of the upper region. A width of the lower region of the upper vertical region VC_a may be greater than a width of the upper region of the upper vertical region ST2.

In an example, the width change region VC_v may be defined as a region in which a width may change as the width of the lower region of the upper vertical region VC_a is different from the width of the upper region of the upper vertical region ST2.

In the modified example, the width change region VC_v may be defined as a region formed as the side surface of the upper vertical region VC_a and the side surface of the upper vertical region ST2 are not vertically aligned.

Also, in the modified example, the width change region VC_v may define a region having a slope different from those of the side surface of the upper vertical region VC_a and the side surface of the upper vertical region ST2. For example, the width change region VC_v may be defined as a slope change region having a slope gentler than the slopes of the side surface of the upper vertical region VC_a and the side surface of the upper vertical region ST2.

Also, in the modified example, as the width change region VC_v may extend while being bent from the side surface of the upper vertical region VC_a and the side surface of the upper vertical region ST2, the width change region VC_v may be defined as a “bent portion.”

Hereinafter, the elements using the term “width change region” may be a width change region formed as the width of the upper region is different from the width of the lower region, or a slope change region having a slope different from the slopes of the upper and lower regions, e.g., a gentle slope, unless otherwise indicated.

In the first stack region ST1, a lowermost interlayer insulating layer 105M among the interlayer insulating layers 105 may have a thickness greater than a thickness of the interlayer insulating layer vertically adjacent to the lowermost interlayer insulating layer 105M.

In the first stack region ST1, an interlayer insulating layer 105L2 between the plurality of upper gate layers 140L1 and 140L2 and the plurality of intermediate gate layers 140M may have a thickness greater than a thickness of the interlayer insulating layer 105 vertically adjacent to the interlayer insulating layer 105L2.

In the first stack region ST1, the uppermost interlayer insulating layer 105L1 of the interlayer insulating layers 105 may be coplanar with the upper surface of the upper insulating structure 175 (in FIG. 1).

In the second stack region ST2, a lowermost interlayer insulating layer 105U among the interlayer insulating layers 105 may have a thickness greater than a thickness of the interlayer insulating layer vertically adjacent to the lowermost interlayer insulating layer 105U.

In an example embodiment, since the vertical memory structure VCa includes the first pad pattern 124 and the second pad pattern 132, performance of the semiconductor device 1 may improve. For example, the first pad pattern 124 may be a source supplying a dopant in the first doped region 126a of the channel layer 126, and the second pad pattern 132 may be a source supplying a dopant in the second doped region 126c of the channel layer 126. The first and second doped regions 126a and 126c in the channel layer 126 may increase erase efficiency of an erase operation using a gate induced drain leakage (GIDL) phenomenon in a flash memory device.

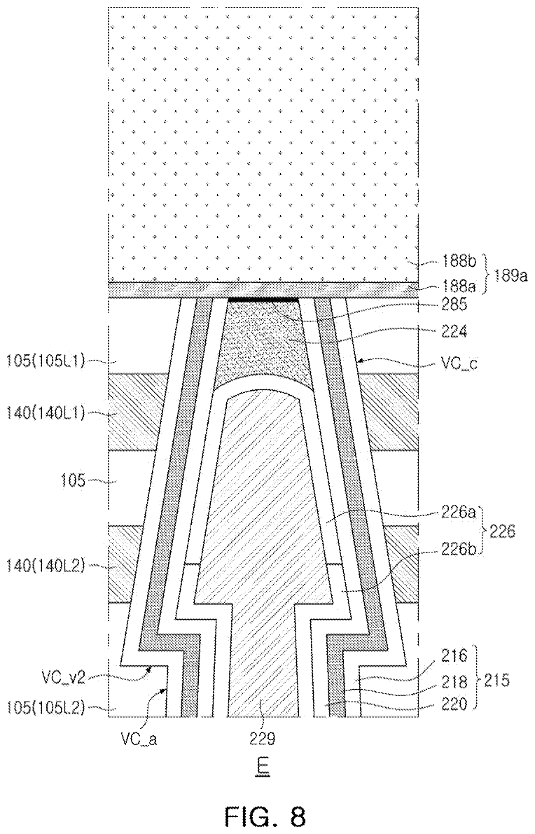

Hereinafter, various modified examples of a portion of the components of the semiconductor device 1 according to an example embodiment will be described. Hereinafter, mainly the modified components will be described. Also, the elements indicated by the same terms may be formed of the same material unless otherwise indicated. For example, the first pad pattern 124 in FIG. 2B and the first pad pattern 224 in FIG. 8 may be formed of the same material.

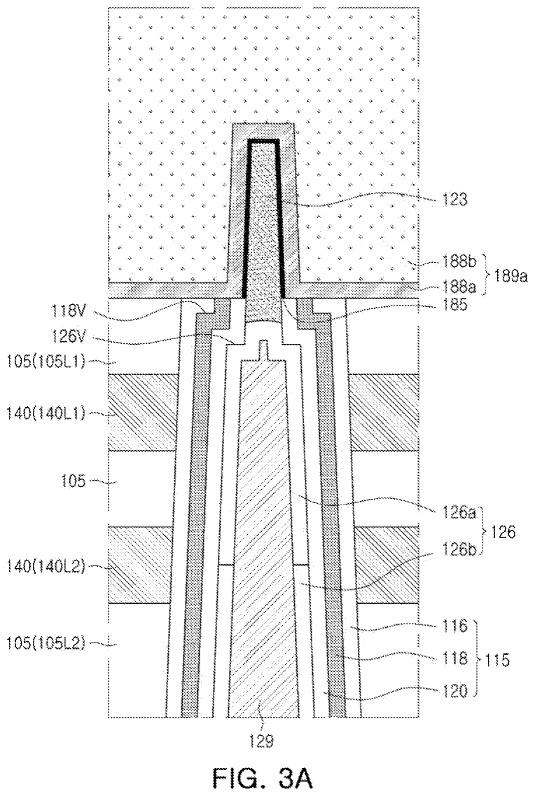

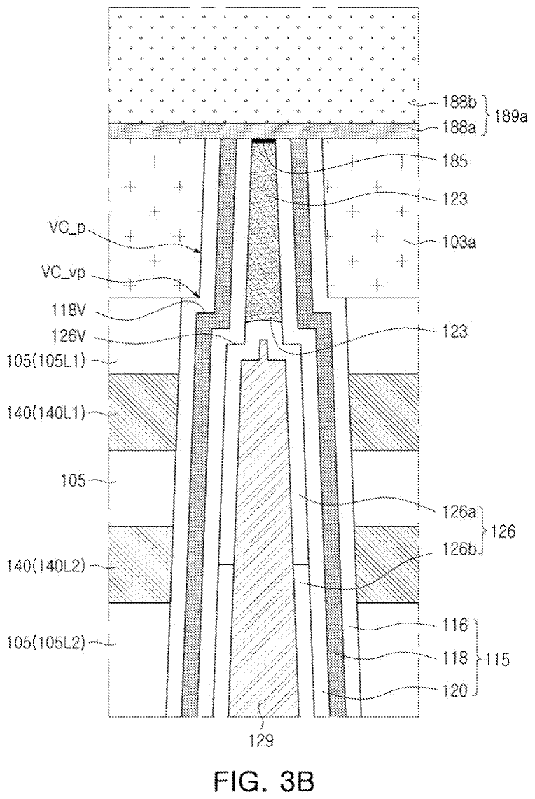

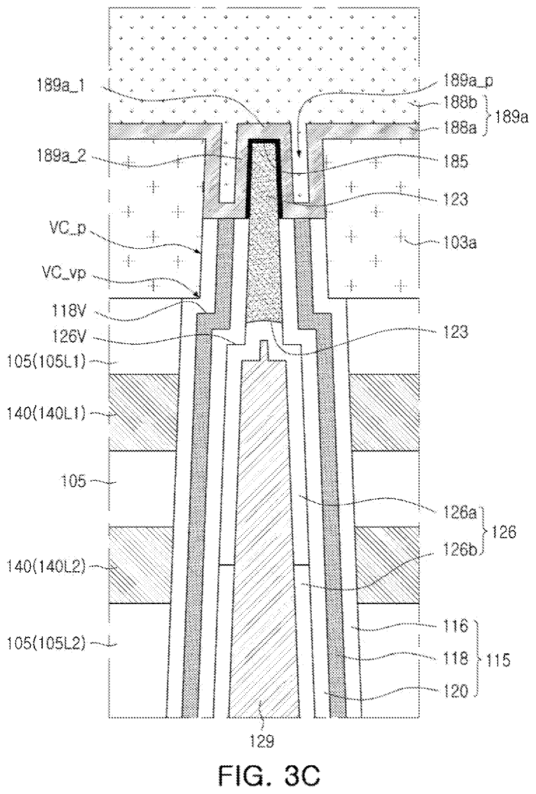

Modified examples of a semiconductor device according to an example embodiment will be described with reference to FIGS. 3A to 3C.

Each of FIGS. 3A to 3C is an enlarged diagram illustrating a modified example of a semiconductor device according to an example embodiment, corresponding to FIG. 2B.

In the modified example, referring to FIG. 3A, the first pad pattern 124 (in FIG. 2B) described with reference to FIG. 2B may be modified as a first pad pattern 123 including a portion extending into the first conductive pattern 189a. For example, the first pad pattern 123 may include a first portion on a level lower than a level of the upper surface of the uppermost interlayer insulating layer 105L1, and a second portion extending from the first portion and on a level higher than a level of the upper surface of the uppermost interlayer insulating layer 105L1. Accordingly, the first conductive pattern 189a may cover an upper surface and a portion of a side surface of the first pad pattern 123. A side surface of the first pad pattern 123 may include a first portion contacting the second dielectric layer 120 and a second portion covered by the first conductive pattern 189a on the first portion. The metal-semiconductor compound layer 185 contacting the first conductive pattern 189a and the first pad pattern 123 may be interposed between the first conductive pattern 189a and the first pad pattern 123.

Accordingly, the area or overlap between the first conductive pattern 189a and the first pad pattern 123 may increase, such that resistive properties may improve. For example, the contact region between the metal-semiconductor compound layer 185 interposed between the first conductive pattern 189a and the first pad pattern 123 and the first pad pattern 123 may increase, contact resistance may decrease. Accordingly, since resistive properties of the semiconductor device 1 may improve, performance of the semiconductor device 1 may improve.

In the modified example, referring to FIG. 3B, the semiconductor device 1 (in FIG. 1) according to an example embodiment may further include a buffer layer 103a between the uppermost interlayer insulating layer 105L1 and the first conductive pattern 189a.

In an example, the buffer layer 103a may include a semiconductor material, e.g., silicon. For example, the buffer layer 103a may be configured as a silicon layer having an N-type conductivity.

In the modified example, the buffer layer 103a may include an insulating material, e.g., at least one of silicon nitride and silicon oxide.

The first pad pattern 124 (in FIG. 2B) described with reference to FIG. 2B may be modified into a first pad pattern 123 protruding to penetrate the buffer layer 103a. The dielectric structure 115 may include a portion interposed between the side surface of the first pad pattern 123 and the buffer layer 103a. The first conductive pattern 189a may contact the upper surface of the buffer layer 103a and the upper end of the dielectric structure 115, and may cover the first pad pattern 123. A metal-semiconductor compound layer 185 may be between the first pad pattern 123 and the first conductive pattern 189a.

The vertical memory structure VCa may include a bent portion VC_vp between side surfaces of a portion VC_p penetrating through the buffer layer 103a, and a portion VC_p penetrating through the buffer layer 103a and a side surface of a portion penetrating through the stack structure (ST in FIG. 1).

The buffer layer 103a may prevent the thickness of the uppermost interlayer insulating layer 105L1 from being excessively reduced. That is, by disposing the buffer layer 103a, the uppermost interlayer insulating layer 105L1 may be formed to have a constant thickness. Accordingly, defects such as leakage current or electric shorts between the first conductive pattern 189a and the uppermost gate layer 140L1, caused by the reduced thickness of the uppermost interlayer insulating layer 105L1, may be prevented, or degradation of performance of the semiconductor device, caused by the excessively reduced thickness of the first pad pattern 123, may be prevented.

In the modified example, referring to FIG. 3C, the first conductive pattern 189a may further include an extension portion 189a_p covering a portion of a side surface of the first pad pattern 123. The first conductive pattern 189a including the extension portion 189a_p may include a portion 189a_1 covering the upper surface of the first pad pattern 123 and a portion 189a_2 covering a portion of a side surface of the first pad pattern 123. When the buffer layer 103a as illustrated in FIG. 3B is disposed, the extension portion 189a_p may extend into the buffer layer 103a. When the buffer layer 103a is not provided as in FIGS. 3A and 3B, the extension portion 189a_p may extend into the uppermost interlayer insulating layer 105L1.

Since the extension portion 189a_p of the first conductive pattern 189a may increase the area of overlap between the first conductive pattern 189a and the first pad pattern 123, resistive properties may improve

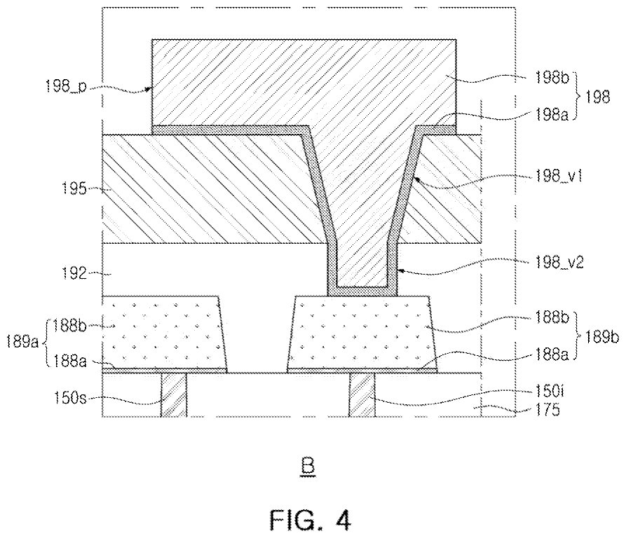

In the description below, referring to FIG. 4, the input/output pattern 198 may include a first portion 198_v1 penetrating through the capping insulating layer 195 and a second portion 198_v2 penetrating through the upper insulating layer 192. In the input/output pattern 198, a side surface of the first portion 198_v1 may have a slope gentler than a slope of a side surface of the second portion 198_v2. For example, in the input/output pattern 198, a side surface of the second portion 198_v2 may be substantially vertical, and a side surface of the first portion 198_v1 may be inclined such that the width of the first portion 198_v1 may decrease downwardly.

The first conductive pattern 189a may contact an upper surface of the source contact plug 150s. The second conductive pattern 189b may contact an upper surface of the input/output contact plug 150i.

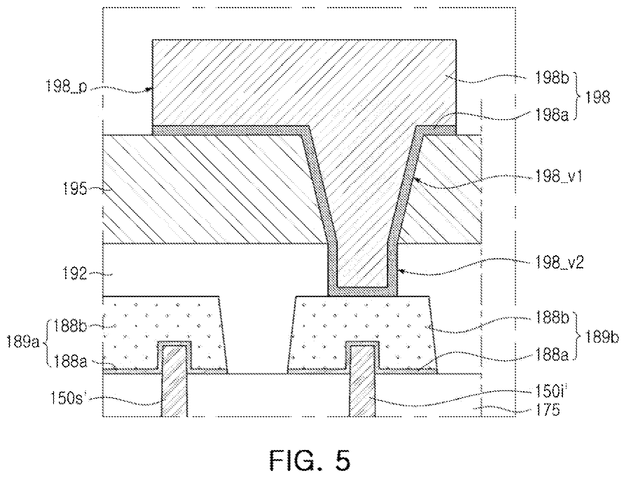

In the description below, a modified example of the source contact plug 150s and the input/output contact plug 150i will be described with reference to FIG. 5.

FIG. 5 is an enlarged diagram illustrating a modified example of a semiconductor device, illustrating a portion of a semiconductor device, and corresponds to FIG. 4.

In the modified example, referring to FIG. 5, the source contact plug 150s may include a portion extending into the first conductive pattern 189a, and the input/output contact plug 150i may include a portion extending into the second conductive pattern 189b. For example, the first conductive pattern 189a may contact an upper surface and a side surface of the source contact plug 150s on a level higher than a level of the upper insulating structure 175, and the second conductive pattern 189b may contact the upper surface and the side surface of the input/output contact plug 150i on a level higher than a level of the upper insulating structure 175. Accordingly, a contact region between the first and second conductive patterns 189a and 189b and the source and input/output contact plugs 150s and 150i may increase, such that contact resistance between the first and second conductive patterns 189a and 189b and the source and the input/output contact plugs 150s and 150i may be reduced.

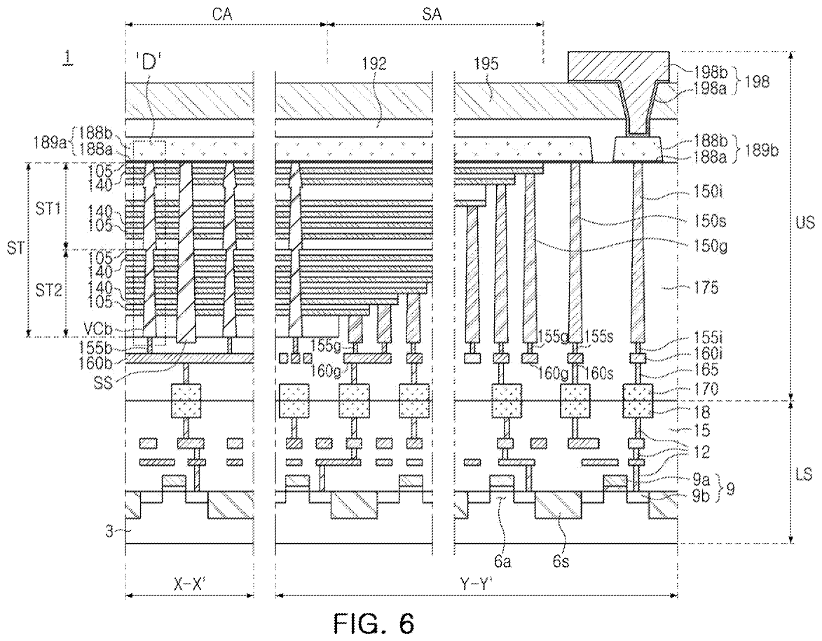

In the description below, a modified example of a semiconductor device will be described with reference to FIGS. 6 to 8.

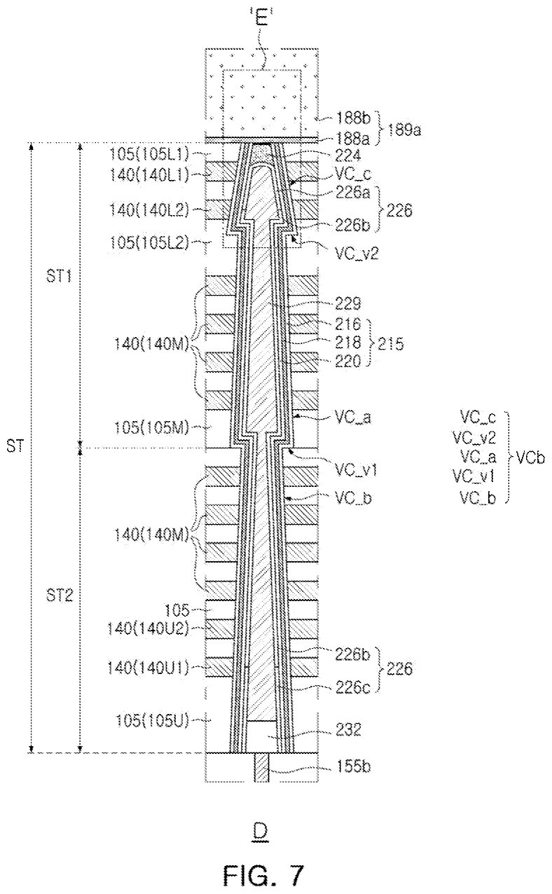

FIG. 6 is a cross-sectional diagram corresponding to FIG. 1, illustrating a modified example of the vertical memory structure VCa in FIG. 1. FIG. 7 is an enlarged diagram illustrating region “D” in FIG. 7. FIG. 8 is an enlarged diagram illustrating region “E” in FIG. 7.

In the modified example, referring to FIGS. 6, 7, and 8, the vertical memory structure VCa described with reference to FIGS. 1, 2A, and 2B may be modified into or replaced with a vertical memory structure VCb in FIGS. 6 to 8.

The vertical memory structure VCb may include an insulating core region 229, a first pad pattern 224 on the insulating core region 229, dielectric structure 215 on a side surface of the insulating core region 229 and a side surface of the first pad pattern 224, a channel layer 226 between the insulating core region 229 and the dielectric structure 215 and between the insulating core region 229 and the first pad pattern 224, and a second pad pattern 232 contacting the channel layer 226 below the insulating core region 229. The dielectric structure 215 may include a first dielectric layer 216, a data storage layer 218, and a second dielectric layer 220 corresponding to the first dielectric layer 116 of the dielectric structure 115 (in FIGS. 2A and 2B), the data storage layer 118, and the second dielectric layer 120 described in the aforementioned example embodiment, respectively.

The channel layer 226 may include a first doped region 226a, an undoped region 226b, and a second doped region 226c, corresponding to the first doped region 126a, the undoped region 126b, and the second doped region 126c described with reference to FIG. 2B, respectively. In the modified example, the first doped region 226a may be modified to face the uppermost gate layer 140L1 in substantially the same manner as the first doped region 126a′ described with reference to FIG. 2C.

In the various modified embodiments below, the “first doped region” of the channel layer may correspond to the first doped region 126a described with reference to FIG. 2B, or the “first doped region” of the channel layer described with reference to FIG. 2C may correspond to the first doped region 126a′ described with reference to FIG. 2C.

A metal-semiconductor compound layer 285 may be between the first pad pattern 224 and the first conductive pattern 189a. A lower surface of the first pad pattern 224 may have a concave shape.

The structure of the vertical memory structure VCb penetrating through the second stack region ST2 may be substantially the same as the vertical memory structure VCa (in FIG. 2B) penetrating through the second stack region ST2 as in FIG. 2B.

The vertical memory structure VCb may include a lower vertical region VC_b penetrating through the second stack region ST2, a first upper vertical region VC_a extending from the lower vertical region VC_b and penetrating through the at least the intermediate gate layers 140M in the first stack region ST1, a second upper vertical region VC_c extending from the first upper vertical region VC_a and penetrating at least the upper gate layers 140L1 and 140L2, a first width change region VC_v1 between the lower vertical region VC_b and the first upper vertical region VC_a, and a second width change region VC_v2 between the first upper vertical region VC_a and the second upper vertical region VC_c

The second width change region VC_v2 may be on a level between the plurality of upper gate layers 140L1 and 140L2 and the plurality of intermediate gate layers 140M. The second width change region VC_v2 may contact the interlayer insulating layer 105L2 between the plurality of upper gate layers 140L1 and 140L2 and the plurality of intermediate gate layers 140M.

The second upper vertical region VC_c may have an inclined side surface, such that a width of the second upper vertical region VC_c may decrease upwardly, and the lower region of the second upper vertical region VC_c may be greater than a width of an upper region of the first upper vertical region VC_a. The second width change region VC_v2 may also be defined as a slope change region described with reference to FIG. 2A.

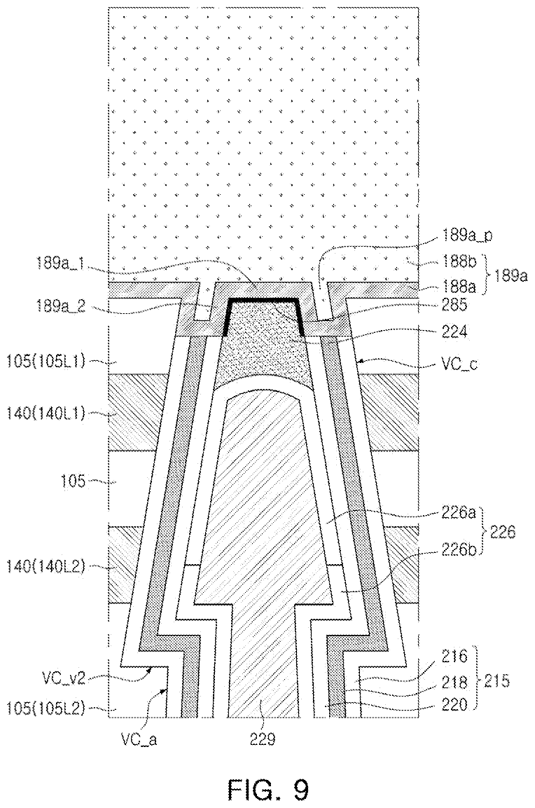

In the description below, modified examples of a semiconductor device will be described with reference to FIGS. 9 to 13.

Each of FIGS. 9 to 13 is an enlarged diagram illustrating a modified example of a semiconductor device, illustrating a portion corresponding to FIG. 8.

In the modified example, referring to FIG. 9, the first conductive pattern 189a described with reference to FIG. 8 may further include an extension portion 189a_p covering a portion of a side surface of the first pad pattern 224. The first conductive pattern 189a including the extension portion 189a_p may include a portion 189a_1 covering the upper surface of the first pad pattern 224, and a portion 189a_2 covering a portion of the side surface of the first pad pattern 224. The extension portion 189a_p may extend into the uppermost interlayer insulating layer 105L1. Since the extension portion 189a_p of the first conductive pattern 189a may increase the area of overlap between the first conductive pattern 189a and the first pad pattern 224, resistive properties may improve.

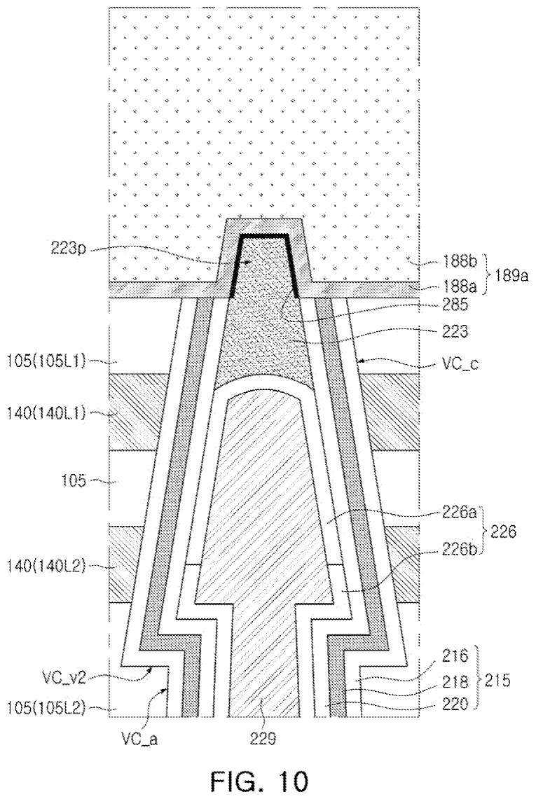

In the modified example, referring to FIG. 10, the first pad pattern 224 (in FIG. 8) described with reference to FIG. 8 may be modified into a first pad pattern 223 including a protruding portion 223p extending into the first conductive pattern 189a. Accordingly, the first conductive pattern 189a may cover an upper surface and a side surface of the protruding portion 223p of the first pad pattern 223. Since the protruding portion 223p of the first pad pattern 223 may increase the area of overlap between the first conductive pattern 189a and the first pad pattern 223, resistive properties may improve.

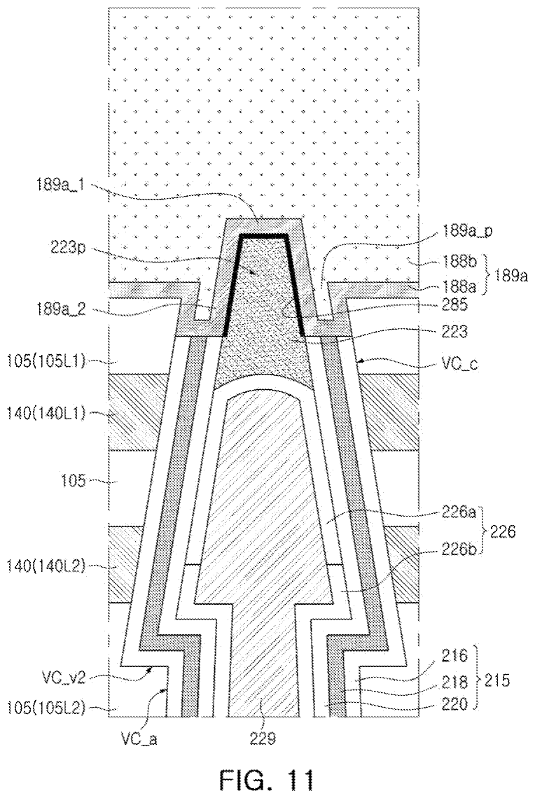

In the modified example, referring to FIG. 11, the first conductive pattern 189a described with reference to FIG. 10 may further include an extension portion 189a_p extending to a region between the uppermost interlayer insulating layer 105L1 and a side surface of the first pad pattern 223. Since the extension portion 189a_p of the first conductive pattern 189a may increase the area of overlap between the first conductive pattern 189a and the first pad pattern 223, resistive properties may improve.

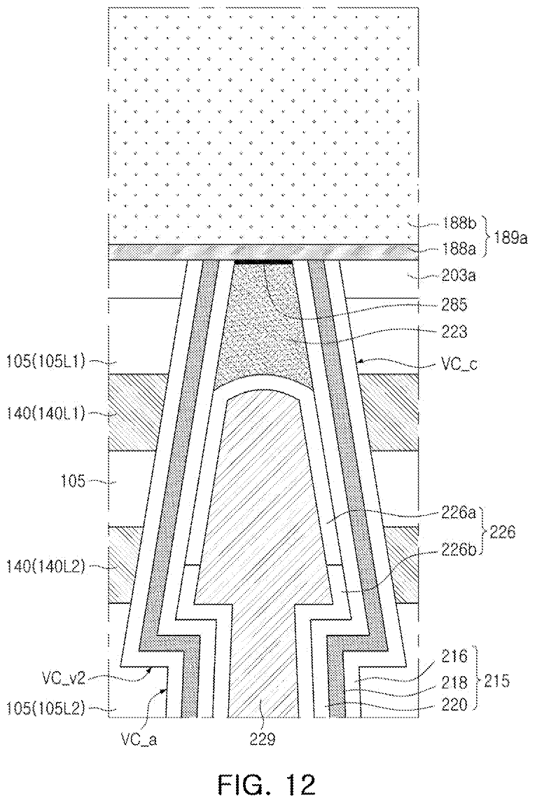

In the modified example, referring to FIG. 12, a buffer layer 203a may be between the uppermost interlayer insulating layer 105L1 and the first conductive pattern 189a. The buffer layer 203a may include the same material as that of the buffer layer 103a (in FIG. 3B) described with reference to FIG. 3B, and may work substantially the same as the buffer layer 103a (in FIG. 3B) described with reference to FIG. 3B.

The first pad pattern 224 in FIG. 8 described with reference to FIG. 8 may be modified into a first pad pattern 223 protruding to penetrate the buffer layer 203a. The dielectric structure 235 may include a portion interposed between the side surface of the first pad pattern 223 and the buffer layer 203a. The first conductive pattern 189a may contact an upper surface of the buffer layer 203a and an upper end of the dielectric structure 215, and may cover the first pad pattern 223. The metal-semiconductor compound layer 285 may be between the first pad pattern 223 and the first conductive pattern 189a.

The first conductive pattern 189a may contact the upper surface of the buffer layer 203a and the upper end of the dielectric structure 215, and may cover the upper surface of the first pad pattern 223.

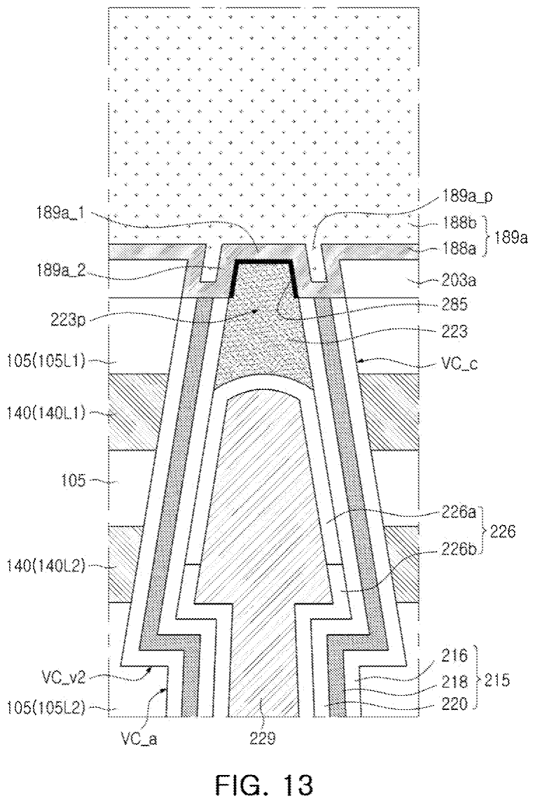

In the modified example, referring to FIG. 13, the first conductive pattern 189a in FIG. 12 may include an extension portion 189a_p extending to a region between the buffer layer 203a and a side surface of the first pad pattern 224. Since the extension portion 189a_p of the first conductive pattern 189a may increase the area of overlap between the first conductive pattern 189a and the first pad pattern 223, resistive properties may improve.

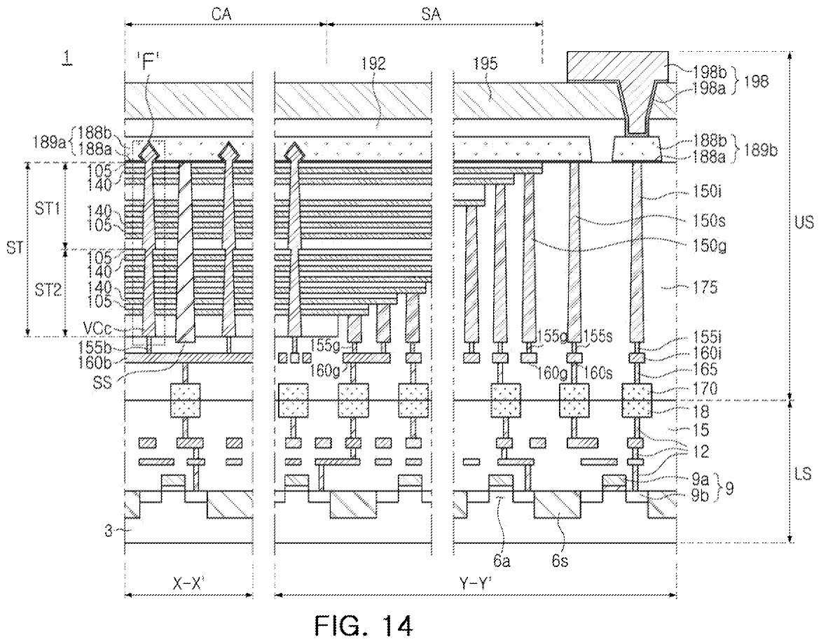

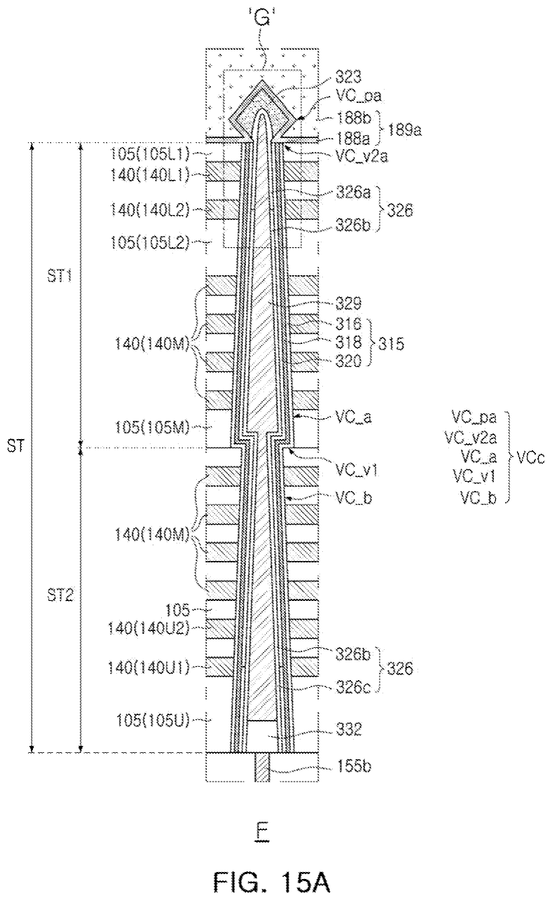

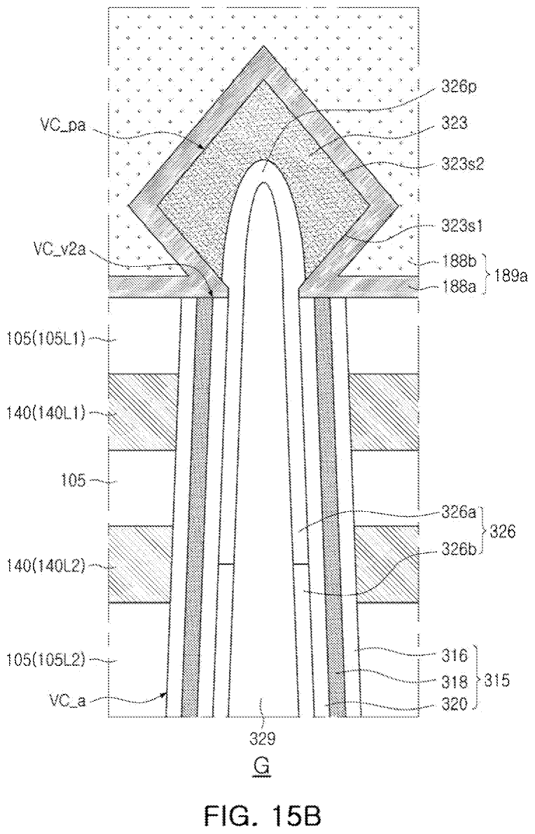

In the description below, a modified example of the semiconductor device will be described with reference to FIGS. 14, 15A, and 15B.

FIG. 14 is a cross-sectional diagram corresponding to FIG. 1, illustrating a modified example of the vertical memory structure VCa in FIG. 1. FIG. 15A is an enlarged diagram illustrating region “F” in FIG. 14. FIG. 15B is an enlarged diagram illustrating region “G” in FIG. 15A.

In the modified example, referring to FIGS. 14, 15A, and 15B, the vertical memory structure VCa described with reference to FIGS. 1, 2A, and 2B modified into or replaced with a vertical memory structure VCc in FIGS. 14, 15A, and 15B.

The vertical memory structure VCc may include an insulating core region 329, a first pad pattern 323 on the insulating core region 329, a dielectric structure 315 on a side surface of the insulating core region 329 and a side surface of the first pad pattern 323, a channel layer 326 between the insulating core region 329 and the dielectric structure 315 and between the insulating core region 329 and the first pad pattern 323, and a second pad pattern 332 contacting the channel layer 326 below the insulating core region 329.

The dielectric structure 315 may include a first dielectric layer 316, a data storage layer 318, and a second dielectric layer 320 corresponding to the first dielectric layer 116, the data storage layer 118, and the second dielectric layer 120 of the dielectric structure 115 (in FIGS. 2A and 2B) described in the aforementioned example embodiment, respectively. The channel layer 326 may include a first doped region 326a, an undoped region 326b, and a second doped region 326c, corresponding to the first doped region 126a, the undoped region 126b, and the second doped region 126c described with reference to FIG. 2B, respectively. In the modified example, the first doped region 326a may be modified to correspond to the first doped region 126a′ described with reference to FIG. 2C.

The structure of the vertical memory structure VCc penetrating through the second stack region ST2 may be substantially the same as the vertical memory structure VCa (in FIG. 2B) penetrating through the second stack region ST2 as in FIG. 2B.

The vertical memory structure VCc may include a lower vertical region VC_b penetrating through the second stack region ST2, an upper vertical region VC_a extending from the er vertical region VC_b and penetrating through the first stack region ST1, a protruding region VC_pa extending from the upper vertical region VC_a and on a level higher than a level of the upper surface of the stack structure ST, a first width change region VC_v1 between the lower vertical region VC_b and the upper vertical region VC_a, and a second width change region VC_v2a between the upper vertical region VC_a and the protruding region VC_pa. The second width change region VC_v2a may also be defined as a slope change region as described above.

The insulating core region 329 may extend upwardly from a portion penetrating through the stack structure ST. The first pad pattern 323 may be on a level higher than a level of the uppermost interlayer insulating layer 105L1. The channel layer 326 may include a region 326p interposed between the insulating core region 329 and the first pad pattern 323 on a level higher than a level of the uppermost interlayer insulating layer 105L1.

The first pad pattern 323 may include a first side surface 323s1 inclined such that a width of the first pad pattern 323 may increase upwardly, and a second side surface 323s2 on a level higher than a level of the first side surface 323s1, extending from the first side surface 323s1, and inclined such that a width of the first pad pattern 323 may decrease upwardly.

The first conductive pattern 189a may cover the first and second side surfaces 323s1 and 323s2 of the first pad pattern 323. The first conductive pattern 189a may include a metal-semiconductor compound layer in a portion covering the first pad pattern 323, in which case the first conductive pattern 189a may contact the first and second side surfaces 323s1 and 323s2 of the first pad pattern 323.

A component referred to as a “first conductive pattern” may include a metal-semiconductor compound layer in a region contacting a component formed of silicon, e.g., the first pad pattern or the channel layer, unless otherwise indicated.

An upper end of the dielectric structure 315 may be on a level lower than a level of the first pad pattern 323. The first conductive pattern 189a may contact an upper end of the dielectric structure 315. The first conductive pattern 189a may contact the channel layer 326 on a level between the upper end of the dielectric structure 315 and the lower end of the first pad pattern 323.

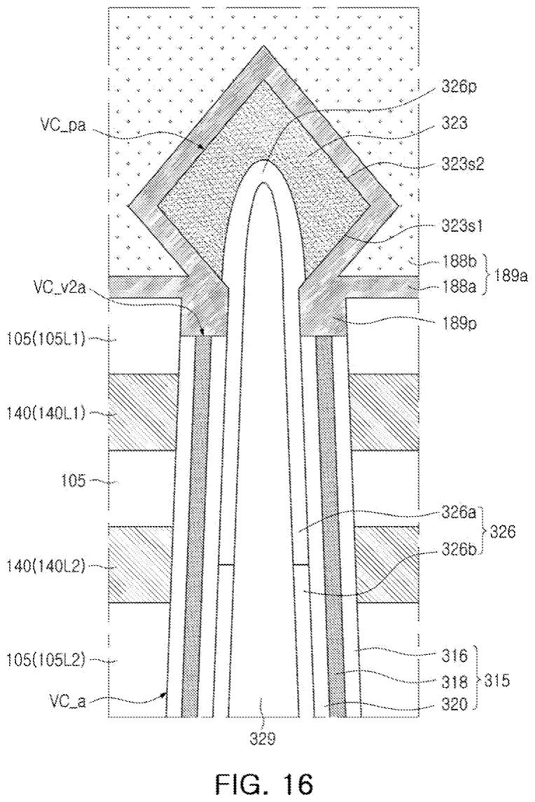

In the description below, modified examples of a semiconductor device will be described with reference to FIGS. 16 to 18.

Each of FIGS. 16 to 18 is an enlarged diagram illustrating a modified example of a semiconductor device, illustrating a portion of the semiconductor device, and corresponds to FIG. 15B.

In the modified example, referring to FIG. 16, the first conductive pattern 189a described with reference to FIG. 15B may further include an extension portion 189p extending to a region between the uppermost interlayer insulating layer 105L1 and the channel layer 326 and in contact with the channel layer 326. Since the first conductive pattern 189a including the extension portion 189p may increase the contact region of the channel layer 326 with the first doped region 326a, resistive properties may improve

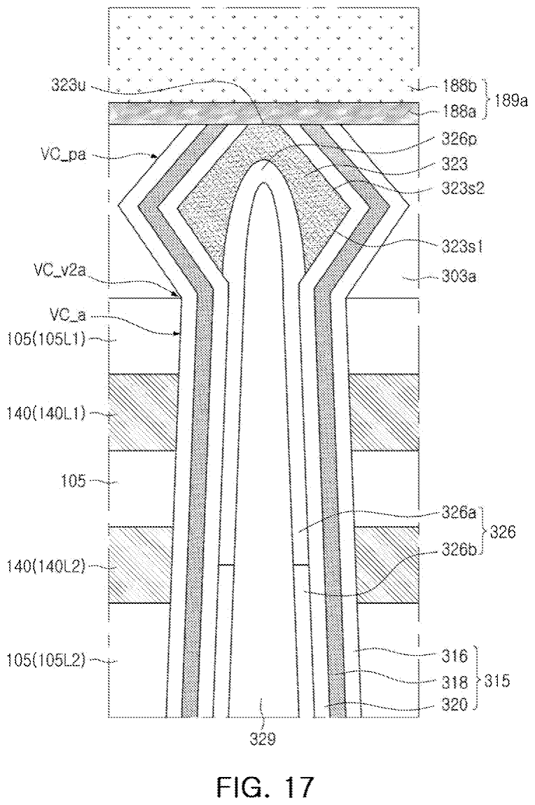

In the modified example, referring to FIG. 17, a buffer layer 303a may be between the uppermost interlayer insulating layer 105L1 and the first conductive pattern 189a. The buffer layer 303a may include the same material as that of the buffer layer 103a (in FIG. 3b) described with reference to FIG. 3B, and may work in substantially the same manner as the buffer layer 103a (in FIG. 3B) described with reference to FIG. 3B.

The first pad pattern 323 may include a first side surface 323s1 inclined such that the width of the first pad pattern 323 may increase upwardly, a second side surface 323s2 on a level higher than a level of the first side surface 323s1, extending from the first side surface 323s1 and inclined such that the width of the first pad pattern 323 may decrease upwardly, and a flat upper surface 323u extending from the upper end of the second side surface 323s2. The buffer layer 303a may surround the first and second side surfaces 323s1 and 323s2 of the first pad pattern 323. The dielectric structure 315 may extend to a region between the buffer layer 303a and the first pad pattern 323. Upper surfaces of the buffer layer 303a, the dielectric structure 315, and the first pad pattern 323 may be coplanar with each other.

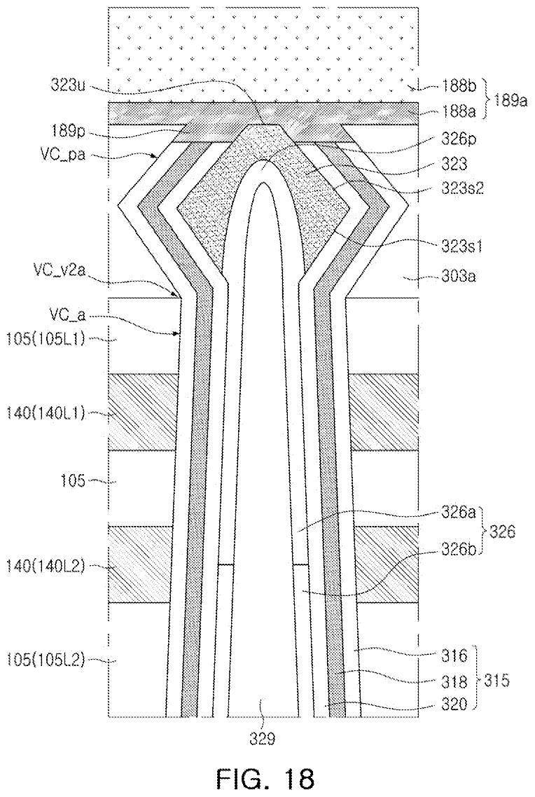

In the modified example, referring to FIG. 18, the first conductive pattern 189a in FIG. 17 may further include an extension portion 189p extending to a region between the buffer layer 303a and the second side surface 323s2 of the first pad pattern 323. Since the extension portion 189p of the first conductive pattern 189a may increase the contact region between the first conductive pattern 189a and the first pad pattern 323, resistive properties may improve.

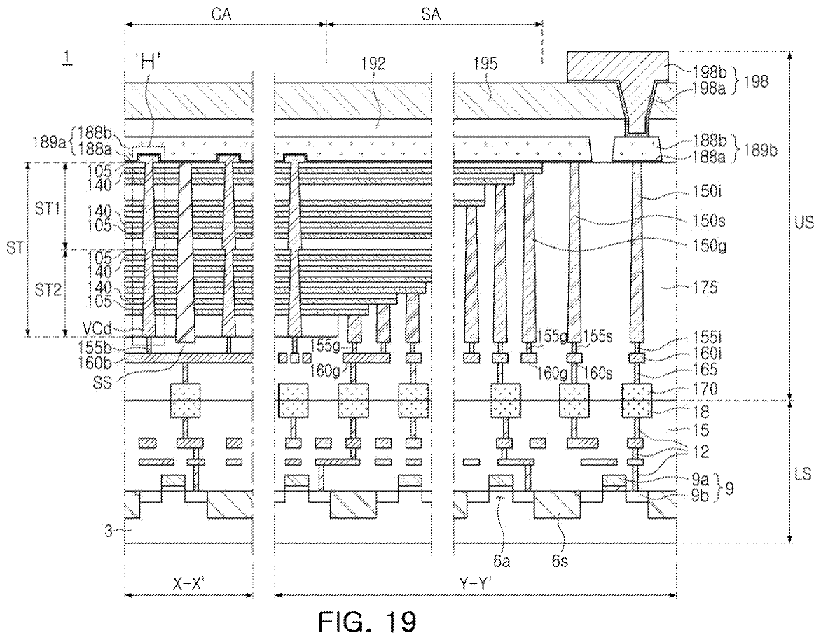

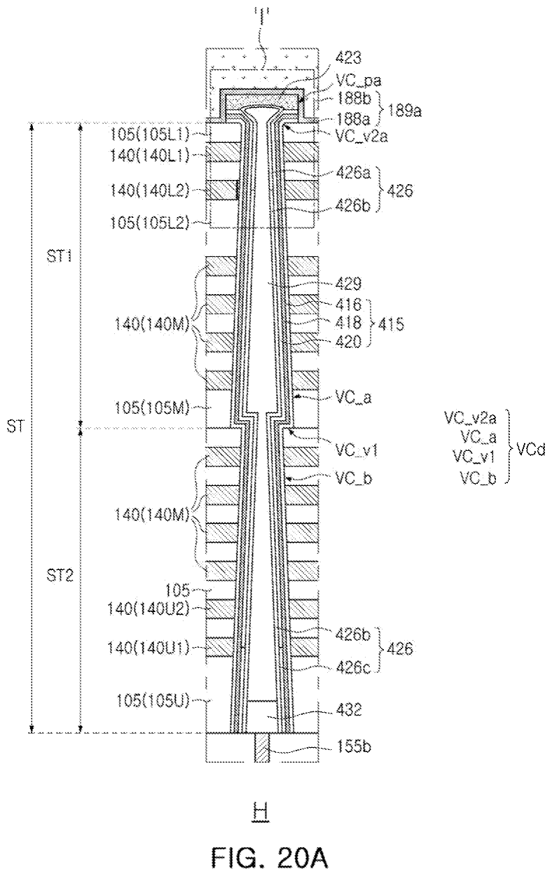

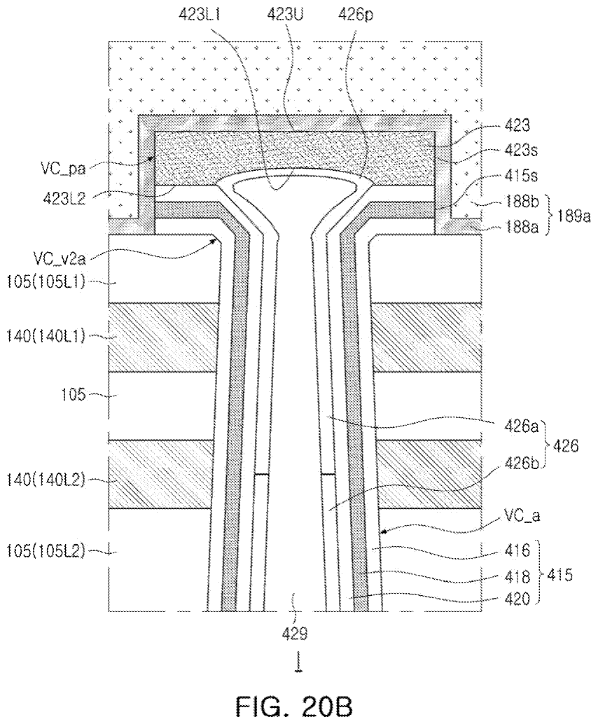

In the description below, a modified example of the semiconductor device will be described with reference to FIGS. 19, 20A, and 20B.

FIG. 19 is a cross-sectional diagram corresponding to FIG. 1 and illustrates a modified example of the vertical memory structure VCa in FIG. 1. FIG. 20A is an enlarged diagram illustrating region “H” in FIG. 19. FIG. 20B is an enlarged diagram illustrating region “I” in FIG. 20A.

In the modified example, referring to FIGS. 19, 20A, and 20B, the vertical memory structure VCa described with reference to FIGS. 1, 2A, and 2B may be modified into or replaced with a vertical memory structure VCd in FIGS. 19, 20A, and 20B.

The vertical memory structure VCd may include an insulating core region 429, a first pad pattern 423 on the insulating core region 429, a dielectric structure 415 on a side surface of the insulating core region 429 and a side surface of the first pad pattern, a channel layer 426 between the insulating core region 429 and the dielectric structure 415 and between the insulating core region 429 and the first pad pattern 423, and a second pad pattern 432 contacting the channel layer 426 below the insulating core region 429.

The dielectric structure 415 may include a first dielectric layer 416, a data storage layer 418, and a second dielectric layer 420 corresponding to the first dielectric layer 116, the data storage layer 118, and the second dielectric layer 120 of the dielectric structure 115 (in FIGS. 2A and 2B) described in the aforementioned example embodiment, respectively. The channel layer 426 may include a first doped region 426a, an undoped region 426b, and a second doped region 426c corresponding to the first doped region 126a, the undoped region 126b, and the second doped region 126c described with reference to FIG. 2B, respectively. In the modified example, the first doped region 426a may be modified to correspond to the first doped region 126a′ described with reference to FIG. 2C.

The structure of the vertical memory structure VCd penetrating through the second stack region ST2 may be substantially the same as the vertical memory structure VCa (in FIG. 2B) penetrating through the second stack region ST2 as in FIG. 2B.

The vertical memory structure VCd may include a lower vertical region VC_b penetrating through the second stack region ST2, an upper vertical region VC_a extending from the er vertical region VC_b and penetrating through the first stack region ST1, a protruding region VC_pa extending from the upper vertical region VC_a and on a level higher than a level of the upper surface of the stack structure ST, a first width change region VC_v1 between the lower vertical region VC_b and the upper vertical region VC_a, and a second width change region VC_2a between the upper vertical region VC_a and the protruding region VC_pa. The second width change region VC_2a may also be defined as a slope change region.

The insulating core region 429 may extend upwardly from a portion penetrating through the stack structure ST. The first pad pattern 423 may be on a level higher than a level of the uppermost interlayer insulating layer 105L1. The channel layer 426 may include a region 426p interposed between the insulating core region 429 and the first pad pattern 423 on a level higher than a level of the uppermost interlayer insulating layer 105L1.

The first pad pattern 423 may have a width greater than a width of a portion of the vertical memory structure VCd adjacent to the first pad pattern 423, and on the same level as a level of the uppermost interlayer insulating layer 105L1.

The dielectric structure 415 may include a portion extending from a portion penetrating through the uppermost interlayer insulating layer 105L1 to the upper surface of the uppermost interlayer insulating layer 105L1, and interposed between the first pad pattern 423 and the uppermost interlayer insulating layer 105L1.

The dielectric structure 415 may include a side surface 415s contacting the first conductive pattern 189a on a level higher than a level of the uppermost interlayer insulating layer 105L1. An end portion of the first dielectric layer 416, an end portion of the data storage layer 418, and an end portion of the second dielectric layer 420 may be on the side surface 415s of the dielectric structure 415.

The first pad pattern 423 may include a side surface 423s, an upper surface 423U, and lower surfaces 423L1 and 423L2. In the first pad pattern 423, the lower surfaces 423L1 and 423L2 may include a first lower surface 423L1 contacting the channel layer 426 and a second lower surface 423L2 contacting the second dielectric layer 420 of the dielectric structure 415. The first lower surface 423L1 may extend from the second lower surface 423L2 and may have a concave shape. For example, the first lower surface 423L1 may have a curved shape, and an upper end of the first lower surface 423L1 may be on a level higher than a level of the second lower surface 423L2.

The side surface 415s of the dielectric structure 415 may be aligned with the side surface 423s of the first pad pattern 423.

The first conductive pattern 189a may contact the side surface 415s of the dielectric structure 415, the side surface 423s of the first pad pattern 423 and the upper surface 423U.

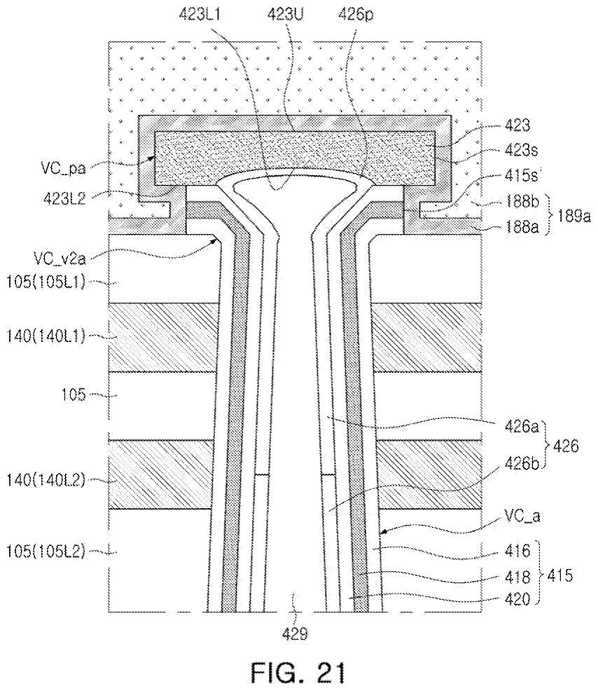

In the description below, modified examples of the semiconductor device in will be described with reference to FIGS. 21 to 24.

Each of FIGS. 21 to 24 is an enlarged diagram illustrating a modified example of a semiconductor device, illustrating a portion of the semiconductor device, and corresponds to FIG. 20B.

In the modified example, referring to FIG. 21, the side surface 415s (in FIG. 20B) of the dielectric structure 415 in FIG. 20B may be modified into a side surface 415s′ not aligned with the side surface 423s of the first pad pattern 423 and below the second lower surface 423L2 of the first pad pattern 423. The first conductive pattern 189a may extend to a region between the second lower surface 423L2 of the first pad pattern 423 and the upper surface of the uppermost interlayer insulating layer 105L1, and may contact the second lower surface 423L2 of the first pad pattern 423.

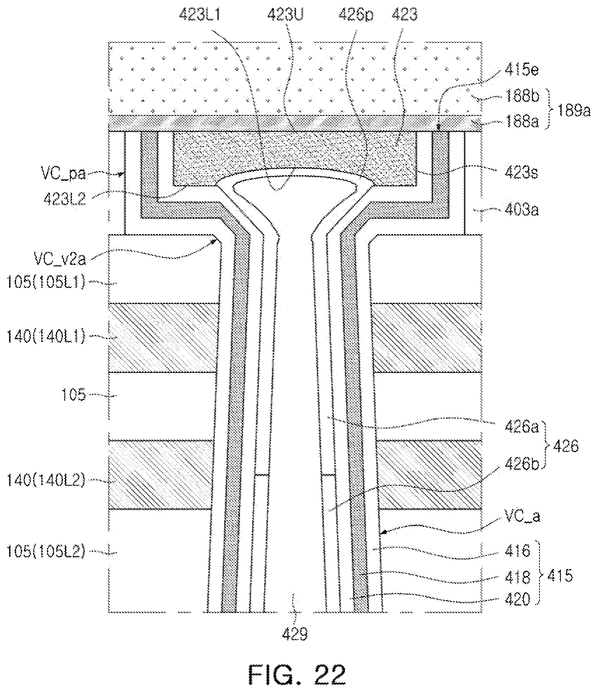

In the modified example, referring to FIG. 22, a buffer layer 403a may be between the uppermost interlayer insulating layer 105L1 and the first conductive pattern 189a. The buffer layer 403a may include the same material as that of the buffer layer 103a (in FIG. 3B) described with reference to FIG. 3B, and may work in substantially the same manner as the buffer layer 103a (in FIG. 3B) described with reference to FIG. 3B.

The buffer layer 303a may surround the side surface 423s of the first pad pattern 423. The dielectric structure 415 may cover the second lower surface 423L2 of the first pad pattern 423, and may extend to a region between the buffer layer 403a and the first pad pattern 423. An end portion of the first dielectric layer 416, an end portion of the data storage layer 418, and an end portion of the second dielectric layer 420 may be on an upper surface 415e of the dielectric structure 415.

Upper surfaces of the buffer layer 403a, the dielectric structure 415, and the first pad pattern 423 may be coplanar with each other. Upper surfaces of the buffer layer 403a, the dielectric structure 415, and the first pad pattern 423 may contact the first conductive pattern 189a.

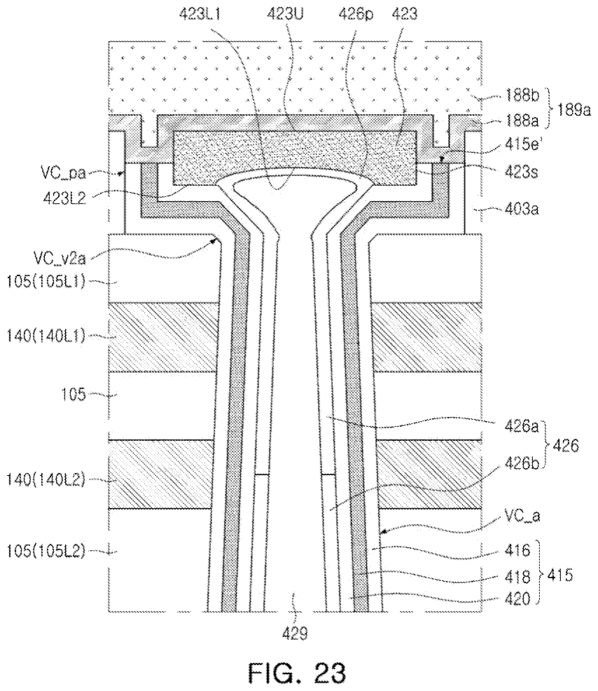

In the modified example, referring to FIG. 23, the upper surface 415e (in FIG. 22) of the dielectric structure 415 in FIG. 22 may be modified into an upper surface 415e′ on a level lower than a level of the upper surfaces of the first pad pattern 423 and the buffer layer 403a. Accordingly, the first conductive pattern 189a may be modified to be in contact with the side surface 423s of the first pad pattern 423.

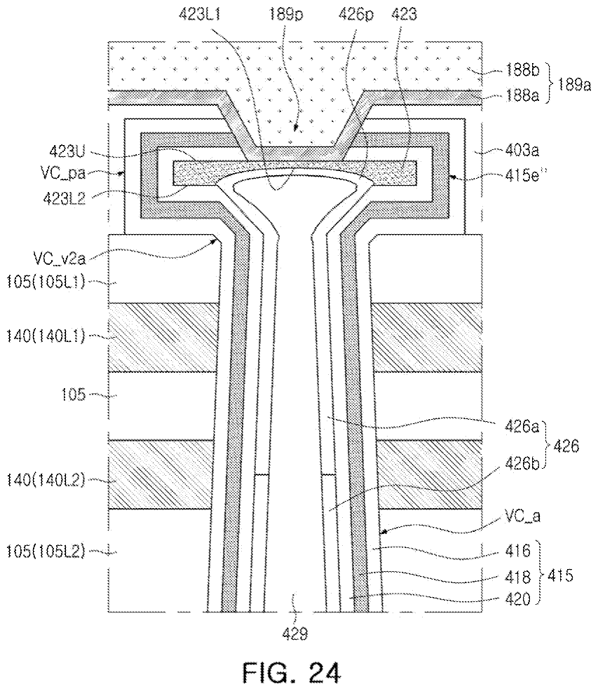

In the modified example, referring to FIG. 24, the buffer layer 403a in FIG. 22 may be modified to cover a portion of the upper surface of the first pad pattern 423, and the dielectric structure 415 may be modified to be interposed between the upper surface of the first pad pattern 423 and the buffer layer 403a. For example, a portion 415e″ of the dielectric structure 415 may contact a portion of the lower surface of the first pad pattern 423, a side surface of the first pad pattern 423, and a portion of the upper surface of the first pad pattern 423 on a level higher than a level of the uppermost interlayer insulating layer 105L1. The first conductive pattern 189a may penetrate the buffer layer 403a and the dielectric structure 415 on the first pad pattern 423, and may contact the first pad pattern 423.

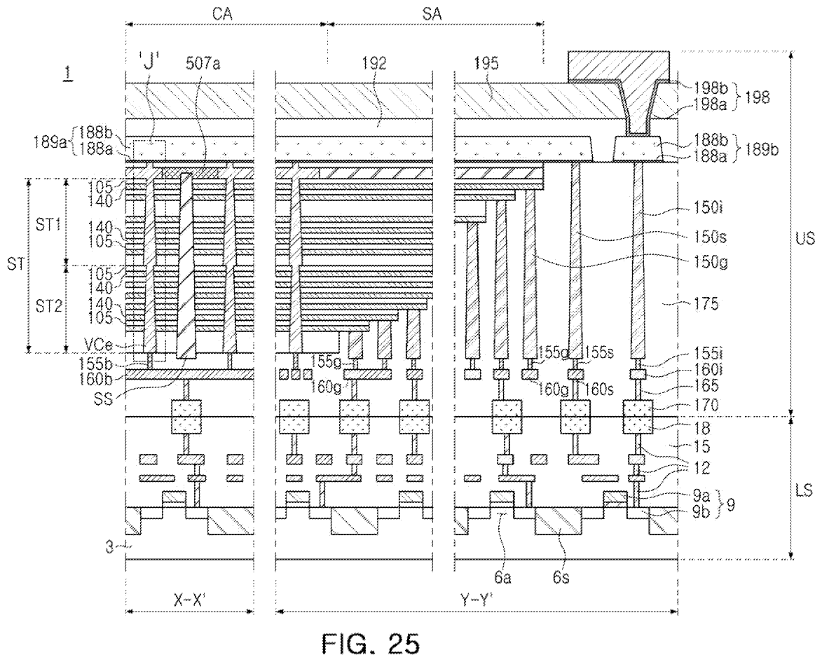

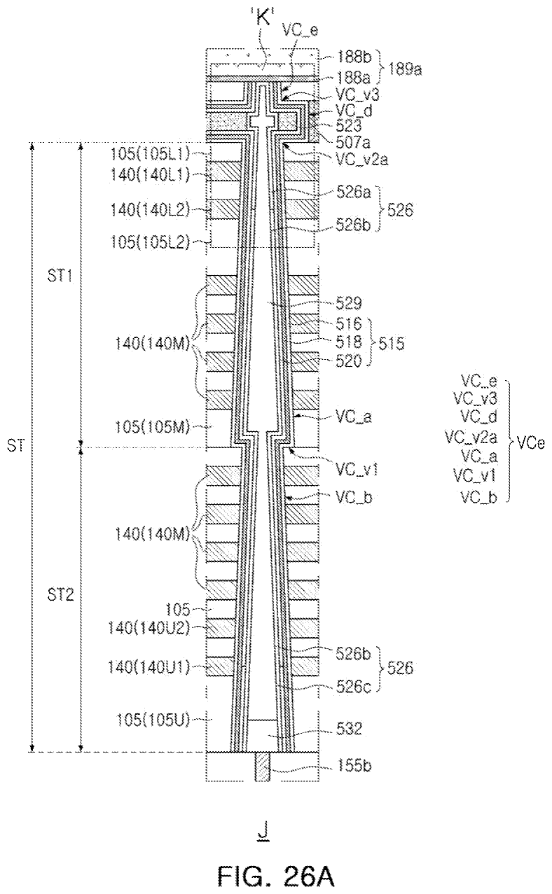

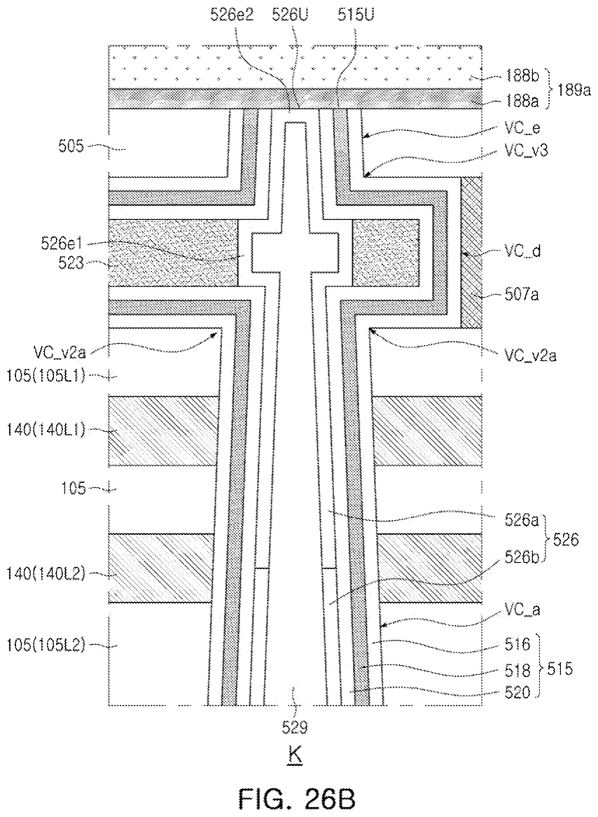

In the description below, a modified example of the semiconductor device will be described with reference to FIGS. 25, 26A, and 26B.

FIG. 25 is a cross-sectional diagram corresponding to FIG. 1, illustrating a modified example of the vertical memory structure VCa in FIG. 1. FIG. 26A is an enlarged diagram illustrating region “J” in FIG. 25. FIG. 26B is an enlarged diagram illustrating region “K” in FIG. 26A.

In the modified example, referring to FIGS. 25, 26A, and 26B, the vertical memory structure VCa described with reference to FIGS. 1, 2A, and 2B may be modified into or replaced with a vertical memory structure VCe in FIGS. 25, 26A, and 26B.

The vertical memory structure VCe may include an insulating core region 529 penetrating through the stack structure ST and extending upwardly, a first pad pattern 523 on the side surface of the insulating core region 529 on a level higher than a level of the stack structure ST and on a level lower than a level of the upper surface of the insulating core region 529, a channel layer 526 covering the side surface of the insulating core region 529 and the upper surface of the insulating core region 529, and a first pad pattern 523 between the dielectric structure 515 and the channel layer 526 on a level higher than a level of the stack structure ST.

The dielectric structure 515 may include a first dielectric layer 516, a data storage layer 518, and a second dielectric layer 520 corresponding to the first dielectric layer 516, the data storage layer 118, and the second dielectric layer 120 of the dielectric structure 115 (in FIGS. 2A and 2B) described in the aforementioned example embodiment, respectively. The channel layer 526 may include a first doped region 526a, an undoped region 526b, and a second doped region 526c corresponding to the first doped region 126a, the undoped region 126b, and the second doped region 126c described with reference to FIG. 2B, respectively. In the modified example, the first doped region 526a may be modified to correspond to the first doped region 126a′ described with reference to FIG. 2C.

The structure of the vertical memory structure VCd penetrating through the second stack region ST2 may be substantially the same as the vertical memory structure VCa (in FIG. 2B) penetrating through the second stack region ST2 as in FIG. 2B.

The vertical memory structure VCd may include a lower vertical region VC_b penetrating through the second stack region ST2, an upper vertical region VC_a extending from the lower vertical region VC_b and penetrating through the first stack region ST1, a first protruding region VC_d extending from the upper vertical region VC_a on a level higher than a level of the upper surface of the stack structure ST, a first width change region VC_v1 between the lower vertical region VC_b and the upper vertical region VC_a, a second width change region VC_v2a between the upper vertical region VC_a and the first protruding region VC_d, and a third width change region VC_v3 between the first protruding region VC_d and a second protruding region VC_e.

The insulating core region 529 may extend upwardly from a portion penetrating through the stack structure ST. The first pad pattern 523 may be on a level higher than a level of the uppermost interlayer insulating layer 105L1. The channel layer 526 may include a first region 526e1 interposed between the insulating core region 529 and the first pad pattern 5623 on a level higher than a level of the uppermost interlayer insulating layer 105L1, and a second region 526e2 extending from the first region 526e1 and covering an upper surface and a side surface of the insulating core region 529. The first pad pattern 523 may surround an external side surface of the first region 526e1 of the channel layer 526.

The insulating core region 529 may have a shape in which a width thereof may increase on a level between an upper surface and a lower surface of the first pad pattern 523.

An upper surface, a lower surface, and an external side surface of the first pad pattern 523 may contact the second dielectric layer 520 of the dielectric structure 513, and an internal side surface of the first pad pattern 523 may contact the channel layer 526.

The semiconductor device 1 according to an example embodiment may further include a first buffer layer 507a on the uppermost interlayer insulating layer 105L1 and covering a side surface of the first protruding region VC_d of the vertical memory structure VCe. The first buffer layer 507a may be formed of a silicon layer or, e.g., an insulating material. The first buffer layer 507a may contact the separation structure SS.

The semiconductor device 1 according to an example embodiment may further include a second buffer layer 505 on the first protruding region VC_d and the first buffer layer 507a ,and covering the side surface of the second protruding region VC_e. The second buffer layer 505 may include an insulating material, e.g., silicon oxide.

The first conductive pattern 189a may contact an upper surface of the second buffer layer 505, an upper surface 515U of the dielectric structure 515, and an upper surface 526U of the channel layer 526. The upper surface of the second buffer layer 505, the upper surface 515U of the dielectric structure 515, and the upper surface 526U of the channel layer 526 may be coplanar with each other.

An end portion of the first dielectric layer 516, an end portion of the data storage layer 518, and an end portion of the second dielectric layer 520 may be on the upper surface 515U of the dielectric structure 515.

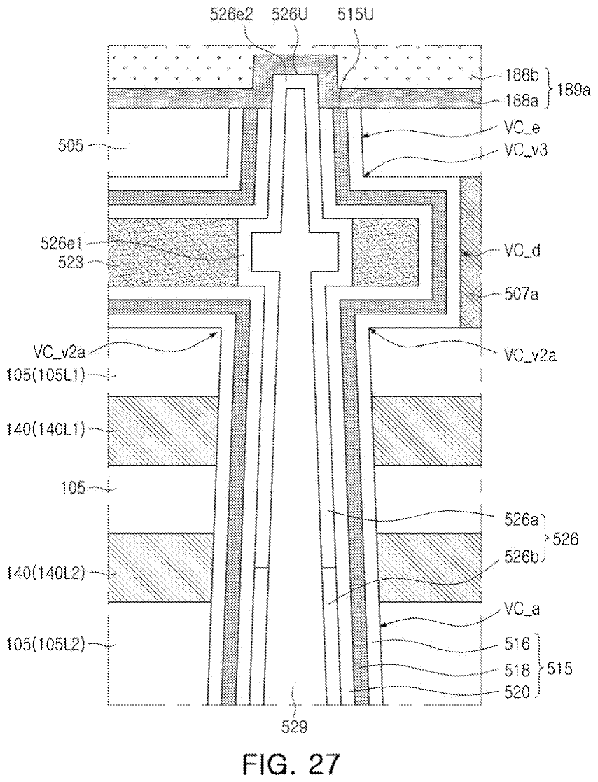

In the description below, modified examples of a semiconductor device will be described with reference to FIGS. 27 to 29.

Each of FIGS. 27 to 29 is an enlarged diagram illustrating a modified example of a semiconductor device, illustrating a portion of the semiconductor device, and corresponds to FIG. 26B.

In the modified example, referring to FIG. 27, the insulating core region 529 and the channel layer 526 may protrude upwardly. Accordingly, the first doped region 526a of the channel layer 526 may include a portion on a level higher than a level of the second buffer layer 505 and the upper surface 515U of the dielectric structure 515. The first conductive pattern 189a may cover and contact the upper surface and the external side surface of the first doped region 526a of the channel layer 526 on a level higher than a level of the second buffer layer 505 and the upper surface 515U of the dielectric structure 515.

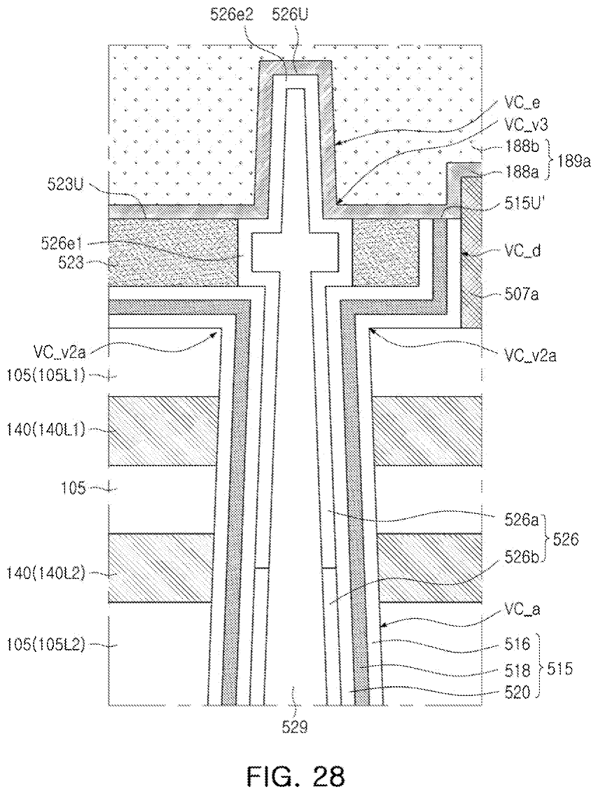

In the modified example, referring to FIG. 28, the second buffer layer 505 (in FIG. 26B) may not be provided. The upper surface 515U′ of the dielectric structure 515 may be on a level higher than a level of the lower surface of the first pad pattern 523, and may be on the same level as a level of an upper surface 523U of the first pad pattern 523 or on a level lower than a level of the upper surface 523U of the first pad pattern 523.

The first conductive pattern 189a may contact the upper surface 523U of the first pad pattern 523 and the upper surface and the external side surface of the first doped region 526a of the channel layer 526 on a level higher than a level of the first pad pattern 523.

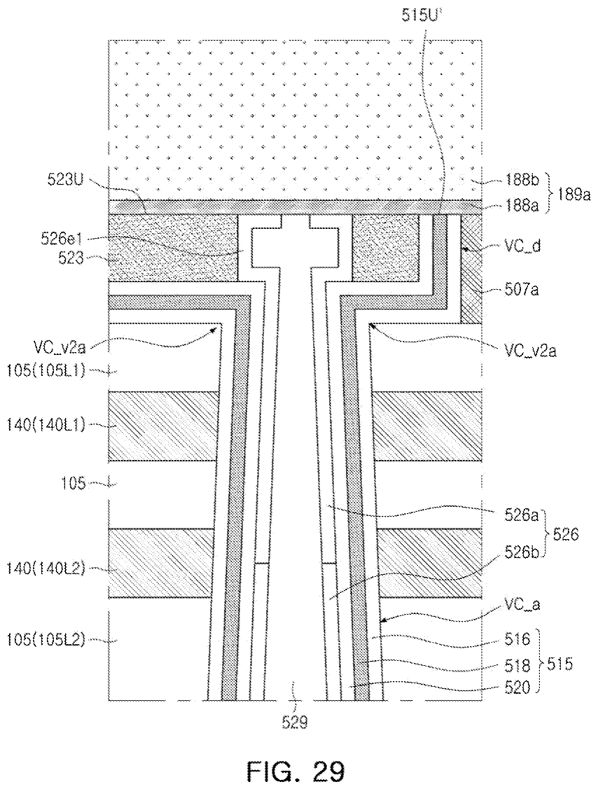

In the modified example, referring to FIG. 29, the second buffer layer 505 (in FIG. 26B) may not be provided. The upper surface 515U′ of the dielectric structure 515 may be on a level higher than a level of the lower surface of the first pad pattern 523, and may be on substantially the same level as a level of the upper surface 523U of the first pad pattern 523. The upper surface of the insulating core region 529 may be on the on the same level as a level of upper surface 523U of the first pad pattern 523. The upper end of the first doped region 526a of the channel layer 526 may be on substantially the same level as a level of the upper surface 523U of the first pad pattern 523. Accordingly, the first conductive pattern 189a may contact the upper surface 523U of the first pad pattern 523, the upper surface of the insulating core region 529, and the upper end of the first doped region 526a of the channel layer 526.

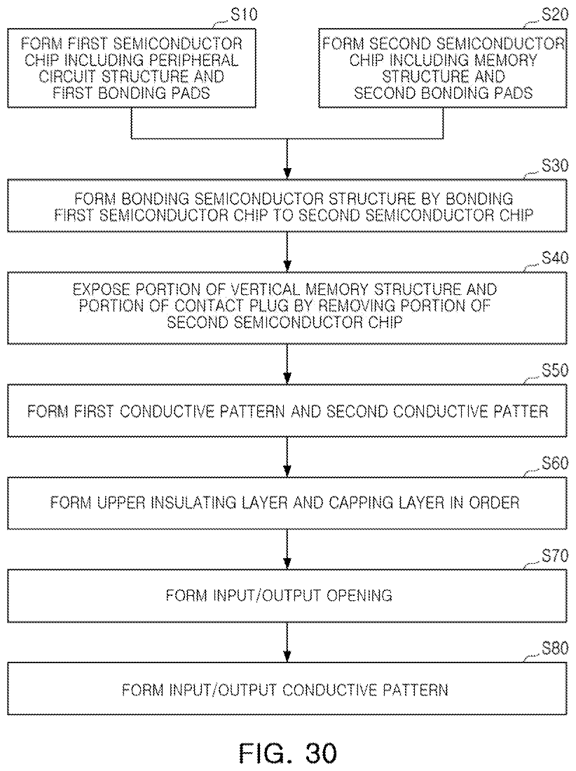

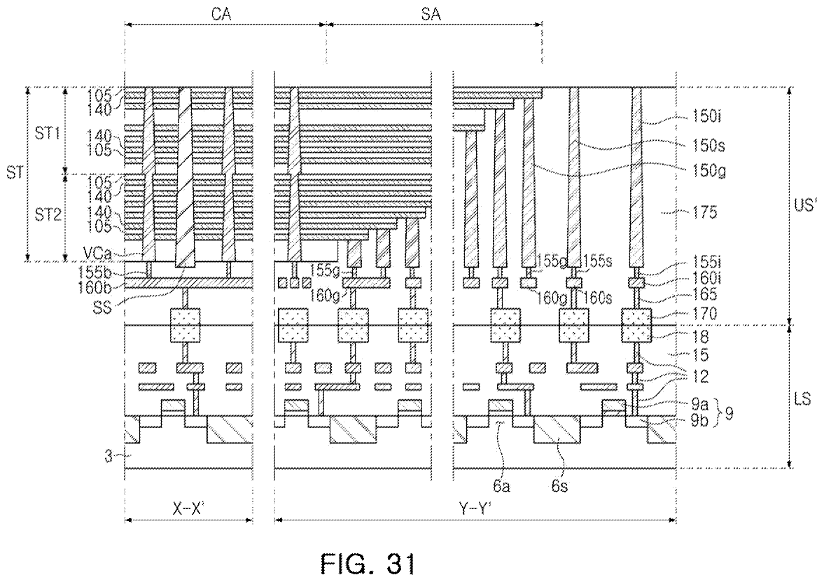

Hereinafter, a method of forming a semiconductor device according to an example embodiment will be described with reference to FIGS. 30 and 31 along with FIG. 1.

FIG. 30 is a flowchart illustrating processes of a method of forming a semiconductor device according to an example embodiment. FIG. 31 is a cross-sectional diagram illustrating a method of forming a semiconductor device according to an example embodiment.

Referring to FIGS. 30 and 31 together with FIG. 1, a first semiconductor chip LS including peripheral circuit structures 9 and 12 and first bonding pads 18 may be formed (S10). The first semiconductor chip LS may be the lower structure LS described in the aforementioned example embodiments. For example, the forming the first semiconductor chip LS may include forming a device isolation region 6s defining an active region 6a on a substrate 3, forming peripheral circuit structures 9 and 12 including a peripheral wiring structure 12 and a lower insulating structure 15 on the substrate 3, and forming first bonding pads 18 embedded in the lower insulating structure 15.

A second semiconductor chip including a memory structure and second bonding pads 170 may be formed (S20). The memory structure may include a stack structure ST including gate layers 140 and interlayer insulating layers 105 alternately stacked, and vertical memory structures VCa penetrating through the stack structure ST.

The second semiconductor chip may include an upper insulating structure 175, contact plugs 150g, 150s, and 150i, the studs 155b, 155g, 155s, and 155i, interconnections 160b, 160g, 160s, and 160i, and a connection structure 165, as described in the aforementioned example embodiments. The second bonding pads 170 may be embedded in the upper insulating structure 175, and may have a surface coplanar with the surface of the upper insulating structure 175.

A bonding semiconductor structure may be formed by bonding the first semiconductor chip to the second semiconductor chip (S30).

A portion of the vertical memory structure VCa and a portion of the contact plugs may be exposed by removing a portion of the second semiconductor chip (S40). The contact plugs may be the source contact plug 150s and the input/output contact plug 150i described above. Accordingly, a second semiconductor chip US′ from which a portion thereof is removed may be formed on the first semiconductor chip LS. As a portion of the vertical memory structure VCa and a portion of the contact plug are exposed, the upper insulating structure 175 around the stack structure ST may be exposed.

A first conductive pattern 189a and a second conductive pattern 189b may be formed (S50). An upper insulating layer 192 and a capping insulating layer 195 may be formed in order (S70). An input/output opening may be formed (S80). The input/output opening may penetrate the capping insulating layer 195 and the upper insulating layer 192 in order, and may expose the second conductive pattern 189b. A conductive input/output pattern 198 may be formed (S80). The input/output conductive pattern 198 may include a portion filling the input/output opening and on the capping insulating layer 195.

Each of the vertical memory structures VCa may be the vertical memory structure described with reference to FIGS. 1 to 2B, and may also be one of the vertical memory structures described with reference to FIGS. 2C to 29.

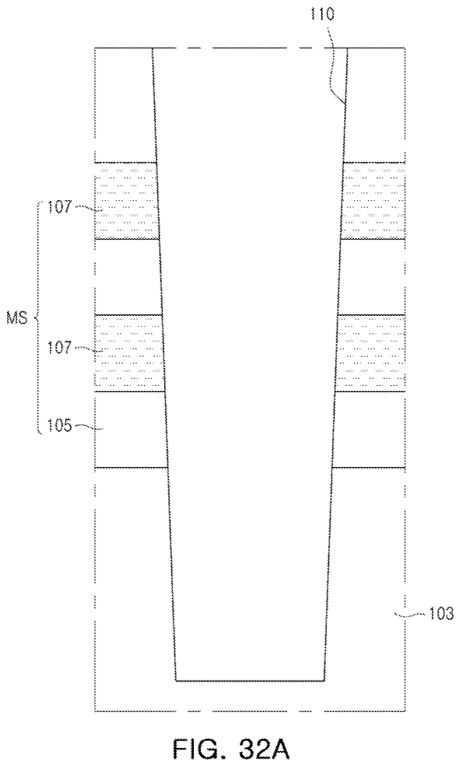

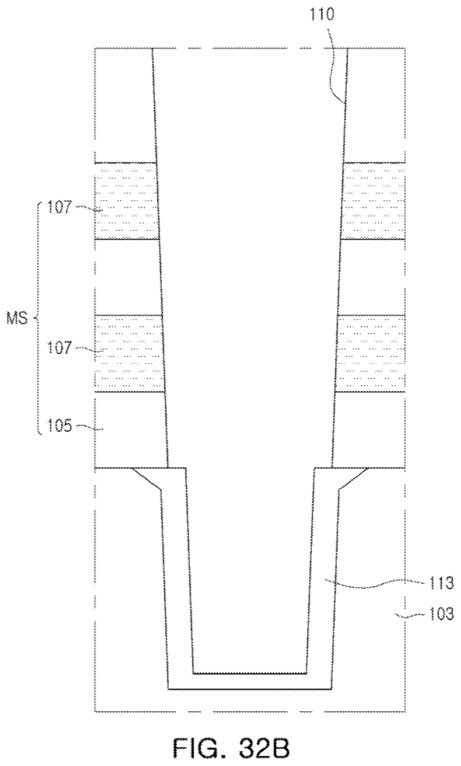

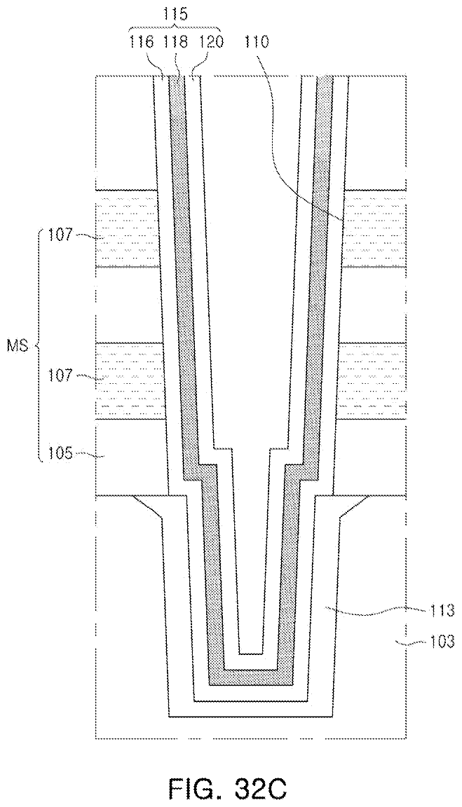

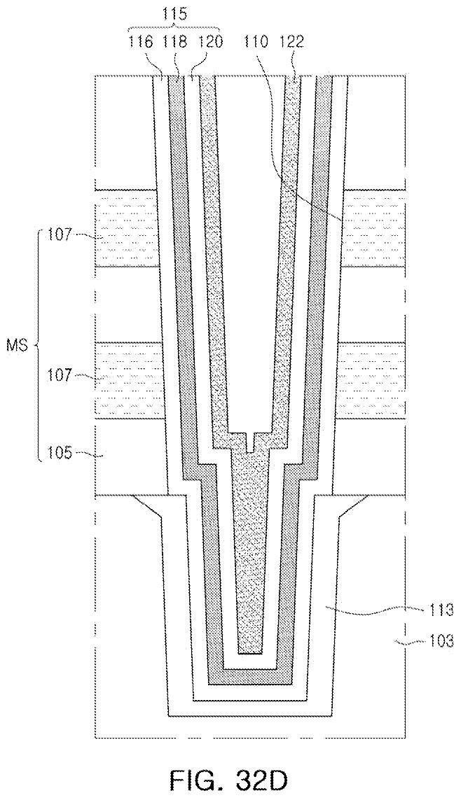

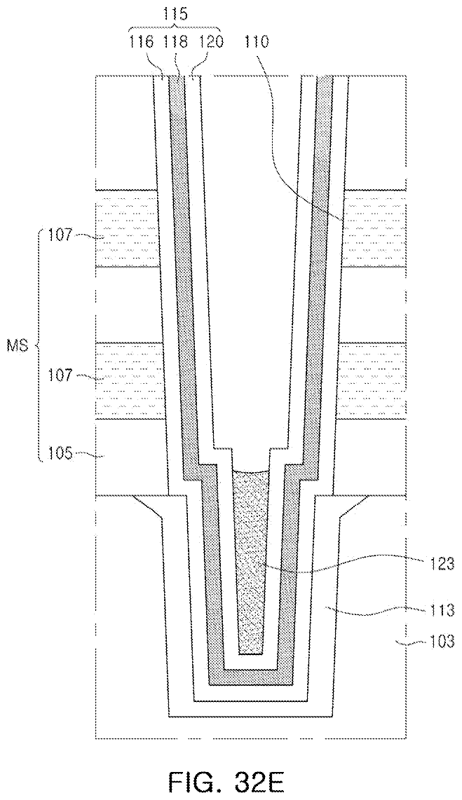

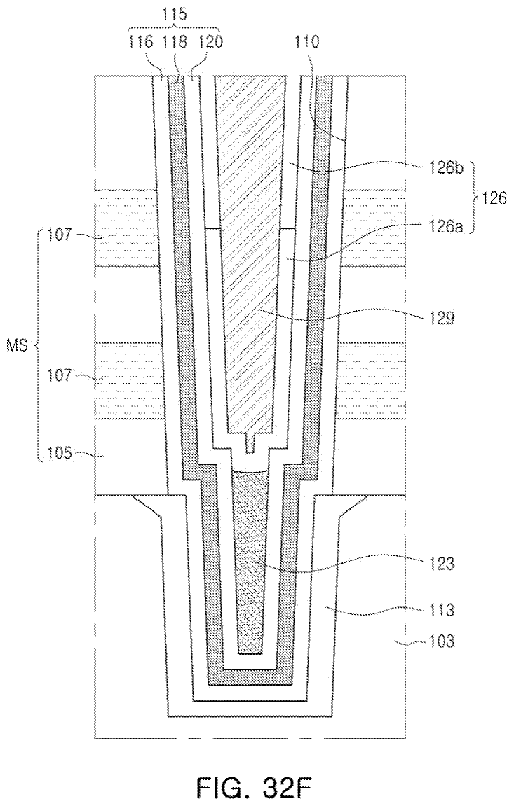

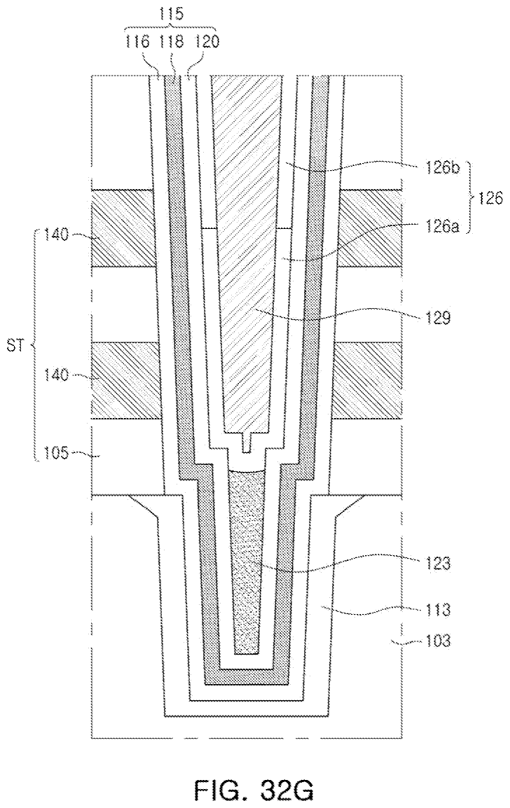

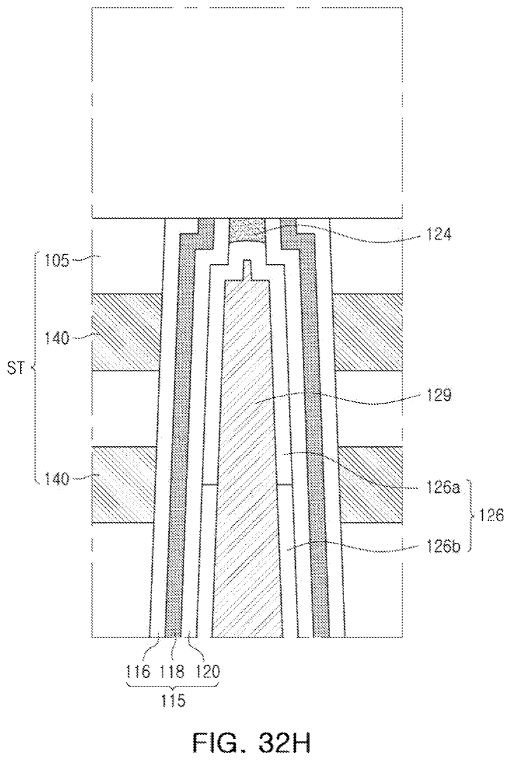

In the description below, examples of a method of forming the vertical memory structures described with reference to FIGS. 1 to 29 will be described with reference to FIGS. 32A to 37F along with FIGS. 30 and 31.

FIGS. 32A to 37F are enlarged cross-sectional diagrams illustrating portions of the vertical memory structures.

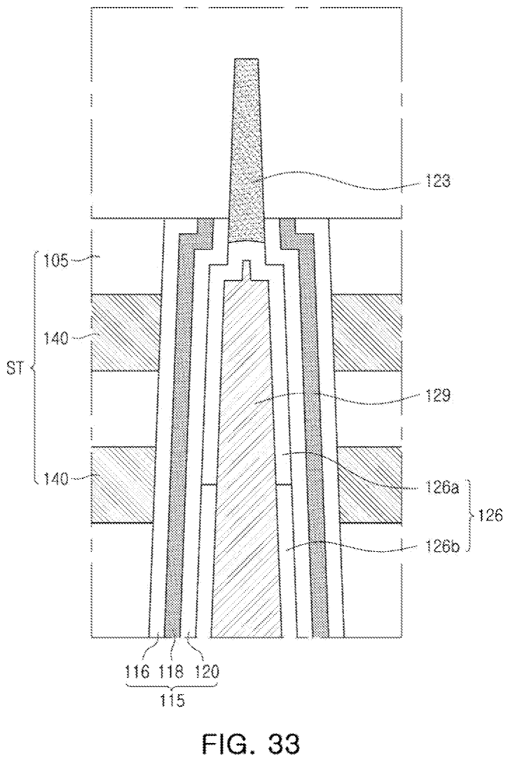

First, a method of forming the vertical memory structure VCa described with reference to FIGS. 1 to 2B and a modified example of the vertical memory structure VCa will be described with reference to FIGS. 32A to 32H and 33.

Referring to FIG. 32A, a mold structure MS may be formed on the semiconductor substrate 103. The mold structure MS may include interlayer insulating layers 105 and mold layers 107 alternately stacked. The mold layers 107 may be configured to replace the gate layers 140 in FIGS. 1 and 2A, may be formed in the same position as that of the gate layers 140 (in FIGS. 1 and 2), and may be formed in the same shape as that of the gate layers 140 (in FIGS. 1 and 2). The mold structure MS may have substantially the same shape as that of the stack structure ST (in FIG. 1). A channel hole 110 may be formed to penetrate through the mold structure MS and extend into the semiconductor substrate 103.

The shape of the side surface of the channel hole 110 in the portion penetrating through the mold structure MS may be substantially the same as the shape of the side surface of the vertical memory structure VCa (FIGS. 1 and 2A) in a portion penetrating through the stack structure ST (in FIG. 2A).

Referring to FIG. 32B, a silicon oxide layer 113 may be formed by thermally oxidizing the semiconductor substrate 103 exposed by the channel hole 110. A width of the channel hole 110 in the semiconductor substrate 103 may decrease by the silicon oxide layer 113.

Referring to FIG. 32C, a dielectric structure 115 may be formed in the channel hole 110 in which the silicon oxide layer 113 is formed. The forming the dielectric structure 115 may include conformally forming the first dielectric layer 116, the data storage layer 118, and the second dielectric layer 120 in order.

Referring to FIG. 32D , a doped polysilicon layer 122 including impurities may be formed in the channel hole 110. The doped polysilicon layer 122 may have an N-type conductivity. The doped polysilicon layer 122 may be formed through an in-situ process. Since the channel hole 110 positioned in the semiconductor substrate 103 is narrowed by the silicon oxide layer 113, the doped polysilicon layer 122 formed on the dielectric structure 115 on the semiconductor substrate (103) may fill the channel hole 110 where it is located in and passes through the lowermost interlayer insulating layer (corresponding to the uppermost interlayer insulating layer in FIG. 2A) of the interlayer insulating layers 105), e.g., a portion of the channel hole 110 may be fully filled.

Referring to FIG. 32E, a first pad pattern 123 may be formed by partially etching the doped polysilicon layer 122. The first pad pattern 123 may fill the channel hole 110 in the semiconductor substrate 103 on the dielectric structure 115, and may fill at least a portion of the channel hole 110 penetrating through the lowermost interlayer insulating layer (corresponding to the uppermost interlayer insulating layer in FIG. 2A).

Referring to FIGS. 31 and 32F, a channel layer 126 may be formed to conformally cover the other portion of the channel hole 110 on the first pad pattern 123 and the dielectric structure 115, an insulating core region 129 may be formed to partially fill the channel hole 110 on the channel layer 126, and a second pad pattern 132 (in FIG. 2A) may be formed to contact the channel layer 126 on the insulating core region 129. The channel layer 126 may be formed of an undoped silicon layer. The second pad pattern 132 in FIG. 2A may be formed of the same material as that of the first pad pattern 123, e.g., doped polysilicon.

A heat treatment process may be performed to diffuse impurities in the first pad pattern 123 and the second pad pattern 132 (in FIG. 2A) into the channel layer 126. Accordingly, impurities may be diffused from the first pad pattern 123 into the channel layer 126, such that impurities may be diffused from the first doped region 126a having an N-type conductivity and the second pad pattern 132 (in FIG. 2A), thereby forming the second doped region 126c (in FIG. 2A) having an N-type conductivity. A region of the channel layer 126 in which impurities are not diffused may be defined as an undoped region 126b.

An upper insulating structure covering the mold structure MS may be formed on the semiconductor substrate 103.

Referring to FIGS. 31 and 32G, an isolation trench penetrating at least the mold structure MS may be formed to expose the mold layers 107 (in FIG. 32F). Empty spaces may be formed by removing the mold layers 107 (in FIG. 32F), the gate layers 140 (in FIGS. 31 and 32G) described above may be formed in the empty spaces. The separation structure SS filling the isolation trench may be formed. Accordingly, a stack structure ST including the gate layers 140 and the interlayer insulating layers 105 may be formed.

Thereafter, the contact plugs 150g, 150s, and 150i, the studs 155b, 155g, 155s, and 155i, the interconnections 160b, 160g, 160s, and 160i, the connection structure 165 and the second bonding pads 170 described in the aforementioned example embodiment with reference to FIG. 31 may be formed together with the upper insulating structure 175. The structure formed up to the second bonding pads 170 and the upper insulating structure 175 may be a second semiconductor chip including the memory structure and the second bonding pads described in process S20 in FIG. 30.

Thereafter, as described with reference to FIG. 30, a bonding semiconductor structure may be formed by bonding the first semiconductor chip to the second semiconductor chip (S30). In the bonding semiconductor structure, the semiconductor substrate 103 (in FIG. 32G) may be exposed.

Referring to FIGS. 31 and 32H, the process of exposing a portion of the vertical memory structure VCa and a portion of the contact plug by removing a portion of the second semiconductor chip described with reference to FIG. 30 (S40) may include forming the first pad pattern 124 defined in the stack structure ST by removing the semiconductor substrate 103 (in FIG. 32G) and the silicon oxide layer 113 from the bonding semiconductor structure and removing a portion of the first pad pattern 123 on a level higher than a level of the stack structure ST. In this process, the dielectric structure 115 and the channel layer 126 on a level higher than a level of the stack structure ST may also be removed. As the semiconductor substrate 103 (in FIG. 32G) is removed, the source and input/output contact plugs 150s and 150i in FIG. 31 may be exposed.

Thereafter, the first and second conductive patterns 189a and 189b, the upper insulating layer 192, the capping insulating layer 195, and the input/output pattern 198 as in FIG. 1 may be formed in order.

In the modified example, referring to FIG. 33, in the process of exposing a portion of the vertical memory structure VCa and a portion of the contact plug by removing a portion of the second semiconductor chip described with reference to FIG. 30 (S40), the dielectric structure 115 and the channel layer on a level higher than a level of the stack structure ST may be removed while removing the semiconductor substrate 103 (in FIG. 32G), and the silicon oxide layer 113, and the first pad pattern 123 may remain. Accordingly, the first pad pattern 123 described with reference to FIG. 3A may be formed.

In another example, a buffer layer may be formed by allowing a portion of the semiconductor substrate 103 to remain (in FIG. 32G).

In another example, after the first pad pattern 123 or 124 is formed, the dielectric structure 115 may be partially etched to expose a portion of a side surface of the first pad pattern 123 or 124.

According to an example embodiment, before performing the process of forming the bonding semiconductor structure by bonding the first semiconductor chip to the second semiconductor chip (S30 in FIG. 30), the memory structure of the second semiconductor chip may include the vertical memory structure VCa including the channel layer 126, the first pad pattern 123 contacting the upper region of the channel layer 126, supplying impurities to the upper region of the channel layer 126 and forming the upper region of the channel layer 126 as the first doped region 126a (in FIG. 32F), and the second pad pattern 132 contacting the lower region of the channel layer 126, supplying impurities to the lower region of the channel layer 126 and forming the lower region of the channel layer 126 as the second doped region 126c.

Since the second semiconductor chip including the vertical memory structure VCa is bonded to the first semiconductor chip, after the process of forming the bonding semiconductor structure (S30 in FIG. 30), an ion implantation process for doping the channel layer 126 and a heat treatment process for diffusing impurities may not be performed.

Accordingly, degradation of performance of the semiconductor device 1 (due to the heat treatment process performed after forming the bonding semiconductor structure) may be prevented. For example, degradation of performance of the semiconductor device 1 (due to a heat treatment process performed after forming the bonding semiconductor structure, e.g., defects due to a subsequent thermal process in a portion in which the first bonding pads 18 and second bonding pads 170 are bonded) may be prevented.

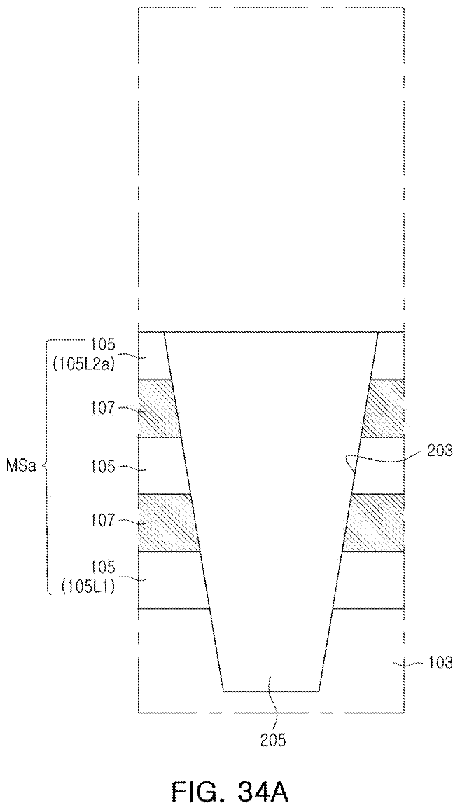

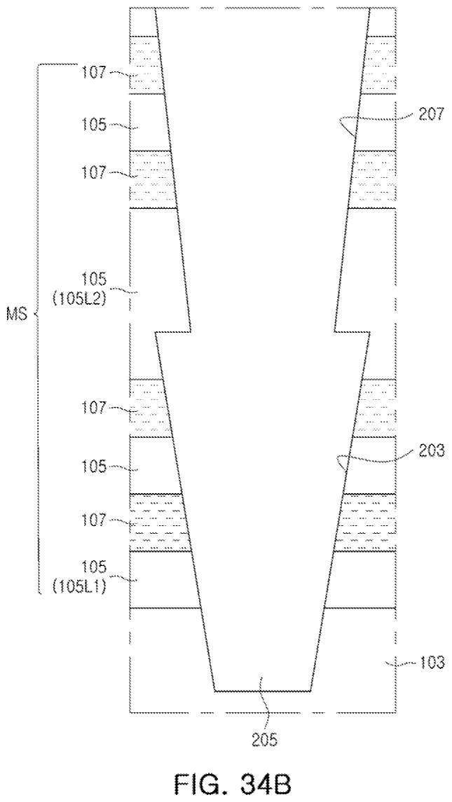

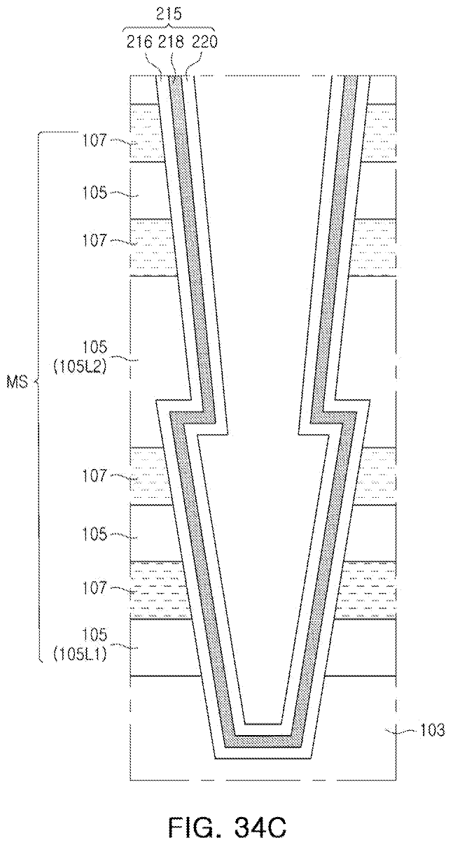

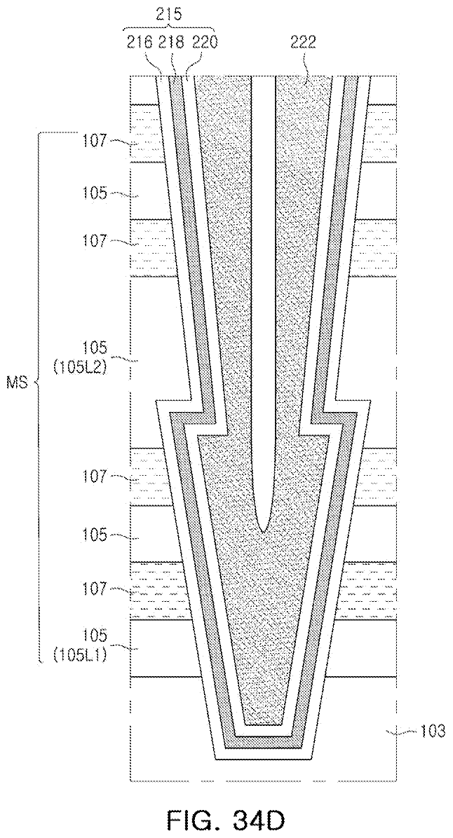

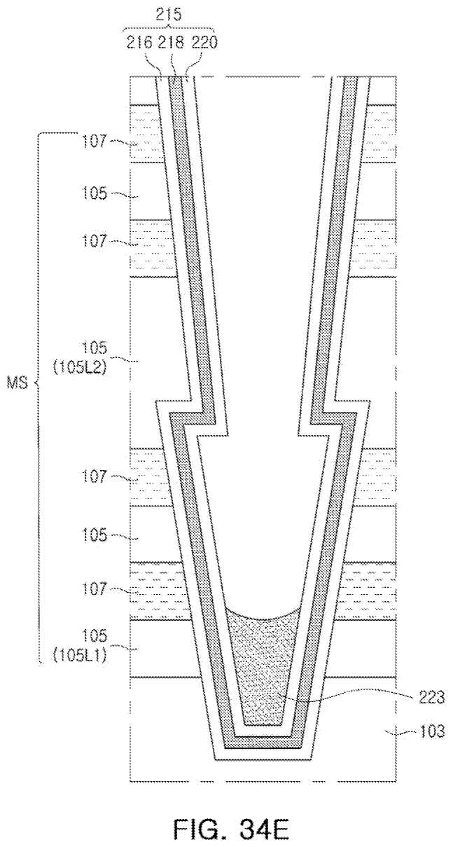

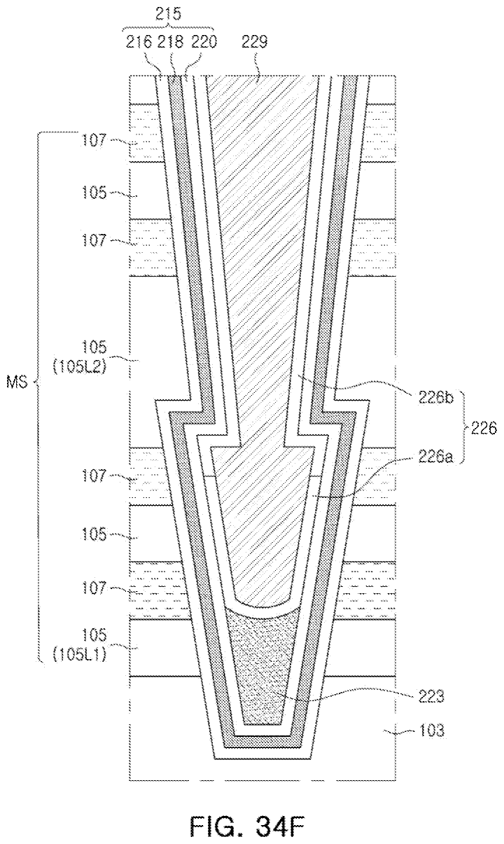

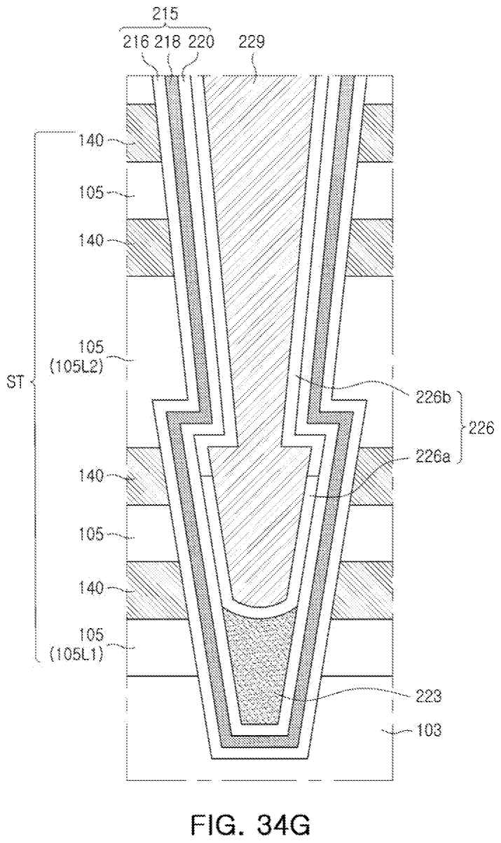

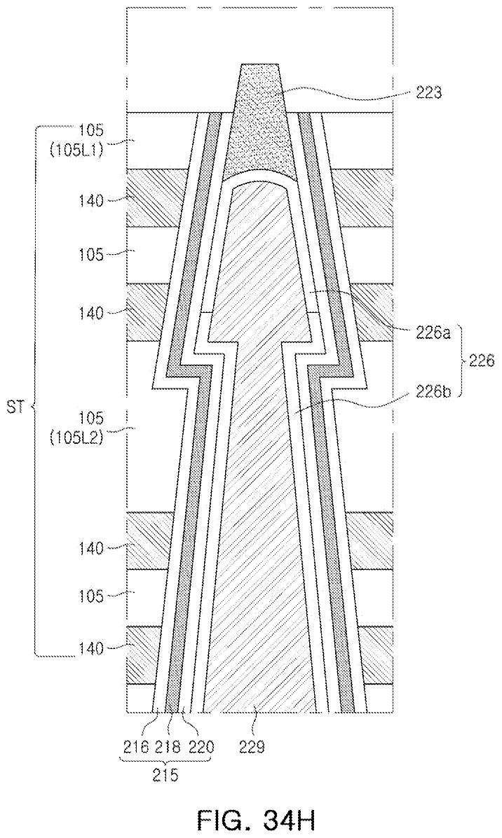

In the description below, a method of forming the vertical memory structure VCb described with reference to FIGS. 6 to 13 and a modified example of the vertical memory structure VCb will be described with reference to FIGS. 34A to 34H.

Referring to FIG. 34A, a lower mold structure MSa may be formed on the semiconductor substrate 103. The lower mold structure MSa may include interlayer insulating layers 105 and mold layers 107 alternately stacked. A lowermost layer 102L1 and an uppermost layer 105L2a of the interlayer insulating layers 105 and the mold layers 107 may be interlayer insulating layers.

A lower channel hole 203 penetrating through the lower mold structure MSa and extending into the semiconductor substrate 103 may be formed. The lower channel hole 203 may have an inclined side surface, such that a width thereof may decrease downwardly. A sacrificial gap-fill layer 205 filling the lower channel hole 203 may be formed.

Referring to FIG. 34B, by forming interlayer insulating layers 105 and mold layers 107 alternately stacked on the lower mold structure MSa, a mold structure MS including the lower mold structure MSa may be formed. The mold structure MS may be substantially the same as the mold structure MS described with reference to FIG. 32A.

An upper channel hole 207 may be formed to penetrate through the interlayer insulating layers 105 and the mold layers 107 on a level higher than a level of the lower mold structure MSa, and to expose a portion of the upper surface of the sacrificial gap-fill layer 205 (in FIG. 34A). Thereafter, the sacrificial gap-fill layer 205 (in FIG. 34A) may be selectively removed.

The side profile of the channel hole including the lower and upper channel holes 203 and 207 penetrating through the mold structure MS may be substantially the same as the shape of the side surface of the vertical memory structure VCb (in FIG. 7) described with reference to FIG. 7.

Referring to FIG. 34C, the dielectric structure 215 may be conformally formed in the channel hole including the lower and upper channel holes 203 and 207. The forming the dielectric structure 215 may include conformally forming the first dielectric layer 216, the data storage layer 218, and the second dielectric layer 220 in order.

Referring to FIG. 34D, in the channel hole including the lower and upper channel holes 203 and 207, a doped polysilicon layer 22 including impurities may be formed on the dielectric structure 215. The doped polysilicon layer 222 may have an N-type conductivity.

Referring to FIG. 34E, a first pad pattern 223 partially filling the lower channel hole 203 may be formed by partially etching the doped polysilicon layer 222.

Referring to FIG. 34F, in the channel hole including the lower and upper channel holes 203 and 207, a channel layer 226 may be formed to conformally cover the other portion of the channel hole, an insulating core region 229 may be formed to partially fill the channel hole on the channel layer 226, and a second pad pattern 232 (in FIG. 7) may be formed to contact the channel layer 226 on the insulating core region 229, on the first pad pattern 23 and the dielectric structure 215. The channel layer 226 may be formed of an undoped silicon layer. The second pad pattern 232 in FIG. 7 may be formed of the same material as that of the first pad pattern 223, e.g., doped polysilicon.

A heat treatment process for diffusing impurities in the first pad pattern 223 and the second pad pattern 232 (in FIG. 7) into the channel layer 226 may be performed. Accordingly, impurities may be diffused from the first pad pattern 223 into the channel layer 226, such that impurities may be diffused from the first doped region 226a having an N-type conductivity, thereby forming the second doped region 226c (in FIG. 7) having an N-type conductivity. The region of the channel layer 226 in which the impurity are not diffused may be defined as an undoped region 226b.

An upper insulating structure covering the mold structure MS may be formed on the semiconductor substrate 103.

Referring to FIGS. 31 and 34G, the mold layers 107 (in FIG. 34F) may be replaced with the gate layers 140 in the same process described with reference to FIG. 32G. Accordingly, a stack structure ST including the gate layers 140 and the interlayer insulating layers 105 may be formed.

Referring to FIG. 34H, similarly to the example described with reference to FIGS. 32G to 32H, after forming the bonding semiconductor structure, a process of exposing a portion of the vertical memory structure and a portion of the contact plug by removing a portion of the second semiconductor chip described above with reference to FIG. 30 may be performed. In this process (S40), the dielectric structure 215 on a level higher than a level of the stack structure ST may be removed, and the first pad pattern 223 may be exposed. Accordingly, the first pad pattern 223 illustrated in FIG. 10 may be formed.

In another example, the first pad pattern 224 defined in the stack structure ST as illustrated in FIG. 8 may be formed by removing the dielectric structure 215 on a level higher than a level of the stack structure ST, and removing the first pad pattern 223 on a level higher than a level of the stack structure ST.

In another example, after the first pad pattern 223 or 224 is formed, a portion of the dielectric structure 215 may be etched.

In another example, the buffer layer 203a as in FIG. 12 may be formed by allowing a portion of the semiconductor substrate 103 to remain (in FIG. 34G).

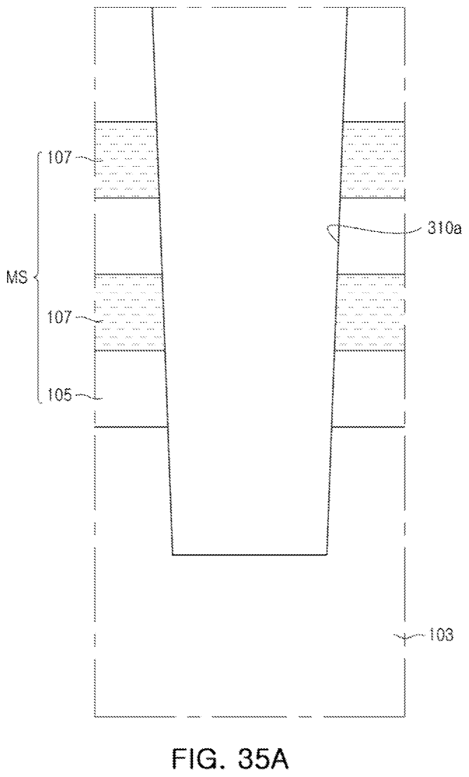

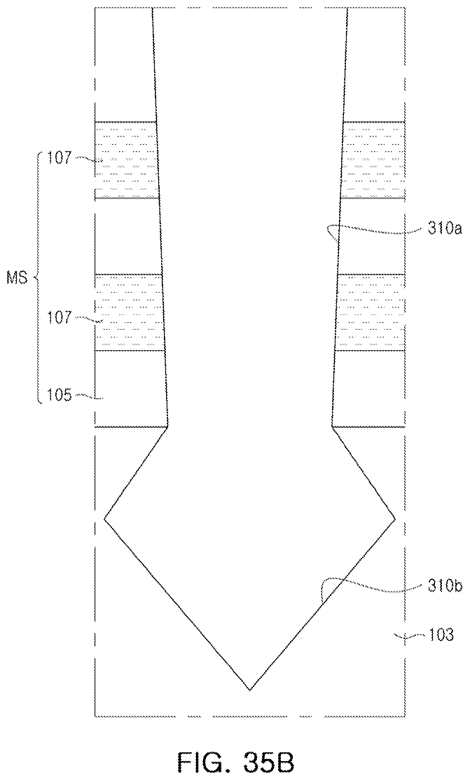

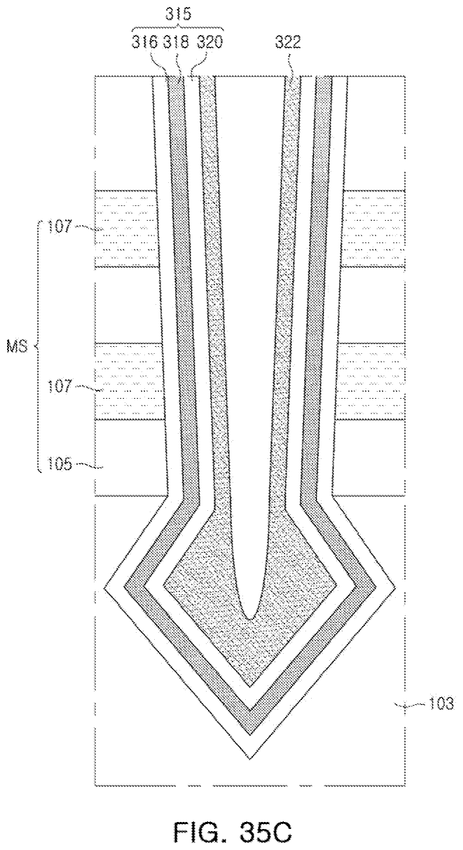

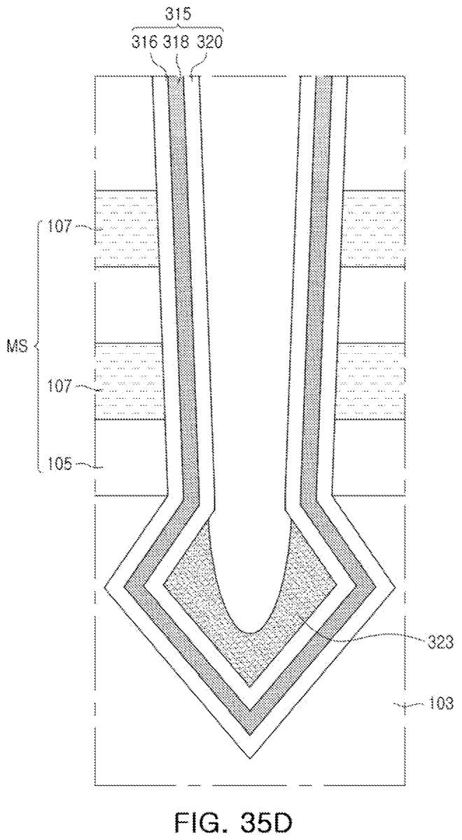

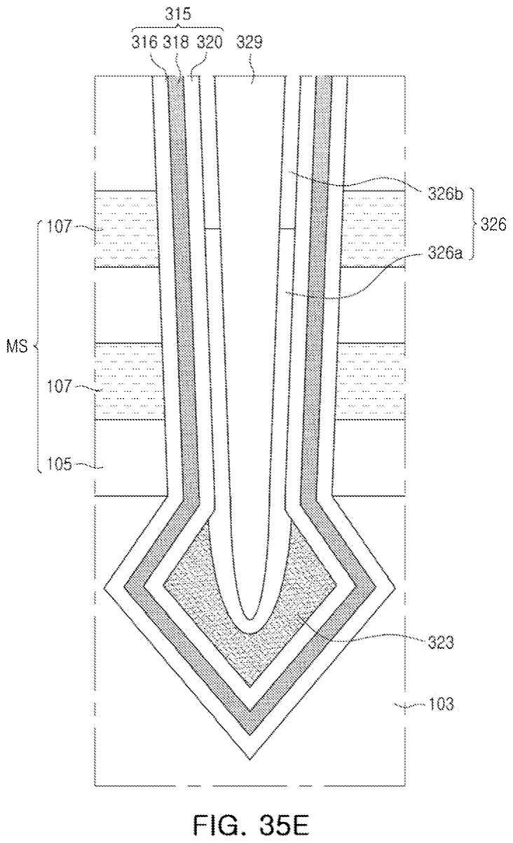

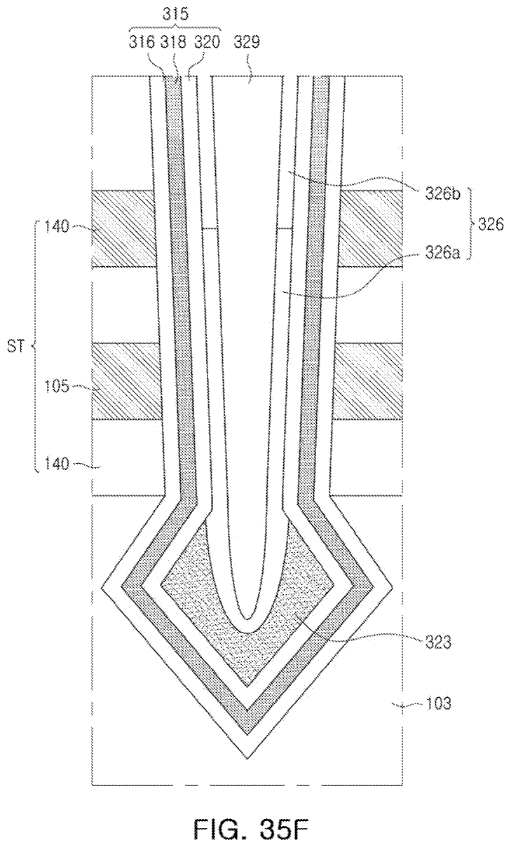

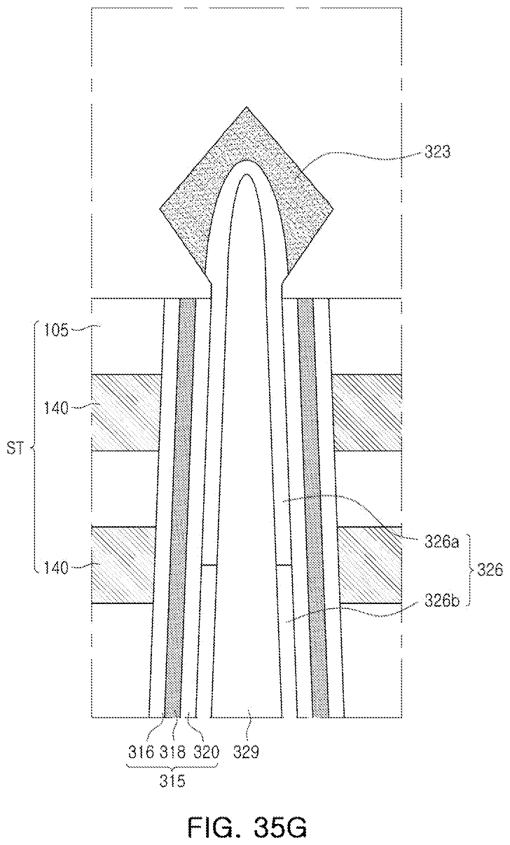

In the description below, a method of forming the vertical memory structure VCc described with reference to FIGS. 14 to 18 and a modified example of the vertical memory structure VCc will be described with reference to FIGS. 35A to 35G.

Referring to FIG. 35A, a mold structure MS may be formed on the semiconductor substrate 103. The mold structure MS may include interlayer insulating layers 105 and mold layers 107 alternately stacked. A channel hole 310a penetrating through the mold structure MS and extending into the semiconductor substrate 103 may be formed. A shape of the side surface of the channel hole 310 in a portion penetrating through the mold structure MS may be substantially the same as a shape of the side surface of the vertical memory structure VCc (in FIG. 15A).

Referring to FIG. 35B, a lower channel hole 310b having a sigma shape may be formed by etching the semiconductor substrate 103 exposed by the channel hole 310a along a crystal plane.

Referring to FIG. 35C, a dielectric structure 315 and a doped polysilicon layer 322 may be formed in order in the channel holes 310a and 310b. The forming the dielectric structure 315 may include conformally forming the first dielectric layer 316, the data storage layer 318, and the second dielectric layer 320 in order. The doped polysilicon layer 322 may have an N-type conductivity.

Referring to FIG. 35D, a first pad pattern 323 remaining in the lower channel hole 310b may be formed by partially etching the doped polysilicon layer 322.

Referring to FIG. 35E, a channel layer 326 may be formed to conformally cover the other portions of the channel holes 310a and 310b on the first pad pattern 323 and the dielectric structure 315, an insulating core region 329 may be formed to partially fill the channel holes 310a and 310b on the channel layer 326, and a second pad pattern 332 (in FIG. 15A) may be formed to contact the channel layer 326 on the insulating core region 329. The channel layer 326 may be formed as an undoped silicon layer. The second pad pattern 332 in FIG. 15A may be formed of the same material as that of the first pad pattern 323, e.g., doped polysilicon.

A heat treatment process for diffusing impurities in the first pad pattern 323 and the second pad pattern 332 (in FIG. 15A) into the channel layer 326 may be performed. Accordingly, a first doped region 326a having an N-type conductivity may be formed by impurities diffused from the first pad pattern 323 into the channel layer 326, and a second doped region 326c (in FIG. 15A) may be formed by impurities diffused from the second pad pattern 332 (in FIG. 15A). A region of the channel layer 326 in which the impurity is not diffused may be defined as an undoped region 326b.

Referring to FIGS. 31 and 35F, the mold layers 107 (in FIG. 35E) may be replaced with the gate layers 140 in the same process described with reference to FIG. 32G. Accordingly, the stack structure ST including the gate layers 140 and the interlayer insulating layers 105 may be formed.

Referring to FIG. 35G, similarly to the example described with reference to FIGS. 32G to 32H, after forming the bonding semiconductor structure, a process of exposing a portion of the vertical memory structure and a portion of the contact plug by removing a portion of the second semiconductor chip described above with reference to FIG. 30 may be performed. In this process S40, the dielectric structure 315 on a level higher than a level of the stack structure ST may be removed, and the first pad pattern 323 may be exposed. Accordingly, the first pad pattern 323 as illustrated in FIGS. 15A and 15B may be formed.

In another example, the method may further include partially etching the dielectric structure 215.

In another example, the buffer layer 303a as illustrated in FIG. 17 may be formed by allowing a portion of the semiconductor substrate 103 (in FIG. 35F) to remain.

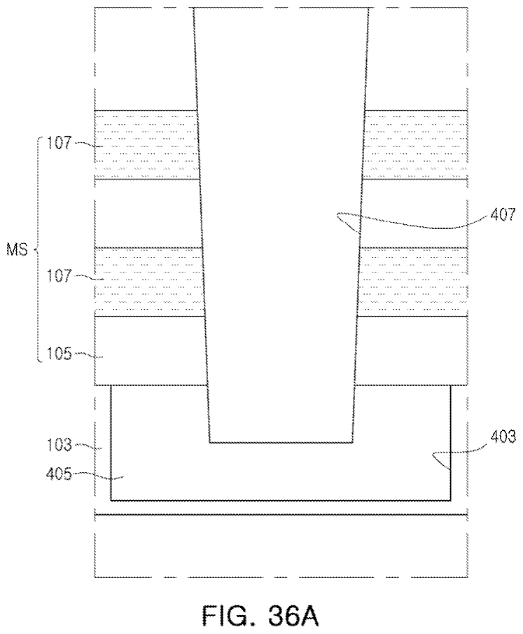

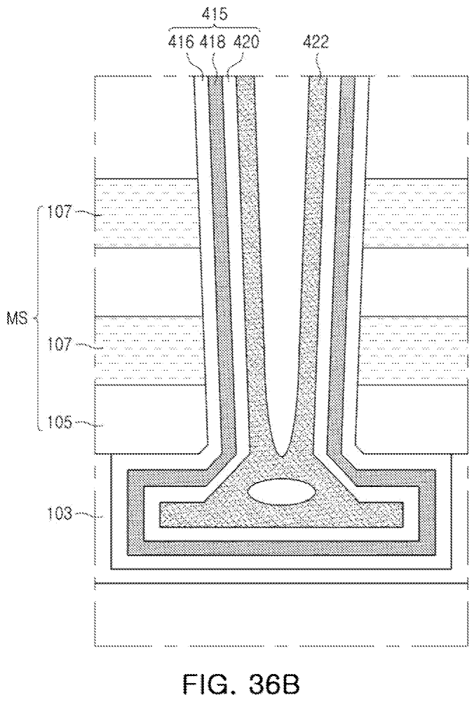

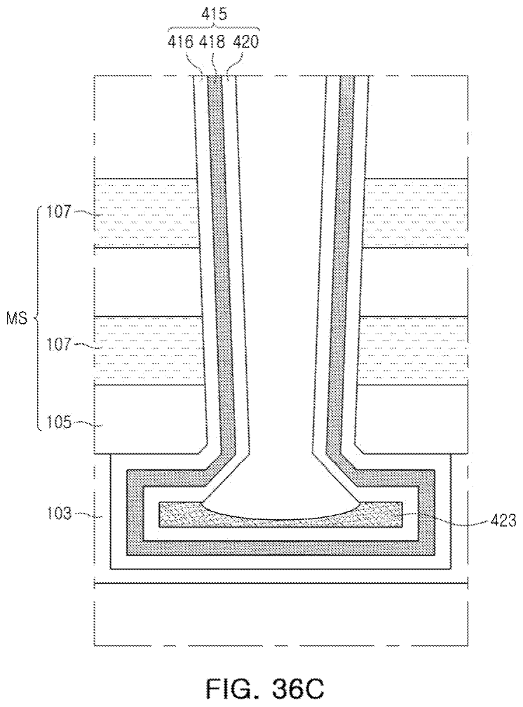

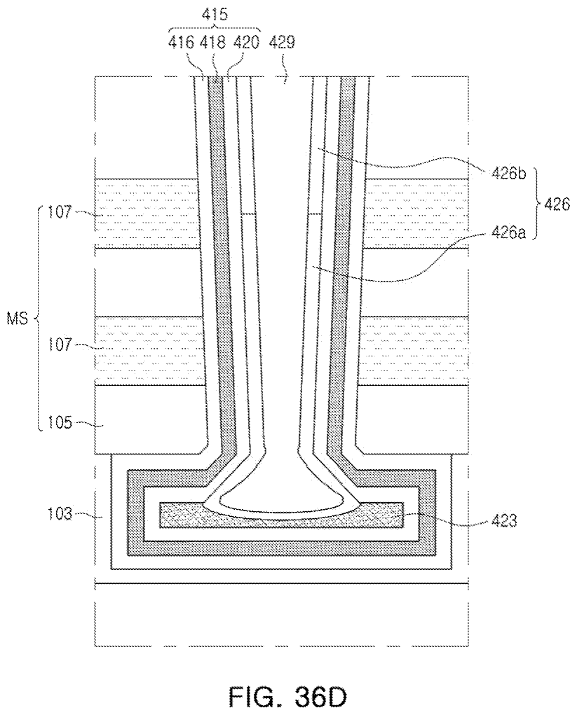

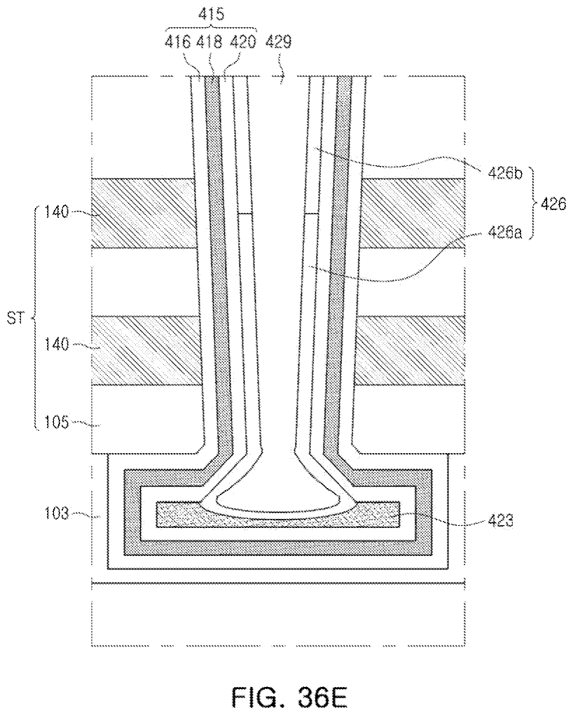

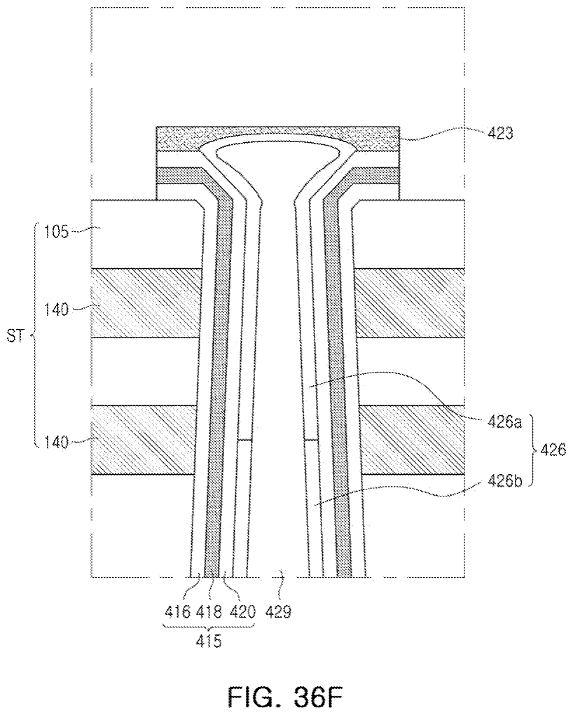

In the description below, a method of forming the vertical memory structure VCd described with reference to FIGS. 19 to 24 and a modified example of the vertical memory structure VCd will be described with reference to FIGS. 36A to 36F.

Referring to FIG. 36A, an opening 403 may be formed in a semiconductor substrate 103. A sacrificial pattern 405 may be formed in the opening 403. A mold structure MS including the interlayer insulating layers 105 and the mold layers 107 alternately stacked on the semiconductor substrate 103 and the sacrificial pattern 405 may be formed.

A channel hole 407 penetrating through the mold structure MS and exposing the sacrificial pattern 405 may be formed. The shape of the side surface of the channel hole 410 in the portion penetrating through the mold structure MS may be substantially the same as the shape of the side surface of the vertical memory structure VCd (in FIG. 20A) in the portion penetrating through the stack structure ST (in FIG. 20A). Thereafter, the sacrificial pattern 405 may be removed.

Referring to FIG. 36B, a dielectric structure 415 and a doped polysilicon layer 422 may be formed in order in the opening 403 from which the channel hole 407 and the sacrificial pattern 405 are removed. The forming the dielectric structure 415 may include conformally forming the first dielectric layer 416, the data storage layer 418, and the second dielectric layer 420 in order. The doped polysilicon layer 422 may have an N-type conductivity.

Referring to FIG. 36C, a first pad pattern 423 remaining in the opening 403 may be formed by partially etching the doped polysilicon layer 422.

Referring to FIG. 36D, a channel layer 426 may be formed to conformally cover the other portions of the opening 403 and the channel hole 407 on the first pad pattern 423 and the dielectric structure 415, an insulating core region 429 may be formed to fill the opening 403 and partially fill the channel hole 407 on the channel layer 326, and the second pad pattern 432 (in FIG. 20A) may be formed to contact the channel layer 426 on the insulating core region 429. The channel layer 426 may be formed as an undoped silicon layer. The second pad pattern 432 in FIG. 20A may be formed of the same material as that of the first pad pattern 423, e.g., doped polysilicon.

A heat treatment process for diffusing impurities in the first pad pattern 423 and the second pad pattern (432 in FIG. 20A) into the channel layer 426 may be performed, thereby forming a first doped region 426a and a second doped region 326c (in FIG. 20A) having an N-type conductivity in the channel layer 426.

Referring to FIG. 36E, the mold layers 107 (in FIG. 36D) may be replaced with the gate layers 140 by the same process as described with reference to FIG. 32G. Accordingly, a stack structure ST including the gate layers 140 and the interlayer insulating layers 105 may be formed.

Referring to FIG. 36F, similarly to the example described with reference to FIGS. 32G to 32H, after forming the bonding semiconductor structure, a process of exposing a portion of the vertical memory structure and a portion of the contact plug by removing a portion of the second semiconductor chip described above with reference to FIG. 30 may be performed. In this process S40, the semiconductor substrate 103 on a level higher than a level of the stack structure ST may be removed, and the dielectric structure 215 in a region not overlapping the first pad pattern 423 may be removed by an etching process, such that the first pad pattern 423 may be exposed. Accordingly, the first pad pattern 423 as illustrated in FIG. 20B may be formed.

In another example, the dielectric structure 215 on a level higher than a level of the stack structure ST may be partially etched, thereby forming the dielectric structure 215 illustrated in FIG. 21.

In another example, the buffer layer 403a as in FIG. 22 or the buffer layer 403a as in FIG. 24 may be formed by allowing a portion of the semiconductor substrate 103 (in FIG. 36G) to remain.

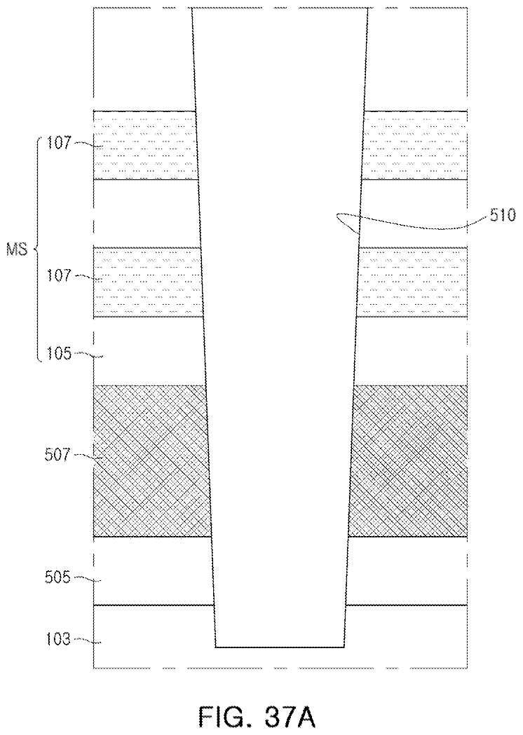

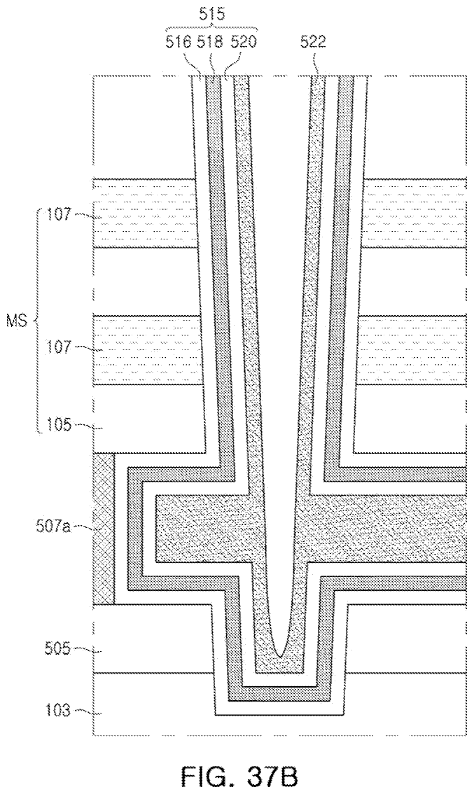

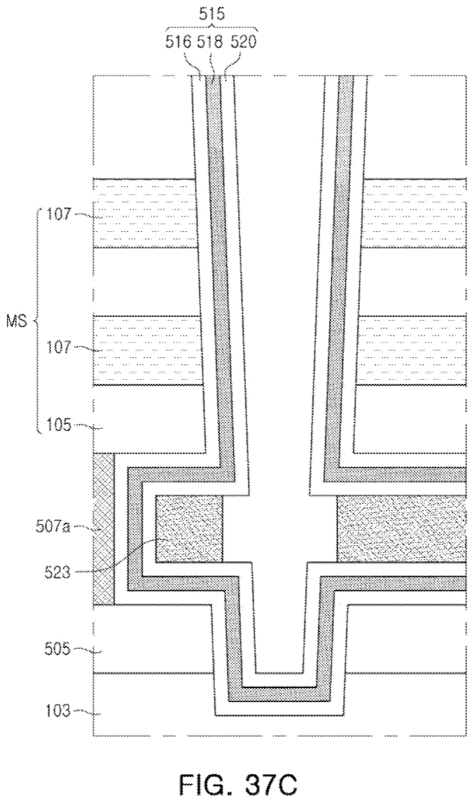

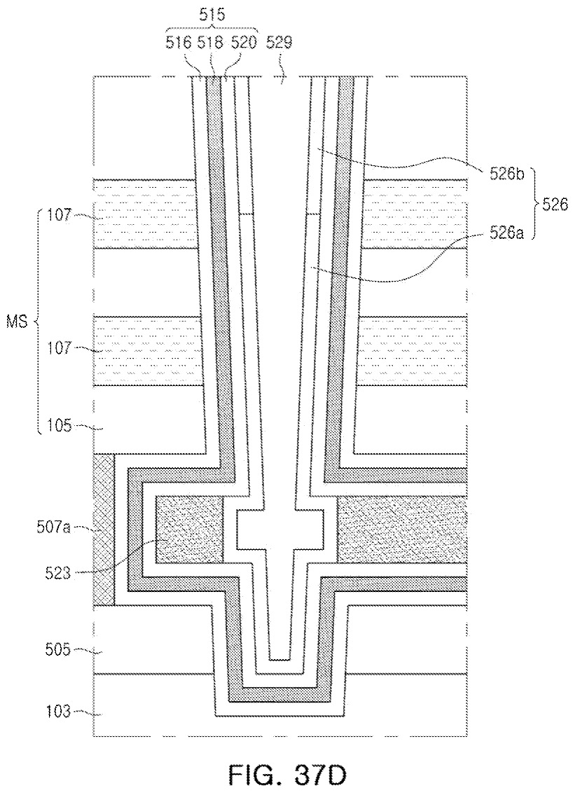

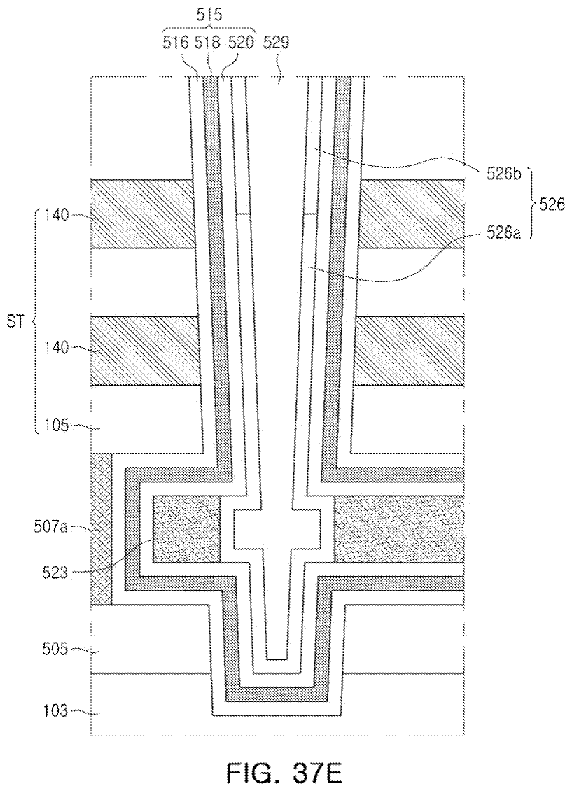

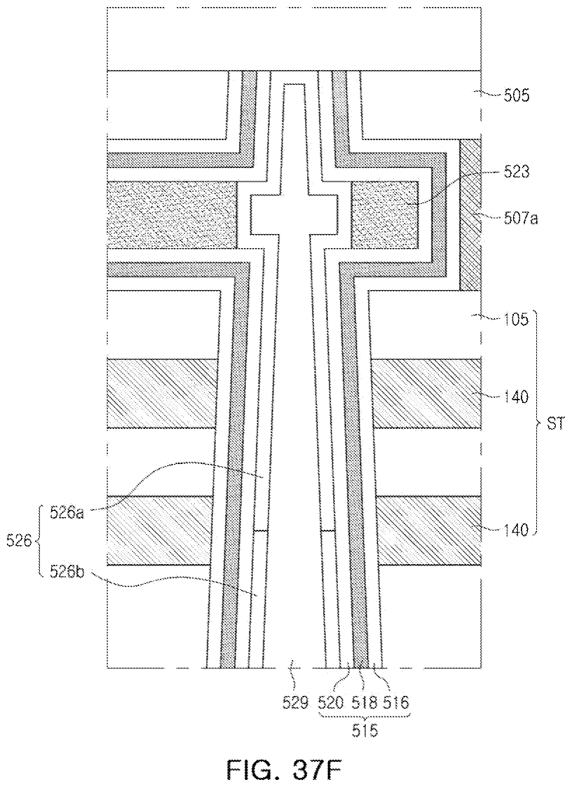

In the description below, a method of forming the vertical memory structure VCe described with reference to FIGS. 25 to 29 and a modified example of the vertical memory structure VCe will be described with reference to FIGS. 37A to 37F.

Referring to FIG. 37A, a lower buffer layer 50 and an upper buffer layer 507 may be formed in order on the semiconductor substrate 103. The lower buffer layer 50 may be formed of an insulating material, e.g., silicon oxide. The upper buffer layer 507 may be formed of a material different from that of the lower buffer layer 50, e.g., a silicon layer or a metal material layer.

A mold structure MS, including the interlayer insulating layers 105 and the mold layers 107 alternately stacked on the upper buffer layer 507, may be formed.

A channel hole 510 penetrating through the mold structure MS, the upper buffer layer 507, and the lower buffer layer 505 and extending into the semiconductor substrate 103 may be formed. A shape of the side surface of the channel hole 510 in a portion penetrating through the mold structure MS may be the same as a shape of the side surface of the vertical memory structure VCe (in FIG. 26A) in a portion penetrating through the stack structure (ST in FIG. 26A). Thereafter, the sacrificial pattern 405 may be removed.

Referring to FIG. 37B, the upper buffer layer 507a may be partially etched to form an upper buffer layer 507a having a reduced width. Accordingly, in the region in which the upper buffer layer 507a is disposed, the width of the channel hole 510 may increase. A dielectric structure 515 and a doped polysilicon layer 522 may be formed in order in the channel hole 510 having an increased width in the region in which the upper buffer layer 507a is disposed. The forming the dielectric structure 515 may include conformally forming a first dielectric layer 516, a data storage layer 518, and a second dielectric layer 520 in order. The doped polysilicon layer 522 may have an N-type conductivity.

Referring to FIG. 37C, a first pad pattern 523 on the same level as a level of the upper buffer layer 507a may be formed by partially etching the doped polysilicon layer 522.

Referring to FIG. 37D, a channel layer 526 may be formed to conformally cover the other portion of the channel hole 510 on the first pad pattern 523 and the dielectric structure 515, an insulating core region 529 may be formed to partially fill the channel hole 510 on the channel layer 526, and a second pad pattern 532 (in FIG. 26A) may be formed to contact the channel layer 526 on the insulating core region 529. The channel layer 526 may be formed as an undoped silicon layer. The second pad pattern 532 (in FIG. 26A) may be formed of the same material as that of the first pad pattern 523, e.g., doped polysilicon.

By performing a heat treatment process for diffusing impurities in the first pad pattern 523 and the second pad pattern 532 (in FIG. 26A) into the channel layer 526, a first doped region 526a and a second doped region 526c (in FIG. 26A) having an N-type conductivity may be formed in the channel layer 526.

Referring to FIG. 37E, the mold layers 107 (in FIG. 37D) may be replaced with the gate layers 140 in the same process as described with reference to FIG. 32G. Accordingly, a stack structure ST including the gate layers 140 and the interlayer insulating layers 105 may be formed.

Referring to FIG. 36F, similarly to the example described with reference to FIGS. 32G to 32H, after forming the bonding semiconductor structure, a process of exposing a portion of the vertical memory structure and a portion of the contact plug by removing a portion of the second semiconductor chip described above with reference to FIG. 30 may be performed. In this process S40, the semiconductor substrate 103 and the dielectric structure 515 on a level higher than a level of the lower buffer layer 505 may be removed, and the channel layer 526 may be exposed. The lower buffer layer 505 may be the second buffer layer 505 described with reference to FIG. 26B. The upper buffer layer 507a may be the first buffer layer 507a described with reference to FIG. 26B.

In another example, by partially etching the second buffer layer 505 and the dielectric structure 215, a portion of the channel layer 526 as illustrated in FIG. 27 may protrude.

In another example, by removing the second buffer layer 505 and the dielectric structure 215 on a level higher than a level of the first pad pattern 523, the channel layer 526 as illustrated in FIG. 28 may protrude.

In another example, the second buffer layer 505, the dielectric structure 215, the channel layer 526, and the insulating core region 529 on a level higher than a level of the first pad pattern 523 may be removed, thereby forming the channel layer 526 as in FIG. 29.

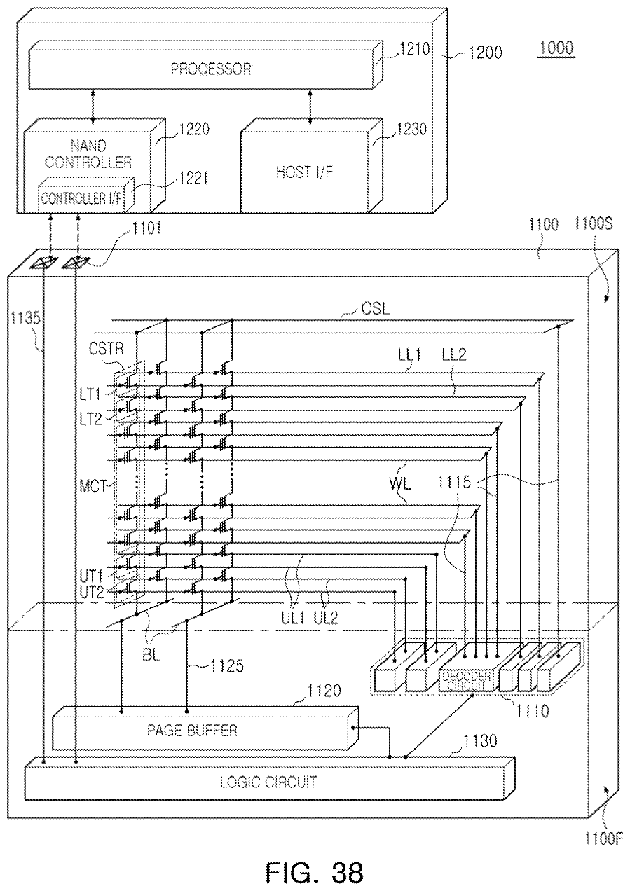

In the description below, a data storage system including the semiconductor device according to an example embodiment will be described with reference to FIGS. 38, 39, and 40.

FIG. 38 is a diagram illustrating a data storage system including a semiconductor device according to an example embodiment.

Referring to FIG. 38, a data storage system 1000 according to an example embodiment may include a semiconductor device 1100 and a controller 1200 electrically connected to the semiconductor device 1100. The data storage system 1000 may be implemented as a storage device including the semiconductor device 1100 or an electronic device including a storage device. For example, the data storage system 1000 may be implemented as a solid state drive device (SSD) device including the semiconductor device 1100, a universal serial bus (USB), a computing system, a medical device, or a communication device.

In an example embodiment, the data storage system 1000 may be implemented as an electronic system for storing data.

The semiconductor device 1100 may be a semiconductor device according to one of the example embodiments described above with reference to FIGS. 1 to 37F. The semiconductor device 1100 may include a first structure 1100F and a second structure 1100S on the first structure 1100F.

The first structure 1100F may be the lower structure LS described with reference to FIG. 1. The second structure 1100S may be the upper structure US described with reference to FIG. 1.

The first structure 1100F may be a peripheral circuit structure including a decoder circuit 1110, a page buffer 1120, and a logic circuit 1130. For example, the first structure 1100F may include the peripheral circuit 9 (in FIG. 1) described in the aforementioned example embodiment. The peripheral circuit 9 (in FIG. 1) may be a transistor forming a peripheral circuit structure including a decoder circuit 1110, a page buffer 1120, and a logic circuit 1130.

The second structure 1100S may be a memory structure including a bit line BL, a common source line CSL, word lines WL, first and second gate upper lines UL1 and UL2, first and second gate lower lines LL1 and LL2, and memory cell strings CSTR between the bit line BL and the common source CSL.

In the second structure 1100S, each of the memory cell strings CSTR may include lower transistors LT1 and LT2 adjacent to the common source line CSL, upper transistors UT1 and UT2 adjacent to the bit line BL, and a plurality of memory cell transistors MCT between the lower transistors LT1 and LT2 and the upper transistors UT1 and UT2. The number of the lower transistors LT1 and LT2 and the number of the upper transistors UT1 and UT2 may be varied in example embodiments.

In example embodiments, the upper transistors UT1 and UT2 may include string select transistors, and the lower transistors LT1 and LT2 may include ground select transistors. The gate lower lines LL1 and LL2 may be gate electrodes of the lower transistors LT1 and LT2, respectively. The word lines WL may be gate electrodes of the memory cell transistors MCT, and the gate upper lines UL1 and UL2 may be gate electrodes of the upper transistors UT1 and UT2, respectively.

The gate layers 140 (in FIG. 1) described in the aforementioned example embodiment may form the gate lower lines LL1 and LL2, the word lines WL, and the gate upper lines UL1 and UL2.

The gate lower lines LL1 and LL2 may correspond to the plurality of upper gate layers 140L1 and 140L2 in FIG. 2A. The gate upper lines UL1 and UL2 may correspond to the plurality of lower gate layers 140U1 and 140U2 in FIG. 2A.

In example embodiments, the lower transistors LT1 and LT2 may include a lower erase control transistor LT1 and a ground select transistor LT2 connected to each other in series. The upper transistors UT1 and UT2 may include a string select transistor UT1 and an upper erase control transistor UT2 connected to each other in series. At least one of the lower erase control transistor LT1 and the upper erase control transistor UT1 may be used in an erase operation for erasing data stored in the memory cells using a gate induce drain leakage (GIDL) phenomenon. The erase control gate electrode of the lower erase control transistor LT1 may be at least one of the plurality of upper gate layers 140L1 and 140L2 in FIG. 2A facing the first doped region 126a. The erase control gate electrode of the upper erase control transistor UT1 may be at least one of the plurality of lower gate layers 140U1 and 140U2 in FIG. 2A facing the second doped region 126c.

The common source line CSL, the first and second gate lower lines LL1 and LL2, the word lines WL, and the first and second gate upper lines UL1 and UL2 may be electrically connected to the decoder circuit 1110 through first connection wirings 1115 extending from the first structure 1100F to the second structure 1100S.

The bit lines BL may be electrically connected to the page buffer 1120 through second connection wirings 1125 extending from the first structure 1100F to the second structure 1100S.

In the first structure 1100F, the decoder circuit 1110 and the page buffer 1120 may perform a control operation on at least one of the plurality of memory cell transistors MCT. The decoder circuit 1110 and the page buffer 1120 may be controlled by a logic circuit 1130.

The semiconductor device 1100 may further include an input/output pad 1101. The input/output pad 1101 may be the input/output pattern (in FIG. 1) described in the aforementioned example embodiment.

The semiconductor device 1100 may communicate with the controller 1200 through the input/output pad 1101 electrically connected to the logic circuit 1130. The input/output pad 1101 may be electrically connected to the logic circuit 1130 through an input/output connection wiring 1135 extending from the first structure 1100F to the second structure 1100S. Accordingly, the controller 1200 may be electrically connected to the semiconductor device 1100 through the input/output pad 1101, and may control the semiconductor device 1100.

The controller 1200 may include a processor 1210, a NAND controller 1220, and a host interface 1230. In example embodiments, the data storage system 1000 may include a plurality of semiconductor devices 1100, and in this case, the controller 1200 may control the plurality of semiconductor devices 1100.

The processor 1210 may control overall operation of the data storage system 1000 including the controller 1200. The processor 1210 may operate according to a predetermined firmware, and may access the semiconductor device 1100 by controlling the NAND controller 1220. The NAND controller 1220 may include a NAND interface 1221 for processing communications with the semiconductor device 1100. A control command for controlling the semiconductor device 1100, data to be written in the memory cell transistors MCT of the semiconductor device 1100, and data to be read from the memory cell transistors MCT may be transmitted through the NAND interface 1221. The host interface 1230 may provide a communication function between the data storage system 1000 and an external host. When a control command is received from an external host through the host interface 1230, the processor 1210 may control the semiconductor device 1100 in response to the control command.

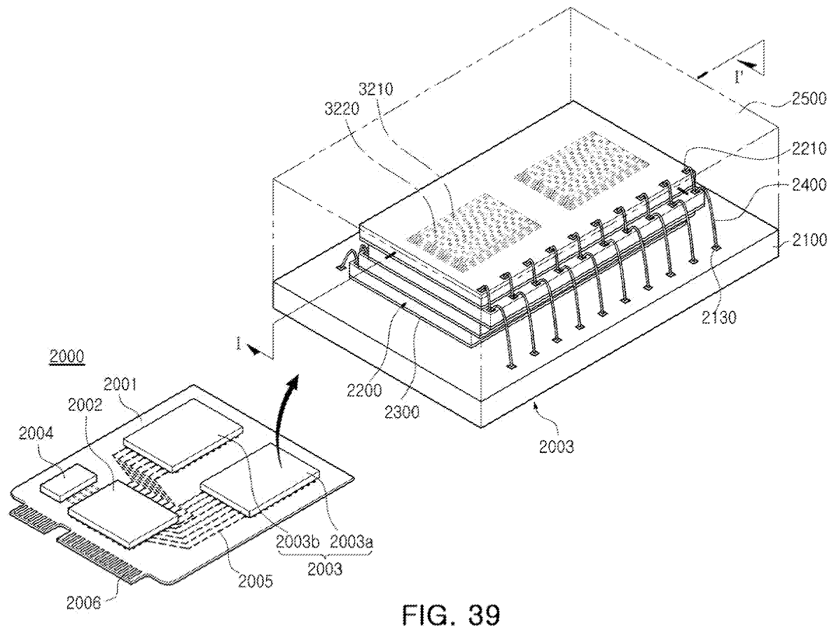

FIG. 39 is a perspective diagram illustrating a data storage system including a semiconductor device according to an example embodiment.

Referring to FIG. 39, a data storage system 2000 according to an example embodiment may include a main substrate 2001, a controller 2002 mounted on the main substrate 2001, one or more semiconductor packages 2003, and a DRAM 2004. The semiconductor package 2003 and the DRAM 2004 may be connected to the controller 2002 by wiring patterns 2005 formed on the main substrate 2001.

The main substrate 2001 may include a connector 2006 including a plurality of pins coupled to an external host. The number and the arrangement of the plurality of pins in the connector 2006 may be varied depending on a communication interface between the data storage system 2000 and the external host. In example embodiments, the data storage system 2000 may communicate with the external host through one of interfaces such as a universal serial bus (USB), a peripheral component interconnect express (PCI-Express), a serial advanced technology attachment (SATA), and an M-phy for universal flash storage (UFS). In example embodiments, the data storage system 2000 may operate by power supplied from the external host through the connector 2006. The data storage system 2000 may further include a power management integrated circuit (PMIC) for distributing power supplied from the external host to the controller 2002 and the semiconductor package 2003.

The controller 2002 may write data in the semiconductor package 2003 or may read data from the semiconductor package 2003, and may improve an operation speed of the data storage system 2000.

The DRAM 2004 may be configured as a buffer memory for mitigating a difference in speeds between the semiconductor package 2003, which may be a data storage space, and an external host. The DRAM 2004 included in the data storage system 2000 may also operate as a cache memory, and may provide a space for temporarily storing data in a control operation for the semiconductor package 2003. When the DRAM 2004 is included in the data storage system 2000, the controller 2002 further may include a DRAM controller for controlling the DRAM 2004 in addition to the NAND controller for controlling the semiconductor package 2003

The semiconductor package 2003 may include first and second semiconductor packages 2003a and 2003b spaced apart from each other. Each of the first and second semiconductor packages 2003a and 2003b may be configured as a semiconductor package including a plurality of semiconductor chips 2200. Each of the semiconductor chips 2200 may include a semiconductor device described in one of the aforementioned example embodiments described with reference to FIGS. 1 to 37F.

Each of the first and second semiconductor packages 2003a and 2003b may include a package substrate 2100, semiconductor chips 2200 on the package substrate 2100, adhesive layers 2300 on lower surfaces of the semiconductor chips 2200, respectively, a connection structure 2400 electrically connecting the semiconductor chips 2200 to the package substrate 2100, and a molding layer 2500 covering the semiconductor chips 2200 and the connection structure 2400 on the package substrate 2100.

The package substrate 2100 may be configured as a printed circuit board including package upper pads 2130. Each of the semiconductor chips 2200 may include an input/output pad 2210.

In example embodiments, the connection structure 2400 may be a bonding wiring electrically connecting the input/output pad 2210 to the package upper pads 2130. Accordingly, in each of the first and second semiconductor packages 2003a and 2003b, the semiconductor chips 2200 may be electrically connected to each other through a bonding wire method, and may be electrically connected to the package upper pads 2130 of the package substrate 2100. In example embodiments, in each of the first and second semiconductor packages 2003a and 2003b, the semiconductor chips 2200 may be electrically connected to each other by a connection structure including a through silicon via (TSV), instead of the connection structure 2400 of a bonding wire method.

In example embodiments, the controller 2002 and the semiconductor chips 2200 may be included in a single package. For example, the controller 2002 and the semiconductor chips 2200 may be mounted on a separate interposer substrate different from the main substrate 2001, and the controller 2002 may be connected to the semiconductor chips 2200 by wirings formed on the interposer substrate.

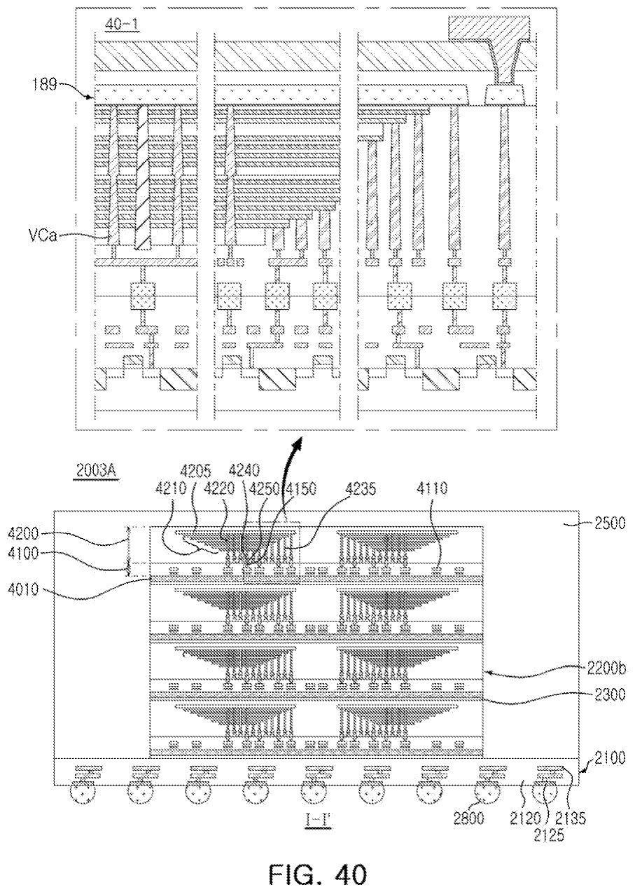

FIG. 40 is a cross-sectional diagram illustrating a data storage system including a semiconductor device according to an example embodiment. FIG. 40 illustrates an example embodiment of the semiconductor package 2003 in FIG. 39, illustrating a cross-sectional region of the semiconductor package 2003 in FIG. 39 taken along line I-I′.

Referring to FIG. 40, in the semiconductor package 2003A, each of semiconductor chips 2200a may include a semiconductor substrate 4010, a first structure 4100 on the semiconductor substrate 4010, and a second structure 4200, bonded to the first structure 4100 by a wafer bonding method, on the first structure 4100.

The first structure 4100 may include a peripheral circuit region including peripheral wiring 4110 and first bonding structures 4150. The second structure 4200 may include a common source line 4205, a gate stack structure 4210 between the common source line 4205 and the first structure 4100, memory channel structures 4220 and a separation structure 4230 penetrating through the gate stack structure 4210, and second bonding structures 4250 electrically connected to the word lines WL (in FIG. 1) of the memory channel structures 4220 and the gate stack structure 4210, respectively. For example, the second bonding structures 4250 may be electrically connected to the memory channel structures 4220 and the word lines WL (in FIG. 38), respectively, through gate connection wirings 4235 electrically connected to bit lines 4240 and the word lines WL (in FIG. 38) electrically connected to the memory channel structures 4220. The memory channel structures 4220 may be vertical memory structures described in the aforementioned example embodiments. The first bonding structures 4150 of the first structure 4100 and the second bonding structures 4250 of the second structure 4200 may be in contact with and bonded to each other. Bonded portions of the first bonding structures 4150 and the second bonding structures 4250 may be formed of, e.g., copper (Cu).

Each of the semiconductor chips 2200b may further include an input/output pad 2210 (in FIG. 39) electrically connected to the peripheral wiring 4110 of the first structure 4100.

The semiconductor chips 2200 in FIG. 39 and the semiconductor chips 2200b in FIG. 40 may be electrically connected to each other by connection structures 2400 configured in the form of bonding wires. However, in example embodiments, semiconductor chips in a single semiconductor package, such as the semiconductor chips 2200 in FIG. 39 and the semiconductor chips 2200b in FIG. 40, may be electrically connected to each other by a connection structure including a through electrode TSV.

In FIG. 40, the enlarged portion, indicated by reference numeral 40-1 is provided to indicate the semiconductor chips 2200b, may be modified to include the cross-sectional structure as in FIG. 1. Accordingly, each of the semiconductor chips 2200b may include the semiconductor device 1 according to one of the example embodiments described above with reference to FIGS. 1 to 37F.

As described above, embodiments may provide a semiconductor device which may improve integration density, and a data storage system including a semiconductor device.

According to the aforementioned example embodiments, before forming a bonding semiconductor structure by bonding a first semiconductor chip including a peripheral circuit to a second semiconductor chip including a memory structure, the memory structure of the second semiconductor chip may include a vertical memory structure including a channel layer, a first pad pattern contacting the upper region of the channel layer, supplying impurities to the upper region of the channel layer and forming the upper region of the channel layer as a doped region and a second pad pattern contacting the lower region of the channel layer, supplying impurities to the lower region of the channel layer and forming the lower region of the channel layer as a doped region.

Since the second semiconductor chip including the vertical memory structure is bonded to the first semiconductor chip after the bonding semiconductor structure is formed, an ion implantation process for doping the channel layer and a heat treatment process for diffusing impurities may not be performed. Accordingly, degradation of performance of the semiconductor device due to a heat treatment process performed after forming the bonding semiconductor structure, e.g., defects caused by a subsequent thermal process in a portion in which the bonding pads are bonded may be prevented.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A semiconductor device, including:
a lower structure including a substrate and a peripheral circuit on the substrate; and
an upper structure on the lower structure, wherein:
the upper structure includes a stack structure including interlayer insulating layers and gate layers, a vertical memory structure penetrating through the stack structure, a bit line electrically connected to the vertical memory structure and below the stack structure, a conductive pattern electrically connected to the vertical memory structure and on the stack structure, an upper insulating layer covering the conductive pattern, and a capping insulating layer on the upper insulating layer,
the vertical memory structure includes an insulating core region, a first pad pattern electrically connected to the conductive pattern and on the insulating core region, a dielectric structure on a side surface of the insulating core region and a side surface of the first pad pattern, and a channel layer between the insulating core region and the dielectric structure and between the insulating core region and the first pad pattern, and
the channel layer includes a first portion contacting the dielectric structure, and a second portion extending from the first portion and between a lower surface of the first pad pattern and an upper surface of the insulating core region.

2. The semiconductor device as claimed in claim 1, wherein the channel layer includes a silicon layer contacting the lower surface of the first pad pattern and the upper surface of the insulating core region.

3. The semiconductor device as claimed in claim 1, wherein:
the dielectric structure includes a first dielectric layer, a second dielectric layer, and a data storage layer between the first dielectric layer and the second dielectric layer, and
the dielectric structure contacts the side surface of the first pad pattern.

4. The semiconductor device as claimed in claim 3, wherein the data storage layer has a bent portion on a level higher than a level of an uppermost gate layer among the gate layers.

5. The semiconductor device as claimed in claim 1, wherein:
the channel layer includes an undoped region, and a first doped region contacting the first pad pattern on the undoped region,
the first doped region and the first pad pattern have the same conductivity type,
the gate layers include a plurality of lower gate electrodes, a plurality of upper gate electrodes, and a plurality of intermediate gate electrodes between the plurality of lower gate electrodes and the plurality of upper gate electrodes,
the first doped region faces at least a portion of at least one of the plurality of upper gate electrodes, and
the undoped region faces the plurality of intermediate gate electrodes.

6. The semiconductor device as claimed in claim 5, wherein:
the channel layer further includes a second doped region below the undoped region, and
the second doped region faces at least a portion of at least one of the plurality of lower gate electrodes.

7. The semiconductor device as claimed in claim 6, wherein:
the at least one of the plurality of upper gate electrodes facing the first doped region is an upper erase control gate electrode, and
the at least one of the plurality of lower gate electrodes facing the second doped region is a lower erase control gate electrode.

8. The semiconductor device as claimed in claim 6, further comprising a bit line stud electrically connecting the bit line to the vertical memory structure and between the bit line and the vertical memory structure, wherein:
the vertical memory structure further includes a second pad pattern below the insulating core region and contacting the second doped region of the channel layer,
the second pad pattern contacts the bit line stud, and
the first pad pattern and the second pad pattern include silicon having an N-type conductivity.

9. The semiconductor device as claimed in claim 1, wherein:
the first pad pattern extends into the conductive pattern, and
the conductive pattern covers an upper surface of the first pad pattern and at least a portion of the side surface of the first pad pattern.

10. The semiconductor device as claimed in claim 1, further comprising a buffer layer between an uppermost interlayer insulating layer among the interlayer insulating layers and the conductive pattern, wherein:
the buffer layer covers at least a portion of the side surface of the first pad pattern, and
the dielectric structure includes a portion extending to a region between the buffer layer and the first pad pattern.

11. The semiconductor device as claimed in claim 1, wherein:
the gate layers include a plurality of lower gate electrodes, a plurality of upper gate electrodes, and a plurality of intermediate gate electrodes between the plurality of lower gate electrodes and the plurality of upper gate electrodes,
the plurality of intermediate gate electrodes include word lines, and
a side surface of the vertical memory structure has a bent portion between the plurality of upper gate electrodes and the plurality of intermediate gate electrodes.

12. The semiconductor device as claimed in claim 11, wherein the vertical memory structure has an inclined side surface, such that a width thereof decreases upwardly on a level higher than a level of the bent portion.

13. The semiconductor device as claimed in claim 1, wherein:
the vertical memory structure penetrates the stack structure and extends upwardly, and
the first pad pattern is on a level higher than a level of the stack structure.

14. The semiconductor device as claimed in claim 13, wherein the first pad pattern has a first side surface inclined such that a width of the first pad pattern increases upwardly, and a second side surface on a level higher than a level of the first side surface, extending from the first side surface, and inclined such that a width of the first pad pattern decreases upwardly.

15. The semiconductor device as claimed in claim 13, wherein:
the dielectric structure further includes a portion interposed between the first pad pattern and the stack structure,
the dielectric structure includes a first dielectric layer, a second dielectric layer, and a data storage layer between the first dielectric layer and the second dielectric layer,
the second dielectric layer contacts a portion of the lower surface of the first pad pattern, and
the data storage layer and the first dielectric layer are spaced apart from the first pad pattern.

16. A semiconductor device, comprising:
a lower structure including a substrate and a peripheral circuit on the substrate; and
an upper structure bonded to the lower structure on the lower structure, wherein:
the upper structure includes:
a stack structure including interlayer insulating layers and gate layers;
a vertical memory structure penetrating through the stack structure;
a bit line electrically connected to the vertical memory structure, and below the stack structure;
gate contact plugs contacting pad regions of the gate layers, and below the gate layers;
a source contact plug and an input/output contact plug spaced apart from the gate layers, and having upper surfaces on a level higher than a level of an uppermost gate layer among the gate layers, and lower surfaces on a level lower than a level of a lowermost gate layer among the gate layers;
a first conductive pattern electrically connected to the vertical memory structure and the source contact plug, and on a level higher than a level of the stack structure;
a second conductive pattern electrically connected to the input/output contact plug, and on the same level as a level of the first conductive pattern;
an upper insulating layer covering the first and second conductive patterns;
a capping insulating layer on the upper insulating layer; and
an input/output pattern penetrating through the capping insulating layer and the upper insulating layer, and electrically connected to the second conductive pattern,
the vertical memory structure includes an insulating core region, a channel layer covering at least a side surface of the insulating core region, a first pad pattern contacting the channel layer and on a level higher than a level of the uppermost gate layer, a dielectric structure contacting the first pad pattern and the channel layer, and a second pad pattern contacting the channel layer and below the insulating core region,
the insulating core region is spaced apart from the first pad pattern,
the dielectric structure includes a first dielectric layer, a second dielectric layer, and a data storage layer between the first dielectric layer and the second dielectric layer, and
the second dielectric layer includes a portion contacting the channel layer and a portion contacting the first pad pattern, and is spaced apart from the second pad pattern.

17. The semiconductor device as claimed in claim 16, wherein:
the source contact plug further includes a portion extending into the first conductive pattern,
the input/output contact plug further includes a portion extending into the second conductive pattern,
the first conductive pattern covers a portion of a side surface and the upper surface of the source contact plug, and
the second conductive pattern covers a portion of a side surface and the upper surface of the input/output contact plug.

18. The semiconductor device as claimed in claim 16, wherein:
the channel layer includes an undoped region, a first doped region contacting the first pad pattern and on the undoped region, and a second doped region contacting the second pad pattern and below the undoped region,
the first pad pattern and the second pad pattern include a silicon layer having an N-type conductivity,
the first doped region and the second doped region have an N-type conductivity,
the gate layers include a plurality of lower gate electrodes, a plurality of upper gate electrodes, and a plurality of intermediate gate electrodes between the plurality of lower gate electrodes and the plurality of upper gate electrodes,
the first doped region faces at least a portion of at least one of the plurality of upper gate electrodes,
the second doped region faces at least a portion of at least one of the plurality of lower gate electrodes,
at least one of the plurality of upper gate electrodes facing the first doped region is an upper erase control gate electrode,
at least one of the plurality of lower gate electrodes facing the second doped region is a lower erase control gate electrode, and
the plurality of intermediate gate electrodes include word lines.

19. A data storage system, comprising:
a semiconductor device including an input/output pattern; and
a controller electrically connected to the semiconductor device through the input/output pattern, and controlling the semiconductor device, wherein:
the semiconductor device includes:
a lower structure including a substrate and a peripheral circuit on the substrate; and
an upper structure bonded to the lower structure on the lower structure, the upper structure includes:
a stack structure including interlayer insulating layers and gate layers;
a vertical memory structure penetrating through the stack structure;
a bit line electrically connected to the vertical memory structure below the stack structure;
gate contact plugs contacting pad regions of the gate layers, and below the gate layers;
a source contact plug and an input/output contact plug spaced apart from the gate layers, and having upper surfaces on a level higher than a level of an uppermost gate layer among the gate layers, and lower surfaces on a level lower than a level of a lowermost gate layer among the gate layers;
a first conductive pattern electrically connected to the vertical memory structure and the source contact plug, and on a level higher than a level of the stack structure;
a second conductive pattern electrically connected to the input/output contact plug, and on the same level as a level of the first conductive pattern;
an upper insulating layer covering the first and second conductive patterns; and
a capping insulating layer on the upper insulating layer,
the input/output pattern penetrates the capping insulating layer and the upper insulating layer, and is electrically connected to the second conductive pattern,
the vertical memory structure includes an insulating core region, a channel layer covering at least a side surface of the insulating core region, a first pad pattern contacting the channel layer and on a level higher than a level of the uppermost gate layer, a dielectric structure contacting the first pad pattern and the channel layer, and a second pad pattern below the insulating core region,
the dielectric structure includes a first dielectric layer, a second dielectric layer, and a data storage layer between the first dielectric layer and the second dielectric layer, and
the second dielectric layer includes a portion contacting the channel layer and a portion contacting the first pad pattern, and is spaced apart from the second pad pattern.

20. The data storage system as claimed in claim 19, wherein:
the channel layer includes an undoped region, a first doped region contacting the first pad pattern and on the undoped region, and a second doped region contacting the second pad pattern and below the undoped region,
the first pad pattern and the second pad pattern include a silicon layer having an N-type conductivity,
the first doped region and the second doped region have an N-type conductivity,
the gate layers include a plurality of lower gate electrodes, a plurality of upper gate electrodes, and a plurality of intermediate gate electrodes between the plurality of lower gate electrodes and the plurality of upper gate electrodes,
the first doped region faces at least a portion of at least one of the plurality of upper gate electrodes,
the second doped region faces at least a portion of at least one of the plurality of lower gate electrodes,
at least one of the plurality of upper gate electrodes facing the first doped region is an upper erase control gate electrode,
at least one of the plurality of lower gate electrodes facing the second doped region is a lower erase control gate electrode, and
the plurality of intermediate gate electrodes include word lines.
